(19) United States
(12) Patent Application Publication
(10) Pub. No.: US 2017/0092838 A1
(43) Pub. Date: Mar. 30, 2017

(54) PIEZOELECTRIC DRIVING APPARATUS, METHOD OF MANUFACTURING THE SAME, MOTOR, ROBOT, AND PUMP

(71) Applicant: Seiko Epson Corporation, Tokyo (JP)

(72) Inventors: Akio KONISHI, Matsumoto (JP); Kiichi KAJINO, Matsumoto (JP); Noboru FURUYA, Chino (JP)

(21) Appl. No.: 15/268,972

(22) Filed: Sep. 19, 2016

(30) Foreign Application Priority Data
Sep. 29, 2015 (JP) 2015-190750
Nov. 13, 2015 (JP) 2015-222938
Nov. 13, 2015 (JP) 2015-222939

(51) Int. Cl. H01L 41/09; B25J 9/12; H01L 41/293; H01L 41/083; H01L 41/27

(52) U.S. Cl. CPC H01L 41/09; H01L 41/083; H01L 41/27; H01L 41/293; B25J 9/12; Y10S 901/28

(57) ABSTRACT

A piezoelectric driving apparatus including a substrate; a piezoelectric element which has a first electrode provided on the substrate, a piezoelectric body layer provided on the first electrode, and a second electrode provided on the first piezoelectric body layer, a layer including copper provided along an outer periphery of the substrate in plan view and electrically connected to the first electrode; and a conductive layer including nickel and phosphorus provided so as to cover the layer including copper.

### BACKGROUND

1. Technical Field

The present invention relates to a piezoelectric driving apparatus, method of manufacturing the same, a motor, a robot, and a pump.

2. Related Art

Ultrasonic motors for driving a driven body by vibrating a piezoelectric body are used in various fields (for example, refer to JP-A-2004-320979) since a magnet or a coil is not necessary. Such ultrasonic motors generally use piezoelectric elements (bulk piezoelectric elements) provided with a bulk-type piezoelectric body (for example, refer to JP-A-2008-227123).

On the other hand, piezoelectric elements (thin-film piezoelectric element) provided with a thin-film piezoelectric body are known. Thin-film piezoelectric elements are mainly used in the heads of ink jet printers to eject ink.

When using the thin-film piezoelectric element described above in an ultrasonic motor, there is a high possibility of being able to reduce the size of the ultrasonic motor and the device driven thereby. However, thin-film piezoelectric elements generally have a significantly smaller output than bulk piezoelectric elements. Thus, with existing thin-film piezoelectric elements, it may not be possible to obtain a sufficient output for use as the driving source of a motor for driving the joints of a robot for example.

In addition, ultrasonic motors for driving a driven body by vibrating a piezoelectric body are used in various fields since a magnet or a coil is not necessary. For example, JP-A-8-237971 and Japanese Patent No. 4813708 describe a piezoelectric driving apparatus where piezoelectric vibrating bodies are laminated in the thickness direction of the substrate.

However, in piezoelectric driving apparatuses as described above, for example, a jumper wire such as wiring is used to electrically connect a piezoelectric vibrating body, and a driving circuit or the like for driving the piezoelectric vibrating body. Therefore, space for routing the jumper wire is required in the piezoelectric driving apparatus as described above and the size of the apparatus may be increased.

### SUMMARY

An object of some aspects of the invention is to provide a piezoelectric driving apparatus which can be reduced in size. In addition, an object of some aspects of the invention is to provide a method for manufacturing a piezoelectric driving apparatus which can be reduced in size. In addition, an object of some aspects of the invention is to provide a motor, a robot, or a pump which includes the piezoelectric driving apparatus described above.

The invention can be realized in the following aspects or application examples.

### Application Example 1

One aspect of a piezoelectric driving apparatus according to the invention includes a substrate, a piezoelectric element which has a first electrode provided on the substrate, a piezoelectric body layer provided on the first electrode, and a second electrode provided on the first piezoelectric body layer, a layer including copper provided along an outer periphery of the substrate in plan view and electrically connected to the first electrode, and a conductive layer including nickel and phosphorus provided so as to cover the layer including copper.

In such a piezoelectric driving apparatus, it is possible to lower the resistance of the member which electrically connects the first electrode and a terminal of the piezoelectric driving apparatus. Due to this, it is possible to achieve a higher output in such a piezoelectric driving apparatus. Furthermore, since such a piezoelectric driving apparatus includes a piezoelectric element which is a thin-film piezoelectric element, it is possible to reduce the size thereof.

Here, in the description according to the invention, the phrase “electrically connected” is used, for example, when a “specific member” (referred to below as “A member”) is electrically connected to another specific member (referred to below as “B member”). In the description according to the invention, in a case such as in this example, the phrase “electrically connected” is used to include a case where the A member and the B member are electrically connected in direct contact and a case where the A member and the B member are electrically connected via another member.

### Application Example 2

In Application Example 1, the conductive layer may have a layer including nickel and phosphorus, and a gold layer provided so as to cover the layer including nickel and phosphorus.

In such a piezoelectric driving apparatus, in a case where the configuration of the terminal electrically connected to the piezoelectric element and the configuration of the conductive layer are the same, and the material of the external wiring connected to the terminal is metal, it is possible to bond the terminal and the external wiring using a metal bond (Au—Au bond).

### Application Example 3

In Application Example 2, the conductive layer may have a palladium layer provided between a layer including nickel and phosphorus and a gold layer.

In such a piezoelectric driving apparatus, it is possible to suppress diffusion between the layer including nickel and phosphorus and the gold layer using the palladium layer.

### Application Example 4

In any one of Application Examples 1 to 3, the conductive layer may be a non-electrolytic plating layer.

In such a piezoelectric driving apparatus, it is possible to easily form the conductive layer.

### Application Example 5

In any one of Application Examples 1 to 4, the substrate may have a first surface and a second surface on an opposite side to the first surface, the piezoelectric element may be provided on the first surface, a metal layer may be provided on the second surface, and the metal layer may be connected to the conductive layer.

In such a piezoelectric driving apparatus, it is possible to further lower the resistance of the member electrically connecting the first electrode and the terminal of the piezoelectric driving apparatus.

### Application Example 6

Application Example 5 may further include a first piezoelectric vibrating body; and a second piezoelectric vibrating body bonded to the first piezoelectric vibrating body, in which the first piezoelectric vibrating body and the second piezoelectric vibrating body may include the substrate, the piezoelectric element, and the layer including copper, and the layer including copper of the first piezoelectric vibrating body and the layer including copper of the second piezoelectric vibrating body may be bonded.

In such a piezoelectric driving apparatus, it is possible to further increase the output in comparison with a case where only one piezoelectric vibrating body is included.

### Application Example 7

In Application Example 6, the first piezoelectric vibrating body and the second piezoelectric vibrating body may form a bonded body, the bonded body may include the metal layer, a plurality of the bonded bodies may be laminated in a thickness direction of the substrate, and in adjacent bonded bodies, the metal layer of one bonded body and the metal layer of the other bonded body may be bonded.

In such a piezoelectric driving apparatus, it is possible to further increase the output in comparison with a case where only one bonded body is formed.

### Application Example 8

One aspect of a method of manufacturing a piezoelectric driving apparatus according to the invention includes forming a first electrode on a substrate; forming a piezoelectric body layer on the first electrode; forming a second electrode on the piezoelectric body layer; forming a layer including copper electrically connected to the first electrode along an outer periphery of the substrate in plan view; and forming a non-electrolytic plating layer so as to cover the layer including copper.

In the method of manufacturing a piezoelectric driving apparatus, it is possible to manufacture a piezoelectric driving apparatus which is able to increase the output. Furthermore, in the method of manufacturing a piezoelectric driving apparatus, it is possible to manufacture a piezoelectric driving apparatus which can be reduced in size.

### Application Example 9

One aspect of the piezoelectric driving apparatus according to the invention includes a first piezoelectric vibrating body having a first substrate, a first piezoelectric element provided on a first surface of the first substrate, and a first wiring layer electrically connected to the first piezoelectric element, a second piezoelectric vibrating body having a second substrate, a second piezoelectric element provided on a first surface of the second substrate, and a second wiring layer electrically connected to the second piezoelectric element, and a terminal electrically connecting external wiring and the first wiring layer and the second wiring layer, in which the first piezoelectric vibrating body and the second piezoelectric vibrating body are bonded such that the first surface of the first substrate and the first surface of the second substrate are opposed, and the terminal is connected to a side surface of the first wiring layer and a side surface of the second wiring layer, and is provided so as to protrude further outward than the side surface of the first substrate and the side surface of the second substrate.

In such a piezoelectric driving apparatus, using a flexible substrate as the external wiring makes it possible, for example, to electrically connect a driving circuit and the flexible substrate. Due to this, in such a piezoelectric driving apparatus, it is possible to reduce the size in comparison with a case of electrically connecting the driving circuit and the wiring layer using a jumper wire.

### Application Example 10

In Application Example 9, the terminal may be a non-electrolytic plating layer.

In such a piezoelectric driving apparatus, it is possible to easily form a terminal.

### Application Example 11

Application Example 9 or 10 may further include a first insulating portion provided between the first substrate and the first wiring layer; and a second insulating portion provided between the second substrate and the second wiring layer, in which the terminal may be connected to a side surface of the first insulating portion and a side surface of the second insulating portion.

In such a piezoelectric driving apparatus, it is possible to suppress contact between the terminal and the substrate. Due to this, in such a piezoelectric driving apparatus, it is possible to suppress leakage current from flowing via the terminal between the substrate of the first piezoelectric vibrating body and the substrate of the second piezoelectric vibrating body.

### Application Example 12

In any one of Application Example 9 to 11, the terminal may be provided to be separated from the first substrate and the second substrate.

In such a piezoelectric driving apparatus, it is possible to suppress leakage current from flowing via the terminal between the substrate of the first piezoelectric vibrating body and the substrate of the second piezoelectric vibrating body.

### Application Example 13

One aspect of a method of manufacturing a piezoelectric driving apparatus according to the invention includes forming a first piezoelectric vibrating body having a first substrate, a first piezoelectric element provided on a first surface of the first substrate, and a first wiring layer electrically connected to the first piezoelectric element, forming a second piezoelectric vibrating body having a second substrate, a second piezoelectric element provided on a first surface of the second substrate, and a second wiring layer electrically connected to the second piezoelectric element, and bonding the first piezoelectric vibrating body and the second piezoelectric vibrating body such that the first surface of the first substrate and the first surface of the second substrate are opposed, and forming a terminal so as to be connected to a side surface of the first wiring layer and a side surface of the second wiring layer, and protrude further outward than the side surface of the first substrate and the side surface of the second substrate.

In the method of manufacturing a piezoelectric driving apparatus, it is possible to manufacture a piezoelectric driving apparatus which can be reduced in size.

### Application Example 14

In Application Example 13, the terminal may be formed by non-electrolytic plating in the forming of the terminal.

In the method of manufacturing a piezoelectric driving apparatus, it is possible to easily form a terminal.

### Application Example 15

In Application Example 13 or 14, in the forming of the first piezoelectric vibrating body, the first piezoelectric vibrating body may be formed so as to have a first insulating portion, in the forming of the second piezoelectric vibrating body, the second piezoelectric vibrating body may be formed so as to have a second insulating portion, and, in the forming of the terminal, the terminal may be formed so as to connect a side surface of the first insulating portion and a side surface of the second insulating portion.

In the method of manufacturing a piezoelectric driving apparatus, it is possible to manufacture a piezoelectric driving apparatus which can suppress leakage current from flowing via the terminal between the substrate of the first piezoelectric vibrating body and the substrate of the second piezoelectric vibrating body.

### Application Example 16

In any one of Application Examples 13 to 15, in the forming of the terminal, the terminal may be formed so as to be separated from the first substrate and the second substrate.

In the method of manufacturing a piezoelectric driving apparatus, it is possible to manufacture a piezoelectric driving apparatus which can suppress leakage current from flowing via the terminal between the substrate of the first piezoelectric vibrating body and the substrate of the second piezoelectric vibrating body.

### Application Example 17

One aspect of the piezoelectric driving apparatus according to the invention includes a plurality of vibrating units, in which the vibrating units include a vibrating plate having a fixing portion, a vibrating portion, and a connecting portion connecting the fixing portion and the vibrating portion, a first electrode provided above the vibrating portion, a first piezoelectric body layer provided above the first electrode, a second electrode provided above the first piezoelectric body layer, a third electrode provided above the fixing portion, a second piezoelectric body layer provided above the third electrode, and a fourth electrode provided above the second piezoelectric body layer, the first electrode, the first piezoelectric body layer, and the second electrode form a piezoelectric element, and the vibrating unit is disposed so as to overlap a plate surface of the vibrating plate in an orthogonal direction.

In such a piezoelectric driving apparatus, a structure similar to the piezoelectric element is formed in the fixing portion of the vibrating plate and, due to this, when the plurality of vibrating units are overlapped, a bending force is not easily generated in the thickness direction thereof and the plurality of vibrating units are laminated in a favorable flat state and damage or the like does not occur easily. Due to this, the residual stress in the vibrating unit is small and damage or the like does not occur easily, in addition, it is possible to easily carry out the manufacturing since the first piezoelectric body layer and the second piezoelectric body layer can be formed in the same step.

### Application Example 18

In Application Example 17, the vibrating unit may include an insulating layer provided above the second electrode and the fourth electrode and a wiring layer provided above the insulating layer, and at least one of the second electrode and the fourth electrode may be electrically connected to the wiring layer.

In such a piezoelectric driving apparatus, even in a case where the electrodes are formed of thin films, it is possible to reduce the wiring resistance and to carry out the driving efficiently.

### Application Example 19

In Application Example 18, an inductor may be formed by electrically connecting the wiring layers of the adjacently disposed vibrating units to each other.

According to such a piezoelectric driving apparatus, it is possible to save space for installing the inductor. Therefore, it is possible to increase the space utilization efficiency in comparison with a case of providing an inductor externally.

### Application Example 20

In any one of Application Examples 17 to 19, the third electrode, the second piezoelectric body layer, and the fourth electrode may form a capacitor.

According to such a piezoelectric driving apparatus, it is possible to save space for installing the capacitor. Therefore, it is possible to increase the space utilization efficiency in comparison with a case of providing a capacitor externally. Furthermore, in a case where the second piezoelectric body layer which forms the capacitor is the same material as the first piezoelectric body layer which forms the piezoelectric element, since the temperature characteristics of the capacitor and the temperature characteristics of the piezoelectric element are similar and both are disposed at spatially close positions, for example, it is possible to simplify the driving circuit or control for responding to changes in temperature.

### Application Example 21

In Application Example 20, the capacitor may be electrically connected in parallel with the piezoelectric element as seen from a power source of the vibrating unit.

According to such a piezoelectric driving apparatus, it is possible to increase the apparent impedance in a case of being viewed as an electrical element and to further increase the mechanical output in a case of being viewed as an acoustic element.

### Application Example 22

In any one of Application Example 17 to 21, the wiring layer may form an inductor.

In such a piezoelectric driving apparatus, it is possible to save space for installing the inductor. Therefore, it is possible to increase the space utilization efficiency in comparison with a case of providing an inductor externally.

### Application Example 23

In Application Example 22, the inductor may be electrically connected in parallel with the piezoelectric element as seen from the power source of the vibrating unit.

According to such a piezoelectric driving apparatus, it is possible to increase the apparent impedance in a case of being viewed as an electrical element and to further increase the mechanical output in a case of being viewed as an acoustic element.

### Application Example 24

One aspect of a motor according to the invention includes the piezoelectric driving apparatus according to any one of Application Examples 1 to 7, 9 to 12, and 17 to 23; and a rotor rotated by the piezoelectric driving apparatus.

In such a motor, it is possible to include the piezoelectric driving apparatus according to an aspect of the invention.

### Application Example 25

One aspect of a robot according to the invention includes a plurality of link portions; joint portions connecting the plurality of link portions; and the piezoelectric driving apparatus according to any one of Application Examples 1 to 7, 9 to 12, and 17 to 23, which rotates the plurality of link portions in the joint portions.

In such a robot, it is possible to include the piezoelectric driving apparatus according to an aspect of the invention.

### Application Example 26

One aspect of a pump according to the invention includes the piezoelectric driving apparatus according to any one of Application Examples 1 to 7, 9 to 12, and 17 to 23; a tube transporting a liquid; and a plurality of fingers closing the tube according to driving of the piezoelectric driving apparatus.

In such a pump, it is possible to include the piezoelectric driving apparatus according to an aspect of the invention.

Here, in the present specification, when referring to arranging (or forming) a specific member Y above (or below) a specific member X, the aspect is not limited to an aspect where the member Y is disposed (or formed) in direct contact above (or below) the member X, but includes an aspect where the member Y is disposed (or formed) via another member above (or below) the member X in a range in which the operation and effects thereof are not inhibited.

### BRIEF DESCRIPTION OF THE DRAWINGS

The invention will be described with reference to the accompanying drawings, wherein like numbers reference like elements.

FIG. 1 is a plan view which schematically shows a piezoelectric driving apparatus according to a first embodiment.

FIG. 2 is a cross-sectional view which schematically shows the piezoelectric driving apparatus according to the first embodiment.

FIG. 3 is a view which schematically shows the piezoelectric driving apparatus according to the first embodiment.

FIG. 4 is a plan view which schematically shows a first piezoelectric vibrating body of the piezoelectric driving apparatus according to the first embodiment.

FIG. 5 is a plan view which schematically shows the first piezoelectric vibrating body of the piezoelectric driving apparatus according to the first embodiment.

FIG. 6 is a cross-sectional view which schematically shows the first piezoelectric vibrating body of the piezoelectric driving apparatus according to the first embodiment.

FIG. 7 is a cross-sectional view which schematically shows the piezoelectric driving apparatus according to the first embodiment.

FIG. 8 is a cross-sectional view which schematically shows the piezoelectric driving apparatus according to the first embodiment.

FIG. 9 is a view which shows an equivalent circuit for illustrating the piezoelectric driving apparatus according to the first embodiment.

FIG. 10 is a view for illustrating a method of electrically connecting a terminal and a driving circuit of the piezoelectric driving apparatus according to the first embodiment.

FIG. 11 is a view for illustrating an operation of the piezoelectric driving apparatus according to the first embodiment.

FIG. 12 is a flow chart for illustrating a method of manufacturing a piezoelectric driving apparatus according to the first embodiment.

FIG. 13 is a cross-sectional view which schematically shows a manufacturing step of the piezoelectric driving apparatus according to the first embodiment.

FIG. 14 is a cross-sectional view which schematically shows a manufacturing step of the piezoelectric driving apparatus according to the first embodiment.

FIG. 15 is a cross-sectional view which schematically shows a manufacturing step of the piezoelectric driving apparatus according to the first embodiment.

FIG. 16 is a cross-sectional view which schematically shows a manufacturing step of the piezoelectric driving apparatus according to the first embodiment.

FIG. 17 is a cross-sectional view which schematically shows a piezoelectric driving apparatus according to a modification example of the first embodiment.

FIG. 18 is a plan view which schematically shows a piezoelectric driving apparatus according to a second embodiment.

FIG. 19 is a cross-sectional view which schematically shows the piezoelectric driving apparatus according to the second embodiment.

FIG. 20 is a view which schematically shows the piezoelectric driving apparatus according to the second embodiment.

FIG. 21 is a plan view which schematically shows a first piezoelectric vibrating body of the piezoelectric driving apparatus according to the second embodiment.

FIG. 22 is a plan view which schematically shows the first piezoelectric vibrating body of the piezoelectric driving apparatus according to the second embodiment.

FIG. 23 is a cross-sectional view which schematically shows the first piezoelectric vibrating body of the piezoelectric driving apparatus according to the second embodiment.

FIG. 24 is a cross-sectional view which schematically shows the piezoelectric driving apparatus according to the second embodiment.

FIG. 25 is a cross-sectional view which schematically shows the piezoelectric driving apparatus according to the second embodiment.

FIG. 26 is a view for illustrating a method of electrically connecting a terminal and a driving circuit of the piezoelectric driving apparatus according to the second embodiment.

FIG. 27 is a flow chart for illustrating a method of manufacturing a piezoelectric driving apparatus according to the second embodiment.

FIG. 28 is a cross-sectional view which schematically shows a manufacturing step of the piezoelectric driving apparatus according to the second embodiment.

FIG. 29 is a cross-sectional view which schematically shows a manufacturing step of the piezoelectric driving apparatus according to the second embodiment.

FIG. 30 is a cross-sectional view which schematically shows a manufacturing step of the piezoelectric driving apparatus according to the second embodiment.

FIG. 31 is a cross-sectional view which schematically shows a piezoelectric driving apparatus according to a modification example of the second embodiment.

FIG. 32 is a schematic view in which a vibrating plate according to a third embodiment is seen in plan view.

FIG. 33 is a schematic view in which a vibrating unit according to the third embodiment is seen in plan view.

FIG. 34 is a schematic view of a cross-section of the vibrating unit according to the third embodiment.

FIG. 35 is a schematic view of a cross-section of the vibrating unit according to the third embodiment.

FIG. 36 is a schematic view of a cross-section of a piezoelectric driving apparatus according to the third embodiment.

FIG. 37 is a schematic view of a cross-section of the piezoelectric driving apparatus according to the third embodiment.

FIG. 38 is a schematic view of a cross-section of the piezoelectric driving apparatus according to the third embodiment.

FIG. 39 is a schematic view in which the vibrating unit according to the third embodiment is seen in plan view and a conceptual view of a driving circuit.

FIG. 40 is a schematic view in which the vibrating unit according to the third embodiment is seen in plan view and a conceptual view of the driving circuit.

FIG. 41 is a schematic view in which the vibrating unit according to the third embodiment is seen in plan view and a conceptual view of the driving circuit.

FIG. 42 is a schematic view in which the vibrating unit according to the third embodiment is seen in plan view and a conceptual view of the driving circuit.

FIG. 43 is a schematic perspective view of the piezoelectric driving apparatus according to the third embodiment.

FIG. 44 is a view which shows an example of a conceptual view of a circuit which drives the piezoelectric driving apparatus according to the third embodiment.

FIG. 45 is a schematic view in which a motor according to the third embodiment is seen in plan view.

FIG. 46 is a diagram for illustrating a robot according to a fourth embodiment.

FIG. 47 is a diagram for illustrating a wrist portion of the robot according to the fourth embodiment.

FIG. 48 is a diagram for illustrating a pump according to the fourth embodiment.

### DESCRIPTION OF EXEMPLARY EMBODIMENTS

Detailed description will be given of favorable embodiments of the invention using the diagrams. Here, the embodiments described below do not unduly limit the contents of the invention described in the claims. In addition, it is not necessarily the case that all of the configurations described below are constituent elements of the invention.

### 1. First Embodiment

### 1.1. Piezoelectric Driving Apparatus

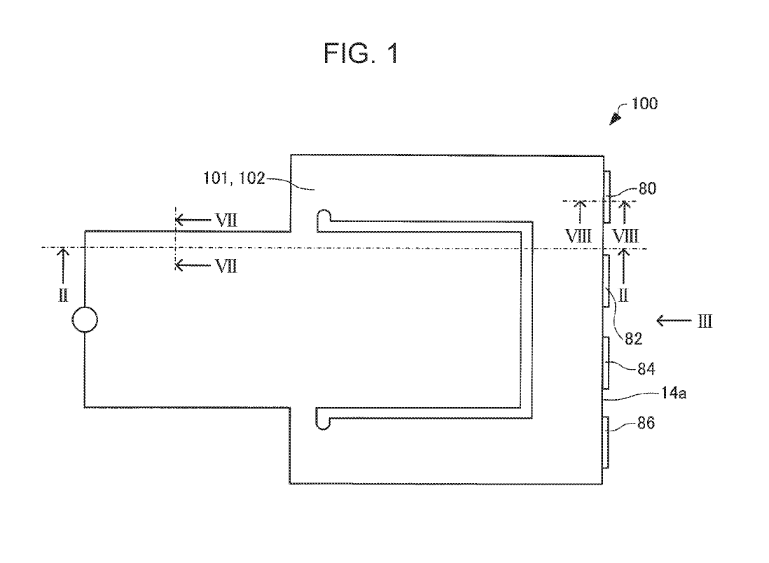

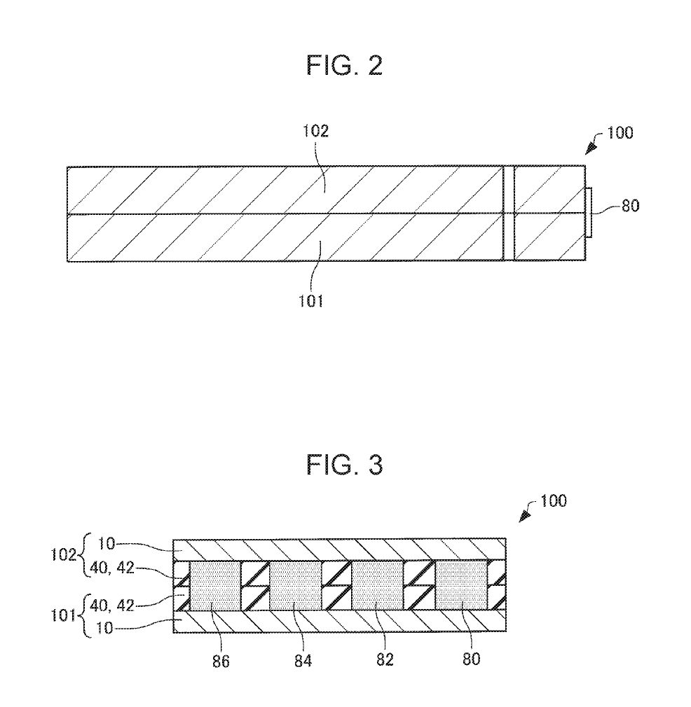

First, description will be given of the piezoelectric driving apparatus according to the first embodiment with reference to the drawings. FIG. 1 is a plan view which schematically shows a piezoelectric driving apparatus 100 according to a first embodiment. FIG. 2 is a cross-sectional view taken along a line II-II of FIG. 1 which schematically shows the piezoelectric driving apparatus 100 according to the first embodiment. FIG. 3 is a view taken along the direction of the arrow III of FIG. 1 which schematically shows the piezoelectric driving apparatus 100 according to the first embodiment.

As shown in FIGS. 1 to 3, the piezoelectric driving apparatus 100 includes a first piezoelectric vibrating body 101, and a second piezoelectric vibrating body 102 bonded to the first piezoelectric vibrating body 101. Here, FIG. 2 and FIG. 3 show the piezoelectric vibrating bodies 101 and 102 in a simplified manner.

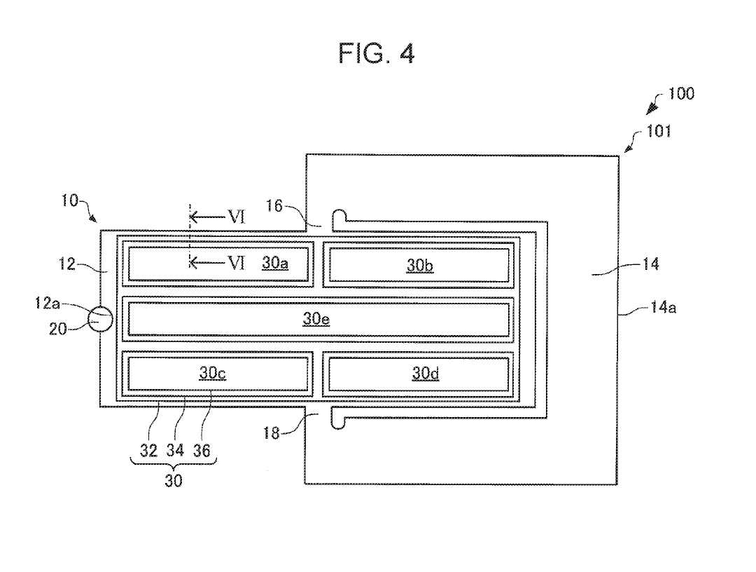

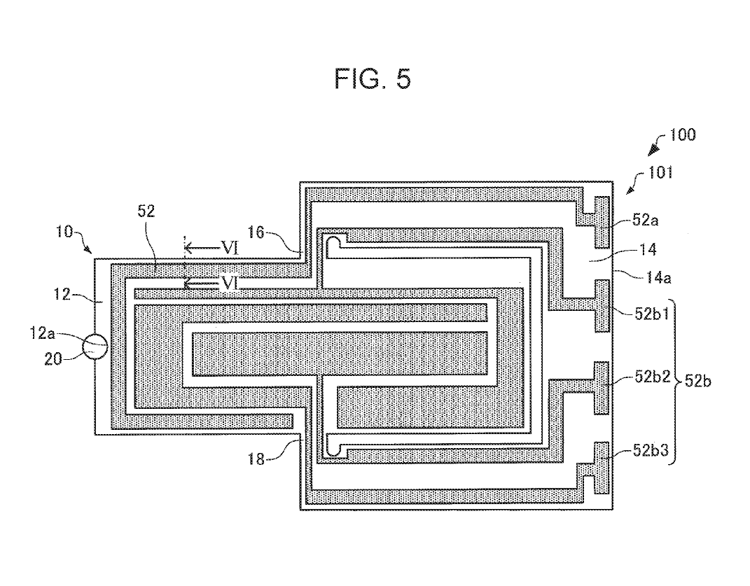

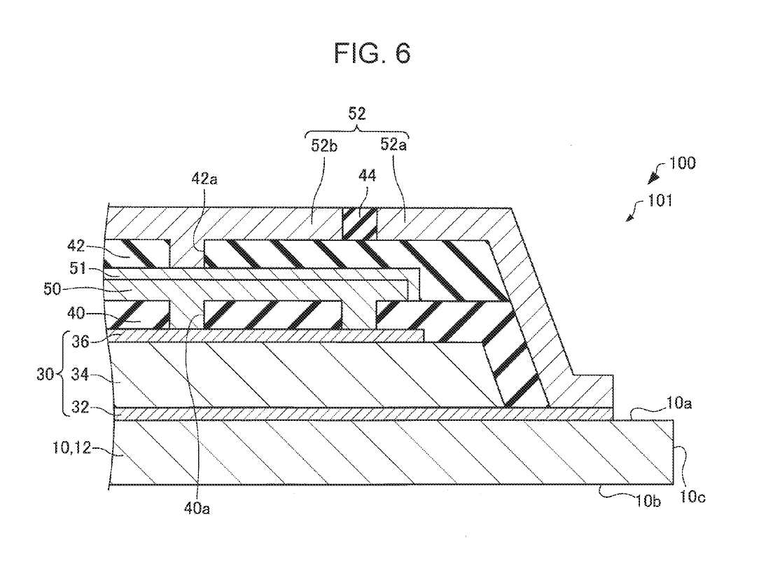

Here, FIG. 4 and FIG. 5 are plan views which schematically show the first piezoelectric vibrating body 101. FIG. 6 is a cross-sectional view taken along a line VI-VI of FIGS. 4 and 5 which schematically shows the first piezoelectric vibrating body 101. The first piezoelectric vibrating body 101 and the second piezoelectric vibrating body 102 basically have the same configuration. Accordingly, in the following, description will be given of the first piezoelectric vibrating body 101 using FIG. 4 to FIG. 6. The description in the first piezoelectric vibrating body 101 can basically be applied to the second piezoelectric vibrating body 102.

As shown in FIGS. 4 to 6, the first piezoelectric vibrating body 101 includes a substrate 10, a contact portion 20, a piezoelectric element 30, a first insulating layer 40, a second insulating layer 42, a first wiring layer 50, and a second wiring layer 52. Here, for the sake of convenience, in FIG. 4, illustration of members other than the substrate 10, the contact portion 20, and the piezoelectric element 30 is omitted. In addition, in FIG. 5, illustration of members other than the substrate 10, the contact portion 20, and a portion of the second wiring layer 52 is omitted.

As shown in FIG. 6, the substrate 10 has a first surface 10a, a second surface 10b on the opposite side to the first surface 10a, and a third surface (side surface) 10c which connects the first surface 10a and the second surface 10b. The piezoelectric element 30 is provided on the first surface 10a. The substrate 10 is, for example, a silicon substrate. Here, the substrate 10 may be formed of a laminate of a silicon substrate, a silicon oxide layer provided on the silicon substrate, and a zirconium oxide layer provided on the silicon oxide layer.

As shown in FIG. 4 and FIG. 5, the substrate 10 has a vibrating body portion 12, a support portion 14, a first connecting portion 16, and a second connecting portion 18. The planar shape of the vibrating body portion 12 (the shape as viewed from the thickness direction of the substrate 10) is substantially rectangular. The piezoelectric element 30 is provided on the vibrating body portion 12 and the vibrating body portion 12 can vibrate according to changes in the shape of the piezoelectric element 30. The support portion 14 supports the vibrating body portion 12 via the connecting portions 16 and 18. In the illustrated example, the connecting portions 16 and 18 extend from the central portion in the longitudinal direction of the vibrating body portion 12 in the direction perpendicular to the longitudinal direction and connect to the support portion 14.

The contact portion 20 is provided on the vibrating body portion 12. In the illustrated example, a concave portion 12a is provided in the vibrating body portion 12 and the contact portion 20 is fitted into and bonded to (for example, adhered to) the concave portion 12a. The contact portion 20 is a member which comes in contact with a driven member to transmit the movement of the vibrating body portion 12 to the driven member. The material of the contact portion 20 is, for example, a ceramic (specifically, alumina (Al₂O₃)), zirconia (ZrO₂), silicon nitride (Si₃N), or the like).

The piezoelectric element 30 is provided on the substrate 10. Specifically, the piezoelectric element 30 is provided on the vibrating body portion 12. The piezoelectric element 30 has a first electrode 32, a piezoelectric body layer 34, and a second electrode 36.

The first electrode 32 is provided on the vibrating body portion 12. In the illustrated example, the planar shape of the first electrode 32 is a rectangle. The first electrode 32 may be formed by an iridium layer provided on the vibrating body portion 12 and a platinum layer provided on the iridium layer. The thickness of the iridium layer is, for example, 5 nm to 100 nm. The thickness of the platinum layer is, for example, 50 nm to 300 nm. Here, the first electrode 32 may be a metal layer formed of Ti, Pt, Ta, Ir, Sr, In, Sn, Au, Al, Fe, Cr, Ni, Cu, and the like or a mixture or a laminate of two or more types thereof. The first electrode 32 is one electrode for applying a voltage to the piezoelectric body layer 34.

The piezoelectric body layer 34 is provided on the first electrode 32. In the illustrated example, the planar shape of the piezoelectric body layer 34 is a rectangle. The thickness of the piezoelectric body layer 34 is, for example, 50 nm to 20 μm, preferably 1 μm to 7 μm. In this manner, the piezoelectric element 30 is a thin-film piezoelectric element. When the thickness of the piezoelectric body layer 34 is less than 50 nm, the output of the piezoelectric driving apparatus 100 may be reduced. Specifically, when attempting to increase the output and increase the applied voltage to the piezoelectric body layer 34, the piezoelectric body layer 34 may cause dielectric breakdown. When the thickness of the piezoelectric body layer 34 is greater than 20 μm, cracks may occur in the piezoelectric body layer 34.

As the piezoelectric body layer 34, a perovskite-type oxide piezoelectric material is used. Specifically, the material of the piezoelectric body layer 34 is, for example, lead zirconate titanate (Pb(Zr,Ti)O₃: PZT), or lead zirconate titanate niobate (Pb(Zr,Ti,Nb)O₃: PZTN). It is possible to change the shape of (expand and contract) the piezoelectric body layer 34 by applying a voltage using the electrodes 32 and 36.

The second electrode 36 is provided on the piezoelectric body layer 34. In the illustrated example, the planar shape of the second electrode 36 is a rectangle. The second electrode 36 may be formed of the adhesive layer provided on the piezoelectric body layer 34, and a conductive layer provided on the adhesive layer. The thickness of the adhesive layer is, for example, 10 nm to 100 nm. The adhesive layer is, for example, a TiW layer, a Ti layer, a Cr layer, a NiCr layer, or a laminate thereof. The thickness of the conductive layer is, for example, 1 μm to 10 μm. The conductive layer is, for example, a Cu layer, an Au layer, an Al layer, or a laminate thereof. The second electrode 36 is the other electrode for applying a voltage to the piezoelectric body layer 34.

As shown in FIG. 4, a plurality of the piezoelectric elements 30 are provided. In the illustrated example, five of the piezoelectric elements 30 are provided (piezoelectric elements 30a, 30b, 30c, 30d, and 30e). In plan view (as viewed from the thickness direction of the substrate 10), for example, the areas of the piezoelectric elements 30a to 30d are the same and the piezoelectric element 30e has an area larger than that of the piezoelectric elements 30a to 30d. The piezoelectric element 30e is provided in the longitudinal direction of the vibrating body portion 12 in the central portion in the lateral direction of the vibrating body portion 12. The piezoelectric elements 30a, 30b, 30c, and 30d are provided at the four corners of the vibrating body portion 12. In the illustrated example, in the piezoelectric elements 30a to 30e, the first electrode 32 is provided as one continuous conductive layer.

As shown in FIG. 6, the first insulating layer 40 is provided so as to cover the piezoelectric element 30. The material of the first insulating layer 40 may be an inorganic material such as silicon oxide or aluminum oxide, or may be an organic material such as an epoxy-based resin, an acrylic-based resin, a polyimide-based resin, or a silicone-based resin. The material of the first insulating layer 40 may be a photosensitive material.

The first wiring layer 50 is provided on the second electrode 36. The first wiring layer 50 is electrically connected to the second electrode 36. In the illustrated example, the first wiring layer 50 is provided on the first insulating layer 40 and in a contact hole 40a formed in the first insulating layer 40 to be connected to the second electrode 36.

The first wiring layer 50 is a layer including copper. The first wiring layer 50 may be formed of a titanium tungsten layer, and a copper layer provided on the titanium tungsten layer. In the illustrated example, the first wiring layer 50 is covered with a non-electrolytic plating layer 51 formed by non-electrolytic plating. The non-electrolytic plating layer 51 may be formed of a layer (Ni—P layer) including nickel and phosphorus. Alternatively, the non-electrolytic plating layer 51 may be formed of a Ni—P layer, and a gold layer provided on the Ni—P layer. Alternatively, the non-electrolytic plating layer 51 may be formed of a Ni—P layer, a palladium layer provided on the Ni—P layer, and a gold layer provided on the palladium layer.

The second insulating layer 42 is provided so as to cover the first wiring layer 50. In the illustrated example, the second insulating layer 42 is provided so as to cover the first wiring layer 50 via the non-electrolytic plating layer 51. The material of the second insulating layer 42 is, for example, the same as the material of the first insulating layer 40.

The second wiring layer 52 has a first portion 52a which is electrically connected to the first electrode 32, and a second portion 52b which is electrically connected to the second electrode 36. As shown in FIG. 5, the first portion 52a and the second portion 52b are electrically separated. The second wiring layer 52 is a layer including copper. The second wiring layer 52 may be formed of a titanium tungsten layer, and a copper layer provided on the titanium tungsten layer.

The first portion 52a of the second wiring layer 52 is connected to the first electrode 32. In the example shown in FIG. 6, the first portion 52a is provided on the upper surface of the first electrode 32, the side surface of the first insulating layer 40, and the upper surface and the side surface of the second insulating layer 42. As shown in FIG. 5, the first portion 52a is provided along the outer periphery of the substrate 10 in plan view.

As shown in FIG. 5, in plan view, the first portion 52a of the second wiring layer 52 extends from the vibrating body portion 12 through the first connecting portion 16 to the vicinity of a side 14a (side of the opposite side to the contact portion 20) of the support portion 14.

As shown in FIG. 6, the second portion 52b of the second wiring layer 52 is provided on the first wiring layer via the non-electrolytic plating layer 51. In the illustrated example, the second portion 52b is provided on the second insulating layer 42 and in a contact hole 42a formed in the second insulating layer 42, and is connected to the non-electrolytic plating layer 51. In the illustrated example, a third insulating layer 44 is provided on the second insulating layer 42 between the first portion 52a and the second portion 52b. Due to this, the first portion 52a and the second portion 52b can be more reliably electrically separated.

As shown in FIG. 5, the second portion 52b of the second wiring layer 52 is further divided into three portions. That is, the second portion 52b of the second wiring layer 52 has a first portion 52b1, a second portion 52b2, and a third portion 52b3. The first portion 52b1 is connected to the second electrodes 36 of the piezoelectric element 30a and 30d. In plan view, the first portion 52b1 extends from the vibrating body portion 12 through the first connecting portion 16 to the vicinity of the side 14a of the support portion 14. The second portion 52b2 is connected to the second electrode 36 of the piezoelectric element 30e. In plan view, the second portion 52b2 extends from the vibrating body portion 12 through the second connecting portion 18 to the vicinity of the side 14a of the support portion 14. In plan view, the third portion 52b3 is connected to the second electrodes 36 of the piezoelectric elements 30b and 30c. In plan view, the third portion 52b3 extends from the vibrating body portion 12 through the second connecting portion 18 to the vicinity of the side 14a of the support portion 14.

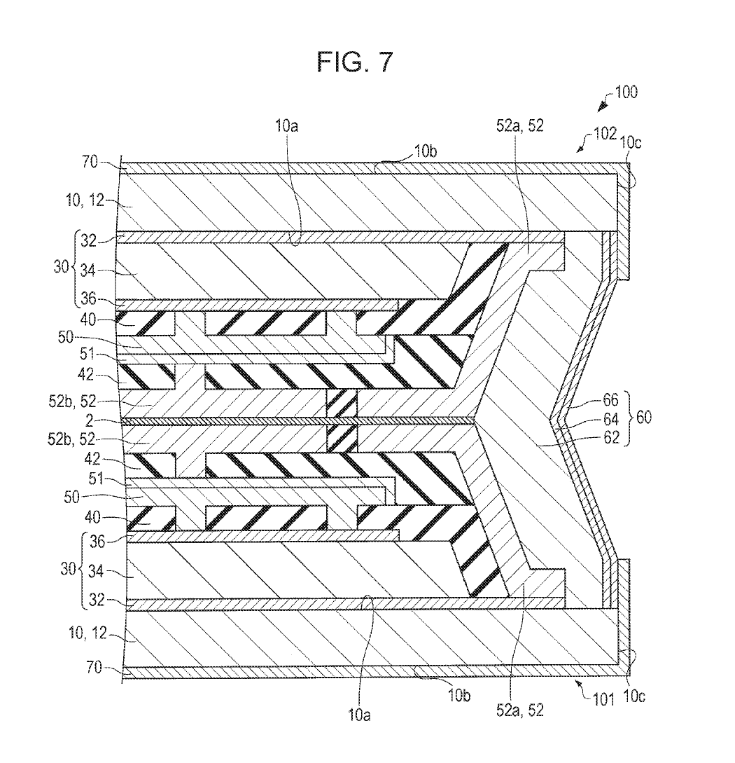

FIG. 7 is a cross-sectional view taken along a line VII-VII of FIG. 1 which schematically shows the piezoelectric driving apparatus 100. As shown in FIG. 7, the first piezoelectric vibrating body 101 and the second piezoelectric vibrating body 102 are laminated in the thickness direction of the substrate 10. The distance between the substrate 10 of the first piezoelectric vibrating body 101 and the substrate 10 of the second piezoelectric vibrating body 102 is, for example, approximately 20 μm. The second wiring layer 52 of the first piezoelectric vibrating body 101 and the second wiring layer 52 of the second piezoelectric vibrating body 102 are bonded. In the illustrated example, the second wiring layer of the first piezoelectric vibrating body 101 and the second wiring layer 52 of the second piezoelectric vibrating body 102 are bonded via an adhesive 2. The adhesive 2 is, for example, a conductive adhesive. Due to this, the second wiring layer 52 of the first piezoelectric vibrating body 101 and the second wiring layer 52 of the second piezoelectric vibrating body 102 can be electrically connected.

Here, the second wiring layer 52 of the first piezoelectric vibrating body 101 and the second wiring layer of the second piezoelectric vibrating body 102 may be bonded by metallic bonds (Cu—Cu bond). Due to this, the piezoelectric vibrating bodies 101 and 102 can be strongly bonded to without using an adhesive.

As shown in FIG. 7, the piezoelectric driving apparatus 100 includes a conductive layer 60 containing nickel and phosphorus, and a metal layer 70.

The conductive layer 60 is provided so as to cover the end portion of the second wiring layer 52. In the illustrated example, the conductive layer 60 is provided to the side of the first portion 52a of the second wiring layer of the piezoelectric vibrating bodies 101 and 102 and connected to the first portion 52a. In other words, the conductive layer 60 is provided above a portion where the second wiring layer 52 is exposed in the side portion when the first piezoelectric vibrating body 101 and the second piezoelectric vibrating body 102 are bonded.

The conductive layer 60 is a non-electrolytic plating layer formed by non-electrolytic plating. The conductive layer 60 has, for example, a layer (Ni—P layer) including nickel and phosphorus, a palladium layer 64, and a gold layer 66. The Ni—P layer 62 is provided so as to cover the first portion 52a. The palladium layer 64 is provided so as to cover the Ni—P layer 62. The palladium layer 64 is provided between the Ni—P layer 62 and the gold layer 66. The gold layer 66 is provided so as to cover the Ni—P layer 62 via the palladium layer 64. Here, although not shown, the palladium layer 64 may not be provided. In addition, the palladium layer 64 and the gold layer 66 may not be provided.

The metal layer 70 is provided on the second surface 10b and the third surface 10c of the substrate 10. The metal layer 70 is connected to the conductive layer 60. In the illustrated example, the metal layer 70 is connected to the gold layer 66 of the conductive layer 60. The metal layer 70 is, for example, a copper layer.

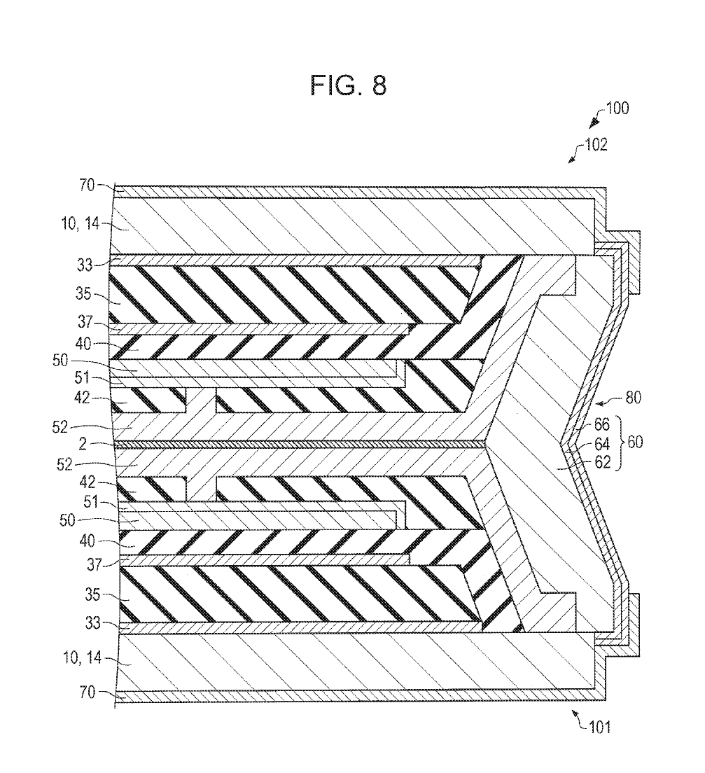

FIG. 8 is a cross-sectional view taken along a line VIII-VIII of FIG. 1 which schematically shows the piezoelectric driving apparatus 100. As shown in FIGS. 1 to and 8, the piezoelectric driving apparatus 100 has terminals 80, 82, 84, and 86. The terminals 80, 82, 84, and 86 have the same structure as the conductive layer 60. As shown in FIG. 1, in plan view, the terminals 80, 82, 84, and 86 protrude outward from the side 14a of the support portion 14. The width of the terminals 80, 82, 84, and 86 (the length in the direction perpendicular to the thickness direction of the substrate 10) is, for example, approximately 200 μm. The distance between the adjacent terminals 80, 82, 84, and 86 is, for example, approximately 100 μm.

The terminal 80 is, for example, electrically connected to the first electrode 32 common to the piezoelectric elements 30a, 30b, 30c, 30d, and 30e via the first portion 52a (refer to FIG. 5) of the second wiring layer 52. The terminal 80 may have a reference potential as a ground. The terminal 82 is, for example, electrically connected to the second electrode 36 of the piezoelectric elements 30a and 30d via the first portion 52b1 (refer to FIG. 5) of the second portion 52b of the second wiring layer 52. The terminal 86 is, for example, electrically connected to the second electrode 36 of the piezoelectric elements 30b and 30c via the third portion 52b3 (refer to FIG. 5) of the second portion 52b of the second wiring layer 52. The terminal 84, for example, is electrically connected to the second electrode 36 of the piezoelectric element 30e via the second portion 52b2 (refer to FIG. 5) of the second portion 52b of the second wiring layer 52. In the piezoelectric driving apparatus 100, connecting the terminals 80, 82, 84, and 86 and the driving circuit makes it possible to apply a voltage to the piezoelectric body layer 34 of the piezoelectric elements 30a to 30e and to vibrate the vibrating body portion 12.

The terminal 80 is, for example, connected to the metal layer 70. Here, although not shown, the terminals 82, 84, and 86 are not connected to the metal layer 70. In addition, the terminal 80 may also not be connected to the metal layer 70.

As shown in FIG. 8, in the piezoelectric vibrating bodies 101 and 102 of the piezoelectric driving apparatus 100, a first conductive layer 33, an insulating layer 35, a second conductive layer 37, the insulating layers 40 and 42, the wiring layers 50 and 52, and the non-electrolytic plating layer 51 are provided on the support portion 14 and the connecting portions 16 and 18. Due to this, for example, in each of the piezoelectric vibrating bodies 101 and 102, the difference in the thickness (height) in the members provided on the vibrating body portion 12, the support portion 14, and the connecting portions 16 and 18 can be reduced. In other words, it is possible to improve the uniformity of the thickness in the piezoelectric vibrating bodies 101 and 102 respectively. Therefore, when laminating the piezoelectric vibrating bodies 101 and 102, it is possible to suppress gaps from being formed between the piezoelectric vibrating bodies 101 and 102. Due to this, it is possible to improve the bonding strength of the piezoelectric vibrating bodies 101 and 102.

Here, the materials of the first conductive layer 33, the insulating layer 35, and the second conductive layer 37 are respectively the same as the materials of the first electrode 32, the piezoelectric body layer 34, and the second electrode 36. The first conductive layer 33, the insulating layer 35, and the second conductive layer 37 can each be formed in the step of forming the first electrode 32, the piezoelectric body layer 34, and the second electrode 36. No voltage is applied to the piezoelectric body layer 34 due to the conductive layers 33 and 37. In the example shown in FIG. 8, the first conductive layer 33 is electrically separated from the terminal 80; however, the first conductive layer 33 may be electrically connected to the terminal 80 and may be electrically connected to the first electrode 32. In a case where the first conductive layer 33 is electrically connected to the first electrode 32 and the terminal 80, the second conductive layer 37 is electrically separated from the second electrode 36.

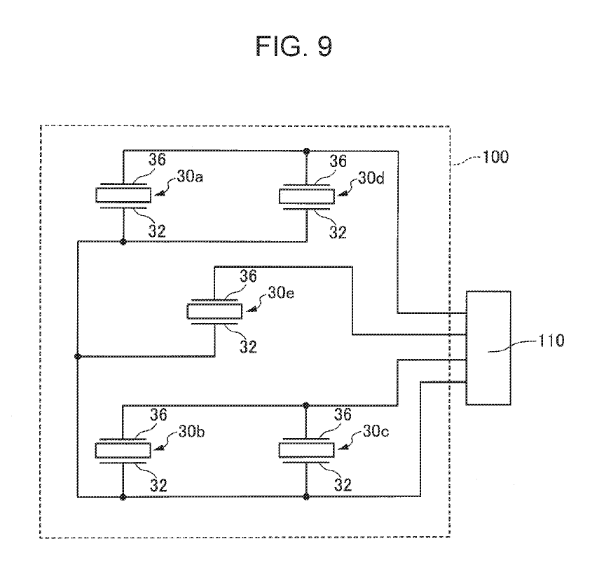

FIG. 9 is a diagram which shows an equivalent circuit for illustrating the piezoelectric driving apparatus 100. The piezoelectric elements 30 are divided into three groups. The first group has two piezoelectric elements 30a and 30d. The second group has two piezoelectric elements 30b and 30c. The third group has only one piezoelectric element 30e. As shown in FIG. 9, the piezoelectric elements 30a and 30d of the first group are connected in parallel with each other and connected to a driving circuit 110. The piezoelectric elements 30b and 30c of the second group are connected in parallel with each other and connected to the driving circuit 110. The piezoelectric element 30e of the third group is connected to the driving circuit 110 alone.

The driving circuit 110 applies a periodically changing AC voltage or a pulsating voltage between the first electrode 32 and the second electrode 36 of predetermined piezoelectric elements out of the five piezoelectric elements 30a, 30b, 30c, 30d, and 30e, for example, the piezoelectric elements 30a, 30d, and 30e. Due to this, the piezoelectric driving apparatus 100 is able to rotate the rotor (driven member) in contact with the contact portion 20 in a predetermined rotation direction by ultrasonically vibrating the vibrating body portion 12. Here, the “pulsating voltage” has the meaning of a voltage where a DC offset is applied to an AC voltage and the orientation of the voltage (electric field) of the pulsating voltage is a direction from one electrode to the other electrode.

Here, the orientation of the current is more preferably from the second electrode 36 toward the first electrode 32 than from the first electrode 32 toward the second electrode 36. In addition, applying the AC voltage or the pulsating voltage between the electrodes 32 and 36 of the piezoelectric elements 30b, 30c, and 30e makes it possible to rotate the rotor in contact with the contact portion 20 in the opposite direction.

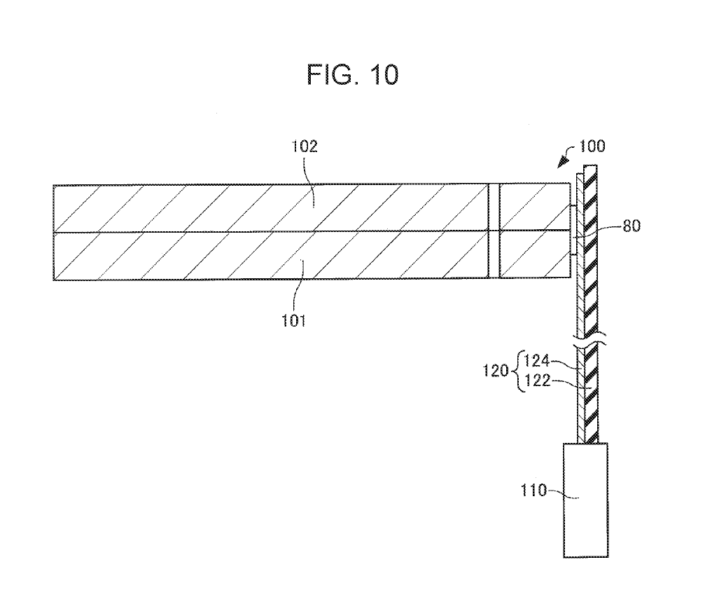

FIG. 10 is a diagram for illustrating a method of electrically connecting the terminal 80 and the driving circuit 110 of the piezoelectric driving apparatus 100. Here, for the sake of convenience, FIG. 10 shows the piezoelectric vibrating bodies 101 and 102 in a simplified manner.

As shown in FIG. 10, the terminal 80 is electrically connected to the driving circuit 110 via a flexible substrate 120. Specifically, the flexible substrate 120 has an insulating substrate 122, and a wiring layer 124 provided on the insulating substrate 122, and is able to electrically connect the terminal 80 and the driving circuit 110 using the wiring layer 124. The wiring layer 124 is, for example, a gold layer, or a copper layer.

Here, in the same manner as the terminal 80, the terminals 82, 84, and 86 are electrically connected to the driving circuit 110 via the flexible substrate 120. In addition, although not shown in the diagram, the terminals 80, 82, 84, and 86 and the driving circuit 110 may be electrically connected using wiring or solder.

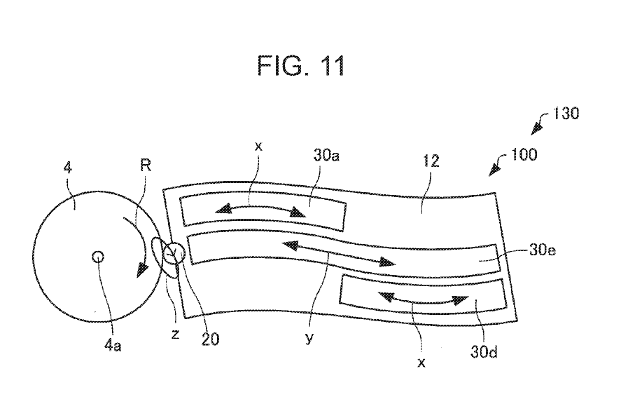

FIG. 11 is a diagram for illustrating the operation of the vibrating body portion 12 of the piezoelectric driving apparatus 100. As shown in FIG. 11, the contact portion 20 of the piezoelectric driving apparatus 100 is in contact with the outer periphery of a rotor 4 as the driven member. The driving circuit 110 applies an AC voltage or a pulsating voltage between the electrodes 32 and 36 of the piezoelectric elements 30a and 30d. Due to this, the piezoelectric elements 30a and 30d expand and contract in the direction of the arrow x. In response to this, the vibrating body portion 12 bends and vibrates in the plane of the vibrating body portion 12 (for example, bends and vibrates along the lateral direction of the vibrating body portion 12 in a state where a voltage is not applied to the piezoelectric element 30) to change shape in a meandering shape (S-shape). Furthermore, the driving circuit 110 applies an AC voltage or a pulsating voltage between the electrodes 32 and 36 of the piezoelectric element 30e. Due to this, the piezoelectric element 30e expands and contracts in the direction of the arrow y. Due to this, the vibrating body portion 12 vibrates longitudinally in the plane of the vibrating body portion 12 (for example, vibrates longitudinally along the longitudinal direction of the vibrating body portion 12 in a state where a voltage is not applied to the piezoelectric element 30). Due to the vibrates longitudinally and the longitudinal vibration of the vibrating body portion 12 as described above, the contact portion 20 move elliptically as in the arrow z. As a result, the rotor 4 rotates in the predetermined direction R around a center 4a thereof (the clockwise direction in the illustrated example).

Here, in a case where the driving circuit 110 applies an AC voltage or a pulsating voltage between the electrodes 32 and 36 of the piezoelectric elements 30b, 30c, and 30e, the rotor 4 rotates in the opposite direction to the direction R (the counterclockwise direction).

In addition, the resonance frequency of the bending vibration and the resonance frequency of the longitudinal vibration of the vibrating body portion 12 are preferably the same. Due to this, the piezoelectric driving apparatus 100 can efficiently rotate the rotor 4.

As shown in FIG. 11, a motor 130 according to the present embodiment includes the piezoelectric driving apparatus (the piezoelectric driving apparatus 100 in the illustrated example) according to the invention and the rotor 4 rotated by the piezoelectric driving apparatus 100.

The piezoelectric driving apparatus 100, for example, has the following characteristics.

The piezoelectric driving apparatus 100 includes the second wiring layer 52 electrically connected to the first electrode 32 and the conductive layer 60 provided so as to cover the second wiring layer 52, provided along the outer periphery of the substrate 10 in plan view. Therefore, in the piezoelectric driving apparatus 100, it is possible to lower the resistance of the member which electrically connects the first electrode 32 and the terminal 80. Due to this, in the piezoelectric driving apparatus 100, it is possible to improve the efficiency of the voltage applied to the piezoelectric body layer 34, furthermore, it is possible to reduce the amount of heating of the member which electrically connects the first electrode 32 and the terminal 80. Furthermore, since the thin-film piezoelectric element has a larger capacitance than a bulk piezoelectric element, the impedance of the piezoelectric body layer is reduced. In the piezoelectric driving apparatus 100, lowering the resistance of the member which electrically connects the first electrode 32 and the terminal 80 makes it possible to increase the impedance of the piezoelectric body layer 34, and to increase the voltage applied to the piezoelectric body layer 34. As a result, the piezoelectric driving apparatus 100 can achieve a higher output.

Furthermore, since the piezoelectric driving apparatus 100 includes the piezoelectric element 30 which is a thin-film piezoelectric element, it is possible to reduce the size thereof in comparison with a case of including a bulk piezoelectric element.

Here, the heat treatment is performed in an oxygen atmosphere in order to form the piezoelectric body layer 34 and is performed at 700° C. to 800° C. Therefore, the first electrode 32 is formed of a material which can withstand high temperatures and which includes platinum which is not oxidized. Accordingly, when the resistance of the first electrode is lowered and the output of the piezoelectric driving apparatus is increased by increasing the thickness of the first electrode, the costs are increased. In the piezoelectric driving apparatus 100 according to the present embodiment, it is possible to achieve a higher output while reducing costs.

In the piezoelectric driving apparatus 100, the conductive layer 60 has the gold layer 66 provided so as to cover the Ni—P layer 62. Therefore, in a case where the configuration of the terminals 80, 82, 84, and 86 and the configuration of the conductive layer 60 are the same and the material of the outer external wiring (specifically, the wiring layer 124 of the flexible substrate 120) connected to the terminals 80, 82, 84, and 86 is gold, it is possible to bond the terminals 80, 82, 84, and 86 and the external wiring using a metal bond (an Au—Au bond).

In the piezoelectric driving apparatus 100, the conductive layer 60 has the palladium layer 64 provided between the Ni—P layer 62 and the gold layer 66. Therefore, in the piezoelectric driving apparatus 100, it is possible to suppress diffusion between the Ni—P layer 62 and the gold layer 66 due to the palladium layer 64.

In the piezoelectric driving apparatus 100, the conductive layer 60 is a non-electrolytic plating layer. Therefore, in the piezoelectric driving apparatus 100, for example, selectively attaching palladium as catalyst to the first portion 52a surface of the second wiring layer 52 makes it possible to selectively form the conductive layer 60. Due to this, in the piezoelectric driving apparatus 100, for example, even in a case where the substrate 10 is in a wafer state, it is possible to easily form the conductive layer 60. In addition, even when the distance between the substrate 10 of the first piezoelectric vibrating body 101 and the substrate 10 of the second piezoelectric vibrating body 102 is reduced to approximately 20 μm, it is possible to easily form the conductive layer 60. For example, in a case where the conductive layer 60 is formed by a sputtering method, it is necessary to perform sputtering from a direction perpendicular to the thickness direction of the substrate 10 and it may not be possible to easily form the conductive layer 60.

Furthermore, the non-electrolytic plating layer can be formed simply by immersion in liquid. Therefore, in the piezoelectric driving apparatus 100, forming the conductive layer 60 makes it possible to suppress damage to the second wiring layer 52. In addition, in the piezoelectric driving apparatus 100, for example, it is possible to form the conductive layer 60 at low cost.

In the piezoelectric driving apparatus 100, the metal layer 70 is provided on the second surface 10b of the substrate 10, and the metal layer 70 is connected to the conductive layer 60. Therefore, in the piezoelectric driving apparatus 100, the resistance of the member which electrically connects the first electrode 32 and the terminal 80 can be further decreased.

The piezoelectric driving apparatus 100 includes the first piezoelectric vibrating body 101 and the second piezoelectric vibrating body 102 which is bonded to the first piezoelectric vibrating body 101. Therefore, in the piezoelectric driving apparatus 100, it is possible to achieve a higher output in comparison with a case where only one piezoelectric vibrating body is included.

The piezoelectric driving apparatus 100 includes the non-electrolytic plating layer 51 provided so as to cover the first wiring layer 50. Therefore, in the piezoelectric driving apparatus 100, for example, when forming the second insulating layer 42, it is possible to suppress the first wiring layer 50 from being oxidized. Specifically, in a case where the material of the second insulating layer 42 is an organic material, a heat treatment (baking) is performed at the time of forming the second insulating layer 42; however, since the first wiring layer includes copper, the first wiring layer 50 is easily oxidized by the heat treatment. However, in the piezoelectric driving apparatus 100, since the non-electrolytic plating layer 51 is provided so as to cover the first wiring layer 50, it is possible to suppress the oxidation of the first wiring layer 50 due to the non-electrolytic plating layer 51.

The motor 130 includes the piezoelectric driving apparatus 100. Therefore, the motor 130 can achieve an increased output and a reduction in size.

### 1.2. Method of Manufacturing Piezoelectric Driving Apparatus

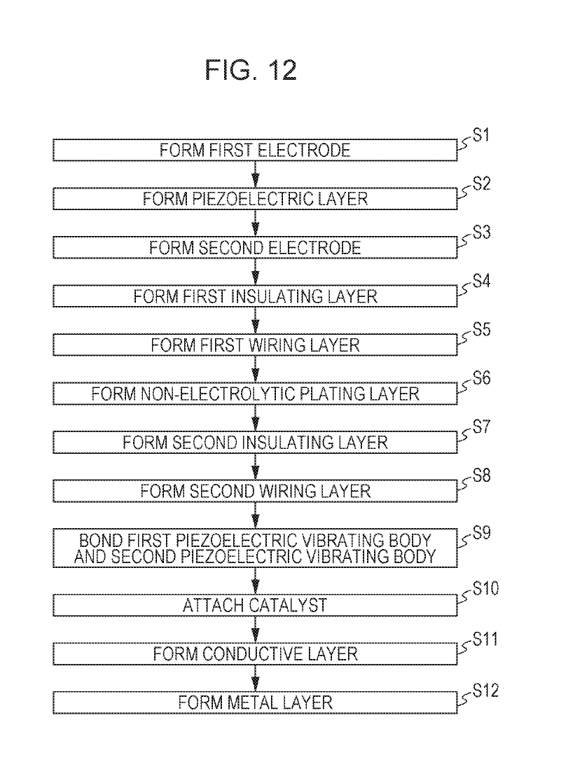

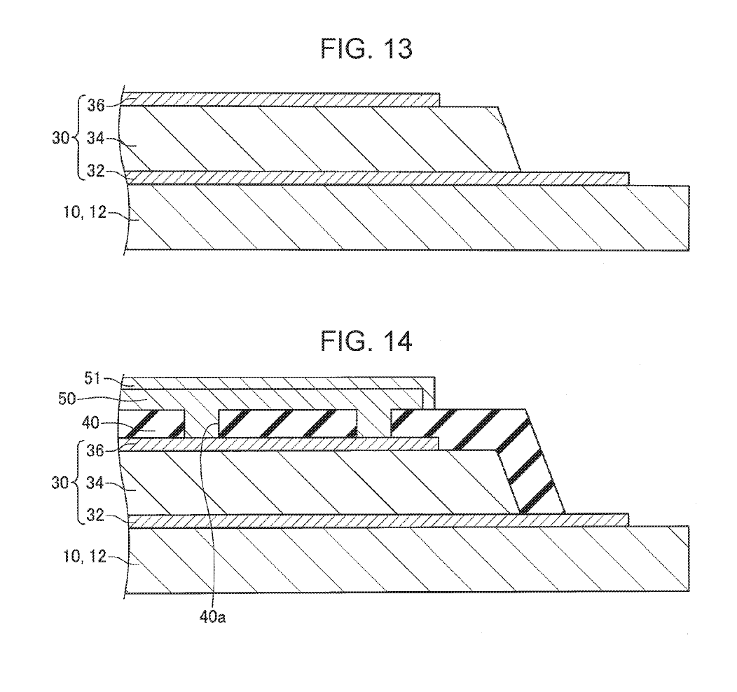

Next, description will be given of a method of manufacturing a piezoelectric driving apparatus 100 according to the first embodiment with reference to the drawings. FIG. 12 is a flow chart for illustrating a method of manufacturing a piezoelectric driving apparatus 100 according to the first embodiment. FIG. 13 to FIG. 16 are cross-sectional views which schematically show manufacturing steps of the piezoelectric driving apparatus 100 according to the first embodiment.

The first piezoelectric vibrating body 101 and the second piezoelectric vibrating body 102 are basically formed by the same manufacturing method. Accordingly, description will be given below of the method of manufacturing the first piezoelectric vibrating body 101 using FIGS. 6, 13, and 14. The description of the method of manufacturing the first piezoelectric vibrating body 101 can basically be applied to the method of manufacturing the second piezoelectric vibrating body 102.

As shown in FIG. 13, the first electrode 32 is formed on the vibrating body portion 12 of the substrate 10 (S1). The first electrode 32 is formed by, for example, film-forming using a sputtering method, a chemical vapor deposition (CVD) method, a vacuum deposition method, and the like, and patterning (patterning by photolithography and etching). In the present step, it is possible to form the first conductive layer 33 on the support portion 14 and the connecting portions 16 and 18 of the substrate 10 (refer to FIG. 8).

Here, the substrate 10 may be in a wafer state. That is, although not shown, a frame portion is provided on the periphery of the substrate 10 and the substrate 10 may be connected to the frame portion via a cut-away portion. In such a case, the substrate 10, the frame portion, and the cut-away portion are integrally provided.

Next, the piezoelectric body layer 34 is formed on the first electrode 32 (S2). The piezoelectric body layer 34 is, for example, formed by patterning after repeating the forming of the precursor layer by a liquid phase method and the crystallization of the precursor layer. The liquid phase method is a method of forming a film with a thin-film material using a raw material solution which includes a constituent material of the thin film (piezoelectric body layer), specifically, a sol-gel method, a metal organic deposition (MOD) method, or the like. The crystallization is performed by a heat treatment at 700° C. to 800° C. in an oxygen atmosphere. In this step, it is possible to form the insulating layer 35 on the first conductive layer 33 (refer to FIG. 8).

Next, the second electrode 36 is formed on the piezoelectric body layer 34 (S3). The second electrode 36 is, for example, formed with the same method as the first electrode 32. Although not shown, the patterning of the second electrode 36 and the patterning of the piezoelectric body layer 34 may be performed as the same step. In this step, it is possible to form the second conductive layer 37 on the insulating layer 35 (refer to FIG. 8).

Through the above steps, it is possible to form the piezoelectric element 30 on the vibrating body portion 12 of the substrate 10.

As shown in FIG. 14, the first insulating layer 40 is formed so as to cover the piezoelectric element 30 (S4). The first insulating layer 40 is, for example, formed by a spin coating method, or a CVD method. Next, the contact hole 40a is formed by patterning the first insulating layer 40. In a case where the material of the first insulating layer 40 is a photosensitive material, the first insulating layer 40 can be patterned by exposure, developing, and baking without etching. Here, in a case where the material of the first insulating layer 40 is not a photosensitive material, the first insulating layer 40 is patterned by photolithography and etching.

Next, the first wiring layer 50 is formed on the second electrode 36 and on the first insulating layer 40 (S5). The first wiring layer 50 is formed by, for example, a plating (electroplating) method, film-forming by sputtering and patterning, or the like.

Next, the non-electrolytic plating layer 51 is formed so as to cover the first wiring layer 50 (S6). The non-electrolytic plating layer 51 is formed by non-electrolytic plating. Specifically, after selectively attaching palladium as a catalyst to the surface of the first wiring layer 50, the non-electrolytic plating layer 51 is selectively formed on the surface of the first wiring layer 50 by non-electrolytic plating.

As shown in FIG. 6, the second insulating layer 42 is formed so as to cover the non-electrolytic plating layer 51 (S7). Next, the contact hole 42a is formed by patterning the second insulating layer 42. The second insulating layer 42 and the contact hole 42a are, for example, respectively formed by the same methods as the first insulating layer 40 and the contact hole 40a. For example, in a case of baking the second insulating layer 42, it is possible to suppress the first wiring layer 50 from oxidizing due to the non-electrolytic plating layer 51. Here, as shown in FIG. 6, the third insulating layer 44 may be formed on the second insulating layer 42. The third insulating layer 44 is, for example, formed in the same manner as the first insulating layer 40.

Next, the second wiring layer 52 is formed on the electrodes 32 and 36 and the second insulating layer 42 (S8). The second wiring layer 52 is, for example, formed in the same manner as the first wiring layer 50. Specifically, the first portion 52a of the second wiring layer 52 electrically connected to the first electrode 32 is formed along the outer periphery of the substrate 10 in plan view. Furthermore, the second portion 52b of the second wiring layer 52 electrically connected to the second electrode 36 is formed.

Through the above steps, it is possible to form the first piezoelectric vibrating body 101 and the second piezoelectric vibrating body 102. Here, in a case where the substrate 10 is in a wafer state, the first piezoelectric vibrating body 101 and the second piezoelectric vibrating body 102 may be formed on different wafers.

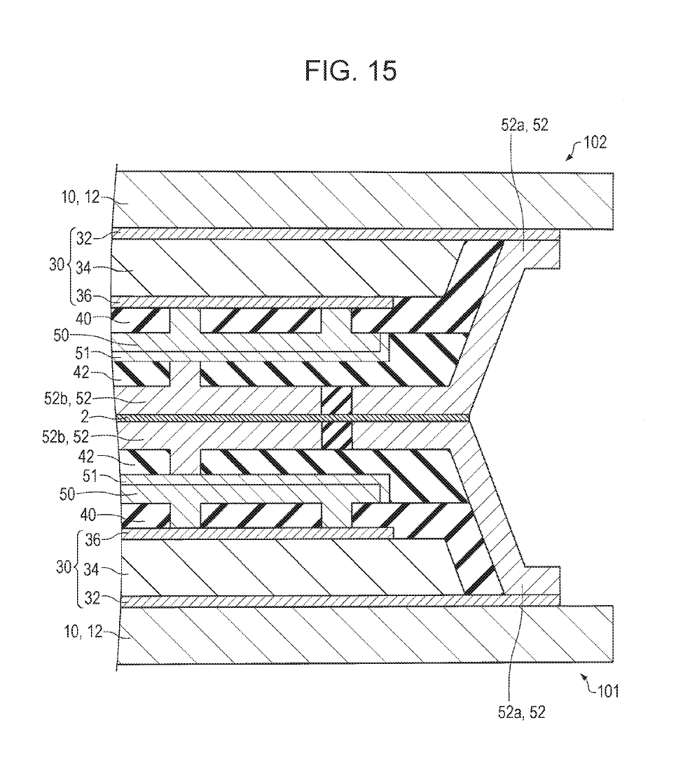

As shown in FIG. 15, the first piezoelectric vibrating body 101 and the second piezoelectric vibrating body 102 are bonded (S9). Specifically, the second wiring layer 52 of the first piezoelectric vibrating body 101 and the second wiring layer 52 of the second piezoelectric vibrating body 102 are bonded via the adhesive 2.

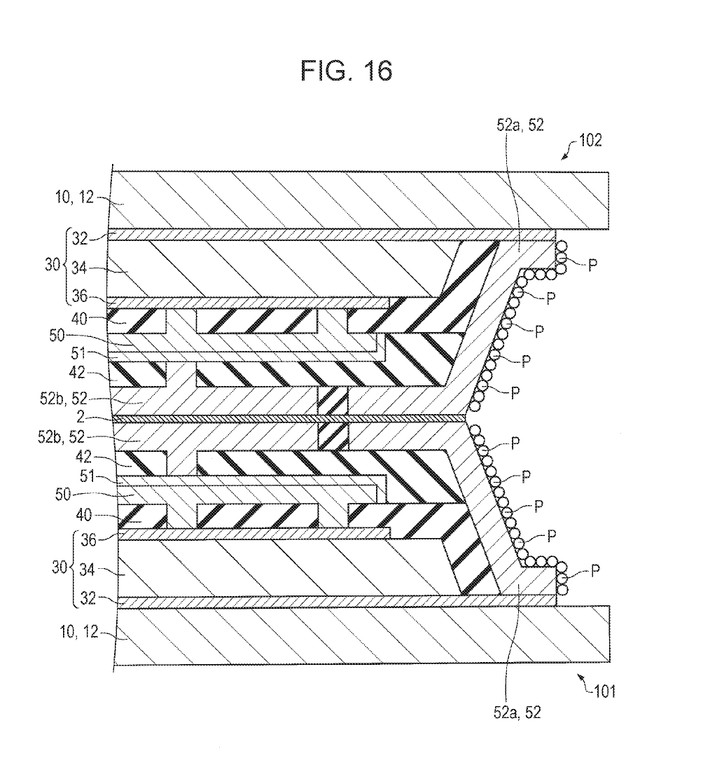

As shown in FIG. 16, palladium P as a catalyst for non-electrolytic plating is selectively attached to the exposed portion of the first portion 52a of the second wiring layer 52 (S10). The palladium P is, for example, attached by a known method.

As shown in FIG. 7, the conductive layer 60 is formed so as to cover the second wiring layer 52 (S11). Specifically, the conductive layer 60 is selectively formed on the portion of the first portion 52a where the palladium P is attached. The conductive layer 60 is formed by non-electrolytic plating. The Ni—P layer 62 of the conductive layer 60 is, for example, formed by the reduction of the nickel layer with hypophosphorous acid (formed by reduction type non-electrolytic plating). The palladium layer 64 and gold layer 66 of the conductive layer 60 are, for example, formed by substitution type non-electrolytic plating.

Next, the metal layer 70 is formed on the surfaces 10b and 10c of the substrate 10 (S12). The metal layer 70 is formed so as to be connected to the conductive layer 60. The metal layer 70 is, for example, formed by a sputtering method.

Here, although not shown, in a case where the substrate 10 is a wafer state, after step (S12), a cut-away portion is cut away by etching or the like to separate the substrate 10 from the frame portion (chip forming).

Through the above steps, it is possible to manufacture the piezoelectric driving apparatus 100.

The manufacturing method of the piezoelectric driving apparatus 100 includes a step (S8) of forming the second wiring layer 52 electrically connected to the first electrode 32 along the outer periphery of the substrate 10 in plan view, and a step (S11) of forming the conductive layer 60 which is a non-electrolytic plating layer so as to cover the layer which includes the second wiring layer. Therefore, in the manufacturing method of the piezoelectric driving apparatus 100, it is possible to manufacture the piezoelectric driving apparatus 100 which can achieve a high output.

Furthermore, in the manufacturing method of the piezoelectric driving apparatus 100, including a step (S1) of forming the first electrode 32 on the substrate 10, a step (S2) of forming the piezoelectric body layer 34 on the first electrode 32, and a step (S3) of forming the second electrode 36 on the piezoelectric body layer 34 makes it possible to form the piezoelectric element 30 which is a thin-film piezoelectric element. Therefore, in the manufacturing method of the piezoelectric driving apparatus 100, it is possible to manufacture the piezoelectric driving apparatus 100 which can be miniaturized in comparison with a case of including the bulk piezoelectric element.

### 1.3. Modification Example of Piezoelectric Driving Apparatus

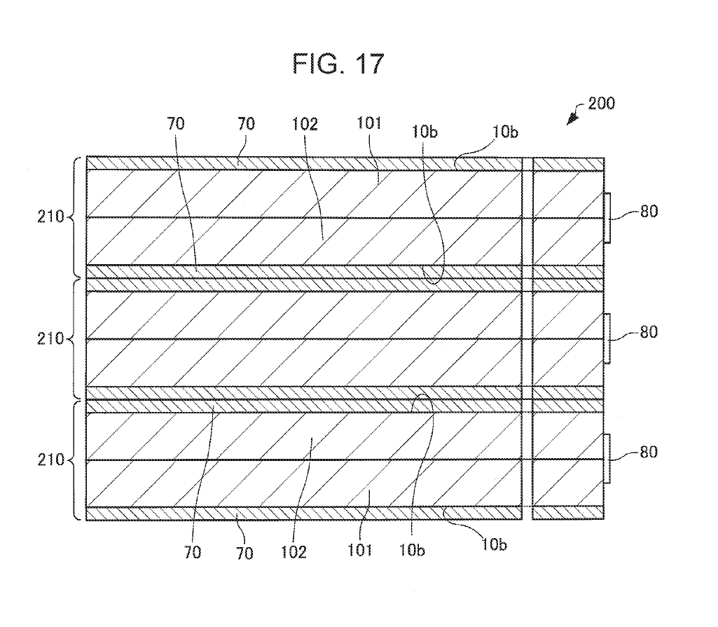

Next, description will be given of the piezoelectric driving apparatus according to a modification example of the first embodiment with reference to the drawings. FIG. 17 is a cross-sectional view schematically showing a piezoelectric driving apparatus 200 according to a modification example of the first embodiment. Here, for the sake of convenience, FIG. 17 illustrates a first piezoelectric vibrating body 101 and a second piezoelectric vibrating body 102 in a simplified manner.

Below, in the piezoelectric driving apparatus 200 according to the modification example of the first embodiment, the constituent members of the piezoelectric driving apparatus 100 of the first embodiment and the members having the same functions are given the same reference numerals and the details thereof will be omitted.

As shown in FIG. 2, in the piezoelectric driving apparatus 100 described above, the first piezoelectric vibrating body 101 and the second piezoelectric vibrating body 102 are included one by one. In contrast, the piezoelectric driving apparatus 200 includes a plurality of each of the first piezoelectric vibrating body 101 and the second piezoelectric vibrating body 102.

In the piezoelectric driving apparatus 200, the first piezoelectric vibrating body 101 and the second piezoelectric vibrating body 102 form a bonded body 210. The bonded body 210 has the metal layer 70. A plurality of the bonded bodies 210 are provided. In the illustrated example, three of the bonded body 210 are provided. A plurality of the bonded bodies 210 are laminated in the thickness direction of the substrate 10.

In the adjacent bonded bodies 210, the metal layer 70 of one of the bonded bodies 210 and the metal layer 70 of the other bonded body 210 are bonded. For example, in a case where the metal layers 70 are gold layers, the metal layer 70 of one of the bonded bodies 210 and the metal layer 70 of the other bonded body 210 are bonded by metal bonding (Au—Au bond). Due to this, it is possible to strongly bond the adjacent bonded bodies 210 without using an adhesive. Here, although not shown, the metal layer 70 of one of the bonded bodies 210 and the metal layer 70 of the other bonded body 210 may be bonded by a conductive adhesive.

In the piezoelectric driving apparatus 200, a plurality of bonded bodies 210 are laminated in the thickness direction of the substrate 10. Therefore, in the piezoelectric driving apparatus 200, it is possible to increase the output in comparison with a case where only one bonded body 210 is formed.

### 2. Second Embodiment

### 2.1. Piezoelectric Driving Apparatus

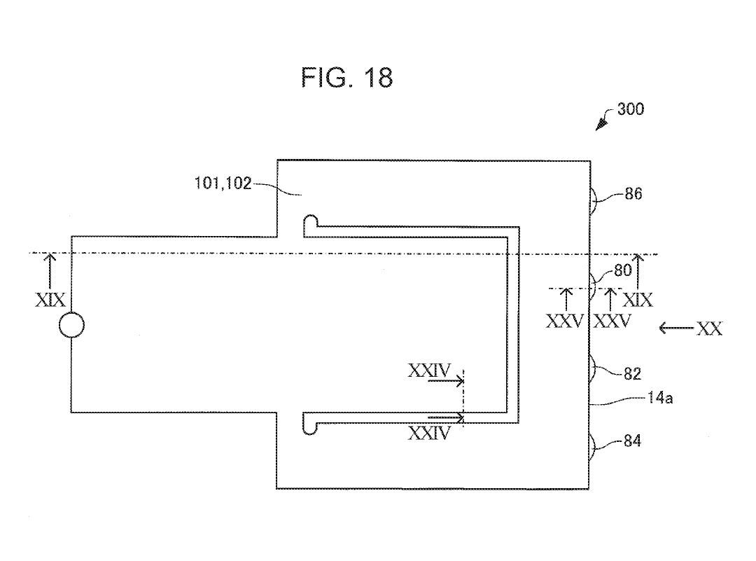

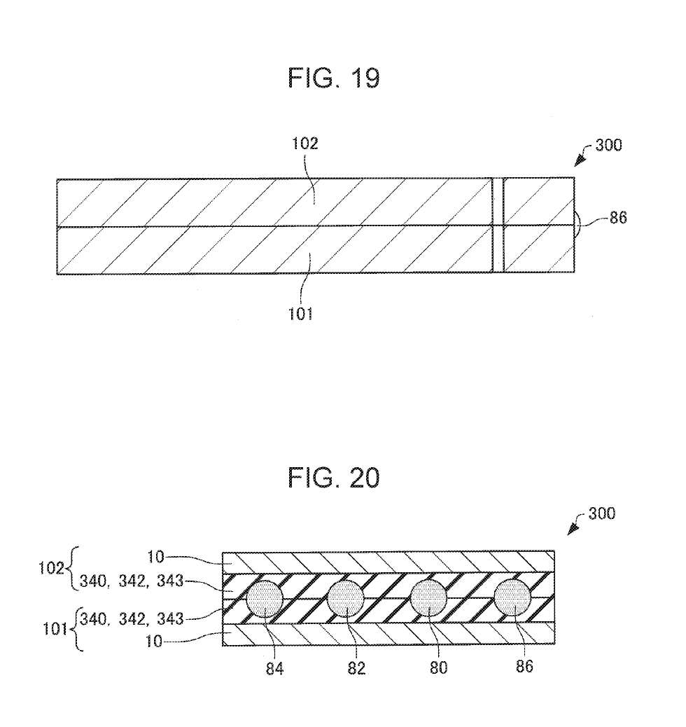

Next, description will be given of a piezoelectric driving apparatus according to a second embodiment with reference to the drawings. FIG. 18 is a plan view which schematically shows a piezoelectric driving apparatus 300 according to the second embodiment. FIG. 19 is cross-sectional view taken along a line XIX-XIX in FIG. 18 which schematically shows the piezoelectric driving apparatus 300 according to the second embodiment. FIG. 20 is a diagram viewed from the direction of the arrow XX in FIG. 18 which schematically shows the piezoelectric driving apparatus 300 according to the second embodiment.

As shown in FIG. 18 to FIG. 20, the piezoelectric driving apparatus 300 includes the first piezoelectric vibrating body 101 and the second piezoelectric vibrating body 102 which is bonded to the first piezoelectric vibrating body 101. Here, FIG. 19 and FIG. 20 show the piezoelectric vibrating bodies 101 and 102 in a simplified manner.

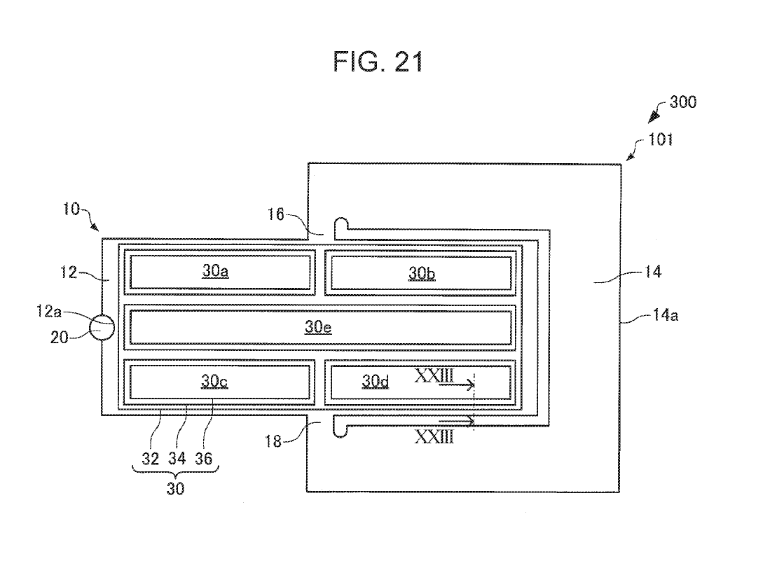

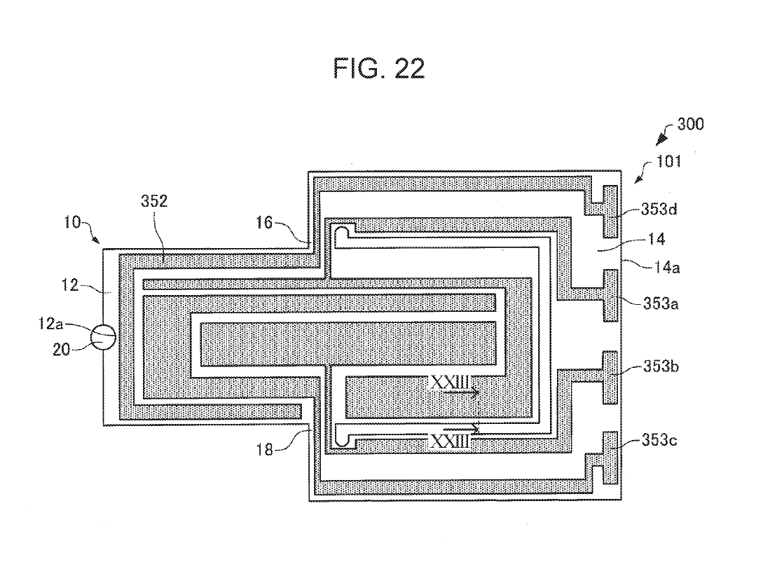

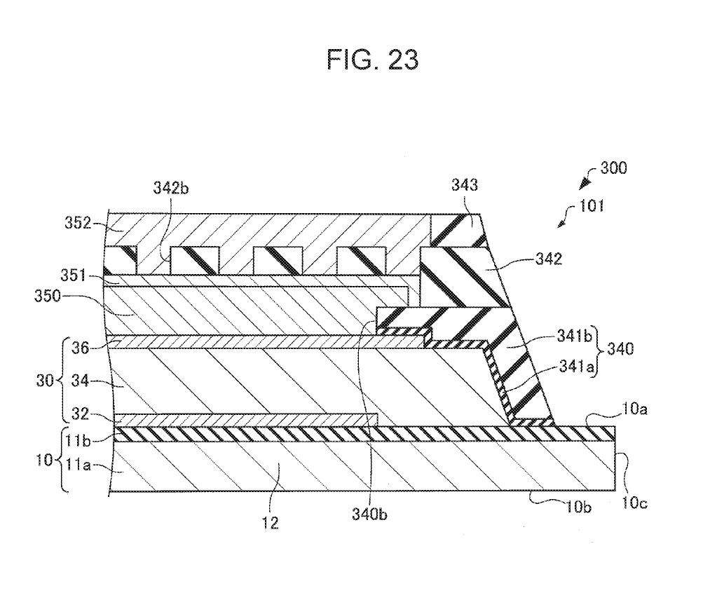

Here, FIG. 21 is a plan view which schematically shows the first piezoelectric vibrating body 101. FIG. 22 is a plan view which schematically shows the first piezoelectric vibrating body 101. FIG. 23 is a cross-sectional view taken along a line XXIII-XXIII in FIG. 21 and FIG. 22 which schematically shows the first piezoelectric vibrating body 101. The first piezoelectric vibrating body 101 and the second piezoelectric vibrating body 102 basically have the same configuration. Therefore, in the following, description will be given of the first piezoelectric vibrating body 101 using FIG. 21 to FIG. 23. The description in the first piezoelectric vibrating body 101 can basically be applied to the second piezoelectric vibrating body 102.

As shown in FIG. 21 to FIG. 23, the first piezoelectric vibrating body 101 includes the substrate 10, the contact portion 20, the piezoelectric element 30, and insulating layers 340, 342, and 343, and wiring layers 350 and 352. Here, for the sake of convenience, the illustration of members other than the substrate 10, the contact portion 20, and the piezoelectric element 30 is omitted in FIG. 21. In addition, the illustration of members other than the substrate 10 and the wiring layer 352 is omitted in FIG. 22.

As shown in FIG. 23, the substrate 10 has the first surface 10a, the second surface 10b on the side opposite to the first surface 10a, and the third surface 10c which connects the first surface 10a and the second surface 10b. The piezoelectric element 30 is provided on the first surface 10a. The third surface 10c is a side surface of the substrate 10.

The substrate 10 is, for example, formed of a silicon substrate 11a and an underlayer 11b provided on the silicon substrate 11a. The underlayer 11b is an insulating layer. The underlayer 11b is, for example, formed of a laminated body of a silicon oxide layer provided on the silicon substrate 11a, and a zirconium oxide layer provided on the silicon oxide layer.

As shown in FIG. 21, the substrate 10 has the vibrating body portion 12, the support portion 14, the first connecting portion 16, and the second connecting portion 18. The planar shape of the vibrating body portion 12 (the shape as viewed from the thickness direction of the substrate 10) is substantially rectangular. The piezoelectric element 30 is provided on the vibrating body portion 12 and the vibrating body portion 12 can vibrate according to changes in the shape of the piezoelectric element 30. The support portion 14 supports the vibrating body portion 12 via the connecting portions 16 and 18. In the illustrated example, the connecting portions 16 and 18 extend from the central portion in the longitudinal direction of the vibrating body portion 12 in the direction perpendicular to the longitudinal direction and connect to the support portion 14.

The contact portion 20 is provided on the vibrating body portion 12. In the illustrated example, the concave portion 12a is provided in the vibrating body portion 12 and the contact portion 20 is fitted into and bonded to (for example, adhered to) the concave portion 12a. The contact portion 20 is a member which comes in contact with a driven member to transmit the movement of the vibrating body portion 12 to the driven member. The material of the contact portion 20 is, for example, a ceramic (specifically, alumina (Al₂O₃)), zirconia (ZrO₂), silicon nitride (Si₃N), or the like).

The piezoelectric element 30 is provided on the substrate 10. The piezoelectric element 30 is provided on the first surface 10a of the substrate 10. The piezoelectric element 30 is provided on the vibrating body portion 12. The piezoelectric element 30 has the first electrode 32, the piezoelectric body layer 34, and the second electrode 36.

The first electrode 32 is provided on the vibrating body portion 12. In the illustrated example, the planar shape of the first electrode 32 is a rectangle. The first electrode 32 may be formed by an iridium layer provided on the vibrating body portion 12 and a platinum layer provided on the iridium layer. The thickness of the iridium layer is, for example, 5 nm to 100 nm. The thickness of the platinum layer is, for example, 50 nm to 300 nm. Here, the first electrode 32 may be a metal layer formed of Ti, Pt, Ta, Ir, Sr, In, Sn, Au, Al, Fe, Cr, Ni, Cu, and the like or a mixture or a laminate of two or more types thereof. The first electrode 32 is one electrode for applying a voltage to the piezoelectric body layer 34.

The piezoelectric body layer 34 is provided on the first electrode 32. In the illustrated example, the planar shape of the piezoelectric body layer 34 is a rectangle. The thickness of the piezoelectric body layer 34 is, for example, 50 nm to 20 μm, preferably 1 μm to 7 μm. In this manner, the piezoelectric element 30 is a thin-film piezoelectric element. When the thickness of the piezoelectric body layer 34 is less than 50 nm, the output of the piezoelectric driving apparatus 300 may be reduced. Specifically, when attempting to increase the output and increase the applied voltage to the piezoelectric body layer 34, the piezoelectric body layer 34 may cause dielectric breakdown. When the thickness of the piezoelectric body layer 34 is greater than 20 μm, cracks may occur in the piezoelectric body layer 34.

As the piezoelectric body layer 34, a perovskite-type oxide piezoelectric material is used. Specifically, the material of the piezoelectric body layer 34 is, for example, lead zirconate titanate (Pb(Zr,Ti)O₃: PZT), or lead zirconate titanate niobate (Pb(Zr,Ti,Nb)O₃: PZTN). It is possible to change the shape of (expand and contract) the piezoelectric body layer 34 by applying a voltage using the electrodes 32 and 36.

The second electrode 36 is provided on the piezoelectric body layer 34. In the illustrated example, the planar shape of the second electrode 36 is a rectangle. The second electrode 36 may be formed of the adhesive layer provided on the piezoelectric body layer 34, and a conductive layer provided on the adhesive layer. The thickness of the adhesive layer is, for example, 10 nm to 100 nm. The adhesive layer is, for example, a TiW layer, a Ti layer, a Cr layer, a NiCr layer, or a laminate thereof. The thickness of the conductive layer is, for example, 1 μm to 10 μm. The conductive layer is, for example, a Cu layer, an Au layer, an Al layer, or a laminate thereof. The second electrode 36 is the other electrode for applying a voltage to the piezoelectric body layer 34.

As shown in FIG. 21, a plurality of the piezoelectric elements 30 are provided. In the illustrated example, five of the piezoelectric elements 30 are provided (the piezoelectric elements 30a, 30b, 30c, 30d, and 30e). In plan view (as viewed from the thickness direction of the substrate 10), for example, the areas of the piezoelectric elements 30a to 30d are the same and the piezoelectric element 30e has an area larger than that of the piezoelectric elements 30a to 30d. The piezoelectric element 30e is provided in the longitudinal direction of the vibrating body portion 12 in the central portion in the lateral direction of the vibrating body portion 12. The piezoelectric elements 30a, 30b, 30c, and 30d are provided at the four corners of the vibrating body portion 12. In the illustrated example, in the piezoelectric elements 30a to 30e, the first electrode 32 is provided as one continuous conductive layer.

As shown in FIG. 23, the insulating layer 340 is provided so as to cover the piezoelectric element 30. The insulating layer 340 has, for example, an inorganic insulating layer 341a provided on the piezoelectric element 30, and an organic insulating layer 341b provided on the inorganic insulating layer 341a. The material of the inorganic insulating layer 341a is, for example, an inorganic material such as silicon oxide or aluminum oxide. The material of the organic insulating layer 341b is, for example, an organic material such as an epoxy-based resin, an acrylic-based resin, a polyimide-based resin, or a silicone-based resin. The material of the organic insulating layer 341b may be a photosensitive material.

The wiring layer 350 is provided on the second electrode 36. The wiring layer 350 is electrically connected to the second electrode 36. In the illustrated example, the wiring layer 350 is provided on the insulating layer 340 and a contact hole 340b formed in the insulating layer 340, and is connected to the second electrode 36.

The wiring layer 350 is a layer including copper. The wiring layer 350 may be formed of a titanium tungsten layer, and a copper layer provided on the titanium tungsten layer. In the illustrated example, the wiring layer 350 is covered with a non-electrolytic plating layer 351 which is formed by non-electrolytic plating. The non-electrolytic plating layer 351 may be formed of a layer (Ni—P layer) including nickel and phosphorus. Alternatively, the non-electrolytic plating layer 351 may be formed of a Ni—P layer, and a gold layer provided on the Ni—P layer. Alternatively, the non-electrolytic plating layer 351 may be formed of a Ni—P layer, a palladium layer provided on the Ni—P layer, and a gold layer provided on the palladium layer.

The insulating layer 342 is provided so as to cover the wiring layer 350. In the illustrated example, the insulating layer 342 is provided so as to cover the wiring layer 350 via the non-electrolytic plating layer 351. The material of the insulating layer 342 may be an inorganic material such as silicon oxide or aluminum oxide, or may be an organic material such as an epoxy-based resin, an acrylic-based resin, a polyimide-based resin, or a silicone-based resin. The material of the insulating layer 342 may be a photosensitive material.

The insulating layer 343 is provided on the insulating layer 342. The insulating layer 343 has, for example, the role of a wall for forming the wiring layer 352 on the insulating layer 342. The material of the insulating layer 343 may be an inorganic material such as silicon oxide or aluminum oxide, or may be an organic material such as an epoxy-based resin, an acrylic-based resin, a polyimide-based resin, or a silicone-based resin. The material of the insulating layer 343 may be a photosensitive material.

The wiring layer 352 is provided on the non-electrolytic plating layer 351. In the example shown in FIG. 23, the wiring layer 352 is electrically connected to the second electrode 36 via the non-electrolytic plating layer 351 and the wiring layer 350. That is, the wiring layer 352 is electrically connected to the piezoelectric element 30. In the illustrated example, the wiring layer 352 is connected to the second electrode 36 via a contact hole 342b formed in the insulating layer 342. The material of the wiring layer 352 is, for example, the same as the material of the wiring layer 350.

As shown in FIG. 22, the wiring layer 352 has a first portion 353a, a second portion 353b, a third portion 353c, and a fourth portion 353d. The first portion 353a is electrically connected to the second electrodes 36 of the piezoelectric elements 30a and 30d. In plan view, the first portion 353a extends from the vibrating body portion 12 through the first connecting portion 16 to the vicinity of the side 14a (side of the opposite side to the contact portion 20) of the support portion 14. The second portion 353b is electrically connected to the second electrode 36 of the piezoelectric element 30e. In plan view, the second portion 353b extends from the vibrating body portion 12 through the second connecting portion 18 up to the vicinity of the side 14a. The third portion 353c is electrically connected to the second electrode 36 of the piezoelectric elements 30b and 30c. In plan view, the third portion 353c extends from the vibrating body portion 12 through the second connecting portion 18 up to the vicinity of the side 14a. The fourth portion 353d is electrically connected to the first electrode 32. In plan view, the fourth portion 353d extends from the vibrating body portion 12 through the first connecting portion 16 up to the vicinity of the side 14a.

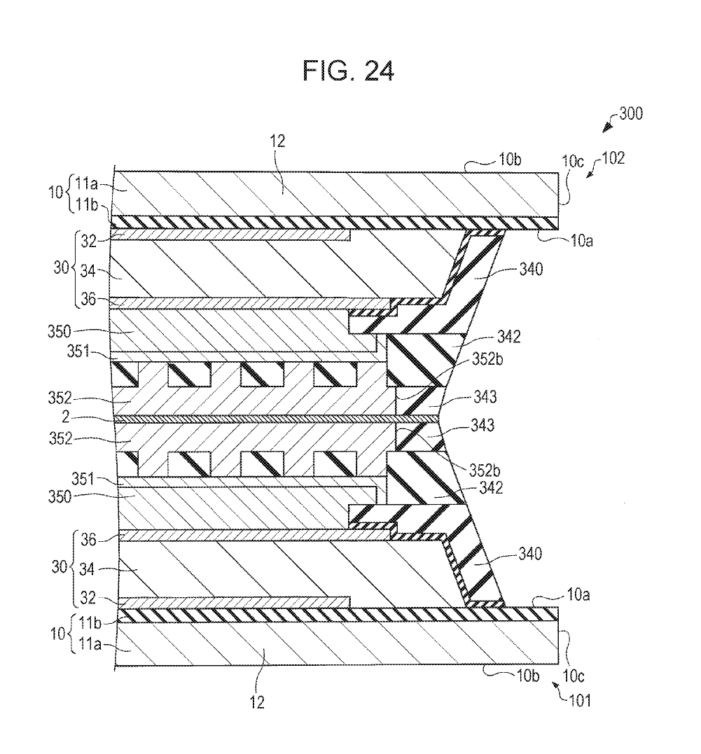

FIG. 24 is a cross-sectional view taken along a line XXIV-XXIV of FIG. 18 which schematically shows the piezoelectric driving apparatus 300. As shown in FIG. 24, the first piezoelectric vibrating body 101 and the second piezoelectric vibrating body 102 are laminated in the thickness direction of the substrate 10. The piezoelectric vibrating bodies 101 and 102 are bonded such that the first surface 10a of the first piezoelectric vibrating body 101 and the first surface 10a of the second piezoelectric vibrating body 102 are opposed. Specifically, the wiring layer 352 of the first piezoelectric vibrating body 101 and the wiring layer 352 of the second piezoelectric vibrating body 102 are bonded. In the illustrated example, the wiring layer 352 of the first piezoelectric vibrating body 101 and the wiring layer 352 of the second piezoelectric vibrating body 102 are bonded via the adhesive 2. The adhesive 2 is, for example, a conductive adhesive. Due to this, the wiring layer 352 of the first piezoelectric vibrating body 101 and the wiring layer 352 of the second piezoelectric vibrating body 102 can be electrically connected. the distance between the substrate 10 of the first piezoelectric vibrating body 101 and the substrate 10 of the second piezoelectric vibrating body 102 is, for example, approximately 20 μm.

Here, the wiring layer 352 of the first piezoelectric vibrating body 101 and the wiring layer 352 of the second piezoelectric vibrating body 102 may be bonded by a metal bond (Cu—Cu bond or Au—Au bond). Due to this, the piezoelectric vibrating bodies 101 and 102 can be strongly bonded to without using an adhesive.

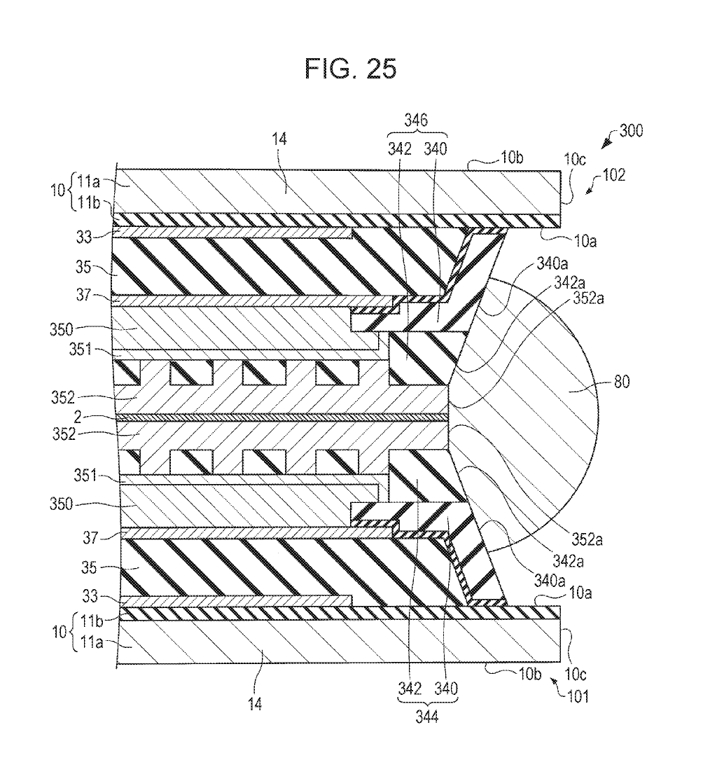

FIG. 25 is a cross-sectional view taken along a line XXV-XXV in FIG. 18 which schematically shows the piezoelectric driving apparatus 300. As shown in FIG. 25, the insulating layer 340 of the piezoelectric vibrating bodies 101 and 102 has a side surface 340a. The insulating layer 342 of the piezoelectric vibrating bodies 101 and 102 has a side surface 342a connected to the side surface 340a. The wiring layers 352 of the piezoelectric vibrating bodies 101 and 102 have side surfaces 352a connected to the side surface 342a. As shown in FIGS. 18 to 20 and 25, the piezoelectric driving apparatus 300 has the terminals 80, 82, 84, and 86.

Here, the substrate 10 of the first piezoelectric vibrating body 101 is the first substrate. The piezoelectric element 30 of the first piezoelectric vibrating body 101 is the first piezoelectric element. The wiring layer 352 of the first piezoelectric vibrating body 101 is the first wiring layer. The insulating layers 340 and 342 of the first piezoelectric vibrating body 101 form a first insulating portion 344. The first insulating portion 344 is provided between the first substrate and the first wiring layer.

In addition, the substrate 10 of the second piezoelectric vibrating body 102 is the second substrate. The piezoelectric element 30 of the second piezoelectric vibrating body 102 and the wiring layer 352 of the second piezoelectric vibrating body 102 which is the second piezoelectric element are the second wiring layer. The insulating layers 340 and 342 of the second piezoelectric vibrating body 102 form a second insulating portion 346. The second insulating portion 346 is provided between the second substrate and the second wiring layer.

As shown in FIG. 25, the terminal 80 is connected to the side surface 352a of the wiring layer 352 of the piezoelectric vibrating bodies 101 and 102. In the illustrated example, as shown in FIG. 25, the terminal 80 is also connected to a portion of the side surface 340a of the insulating layer 340 of the piezoelectric vibrating bodies 101 and 102 and to the side surface 342a of the insulating layer 342. That is, the terminal 80 is provided on a portion of the side surface 340a and the side surfaces 342a and 352a. The terminal 80 is provided so as to protrude further outward than the side surface 10c of the substrate 10 of the piezoelectric vibrating bodies 101 and 102. That is, as shown in FIG. 18, in plan view, the terminal 80 has a portion which does not overlap the piezoelectric vibrating bodies 101 and 102. In plan view, the terminal 80 protrudes outward from the side 14a of the support portion 14. The side 14a is, for example, a side formed by the side surface 10c. The terminal 80 is provided to be separated without contacting the substrate 10 of the piezoelectric vibrating bodies 101 and 102. The terminals 82, 84, and 86, for example, have the same shape and size as the terminal 80.

The terminals 80, 82, 84, and 86 are non-electrolytic plating layers formed by non-electrolytic plating. The terminals 80 to 86 may be formed of a layer (Ni—P layer) including nickel and phosphorus. Alternatively, the terminals 80 to 86 may be formed of a Ni—P layer, and a gold layer provided so as to cover the Ni—P layer. Alternatively, the terminals 80 to 86 may be formed of a Ni—P layer, a palladium layer provided so as to cover the Ni—P layer, and a gold layer provided so as to cover the palladium layer.

Here, as shown in FIG. 24, a side surface 352b other than the side surface 352a where the terminals 80, 82, 84, and 86 of the wiring layer 352 are provided is, for example, covered with the insulating layer 343. Therefore, a terminal (non-electrolytic plating layer) is not formed on the side surface 352b of the wiring layer 352. Due to this, it is possible to suppress wastage of the non-electrolytic plating material. Furthermore, since non-electrolytic plating is not performed on unnecessary portions, it is possible to suppress inhibition of the movement of the piezoelectric driving apparatus 300 by the non-electrolytic plating layer to a corresponding extent.

The terminal 80 is, for example, electrically connected to the second electrodes 36 of the piezoelectric elements 30a and 30d via the first portion 353a of the wiring layer 352. The terminal 82 is, for example, electrically connected to the second electrode 36 of the piezoelectric element 30e via the second portion 353b of the wiring layer 352. The terminal 84 is, for example, electrically connected to the second electrodes 36 of the piezoelectric elements 30b and 30c via the third portion 353c of the wiring layer 352. The terminal 86 is, for example, electrically connected to the first electrode 32 of the piezoelectric elements 30a, 30b, 30c, and 30d, and 30e via the fourth portion 353d of the wiring layer 352. The terminal 86 may have a reference potential as a ground. In the piezoelectric driving apparatus 300, connecting the terminals 80 to 86 and the driving circuit makes it possible to apply a voltage to the piezoelectric body layer 34 of the piezoelectric elements 30a to 30e and to vibrate the vibrating body portion 12.

As shown in FIG. 25, in the piezoelectric vibrating bodies 101 and 102 of the piezoelectric driving apparatus 300, the first conductive layer 33, the insulating layer 35, the second conductive layer 37, the insulating layers 340 and 342, the wiring layers 350 and 352, and the non-electrolytic plating layer 351 are provided on the support portion 14 and the connecting portions 16 and 18. Due to this, for example, in each of the piezoelectric vibrating bodies 101 and 102, the difference in the thickness (height) in the members provided on the vibrating body portion 12, the support portion 14, and the connecting portions 16 and 18 can be reduced. That is, in each of the piezoelectric vibrating body 101 and 102, it is possible to improve the uniformity of the thickness. Therefore, when laminating the piezoelectric vibrating bodies 101 and 102, it is possible to suppress gaps from being formed between the piezoelectric vibrating bodies 101 and 102. Due to this, it is possible to improve the bonding strength of the piezoelectric vibrating bodies 101 and 102.

Here, the materials of the first conductive layer 33, the insulating layer 35, and the second conductive layer 37 are respectively the same as the materials of the first electrode 32, the piezoelectric body layer 34, and the second electrode 36. The first conductive layer 33, the insulating layer 35, and the second conductive layer 37 can each be formed in the step of forming the first electrode 32, the piezoelectric body layer 34, and the second electrode 36. No voltage is applied to the piezoelectric body layer 34 due to the conductive layers 33 and 37. For example, the first conductive layer 33 is electrically separated from the first electrode 32 and the second conductive layer 37 is electrically separated from the second electrode 36. In the examples shown in FIG. 25, the second conductive layer 37 is electrically connected to the terminal 80, but the second conductive layer 37 may be electrically separated from the terminal 80.

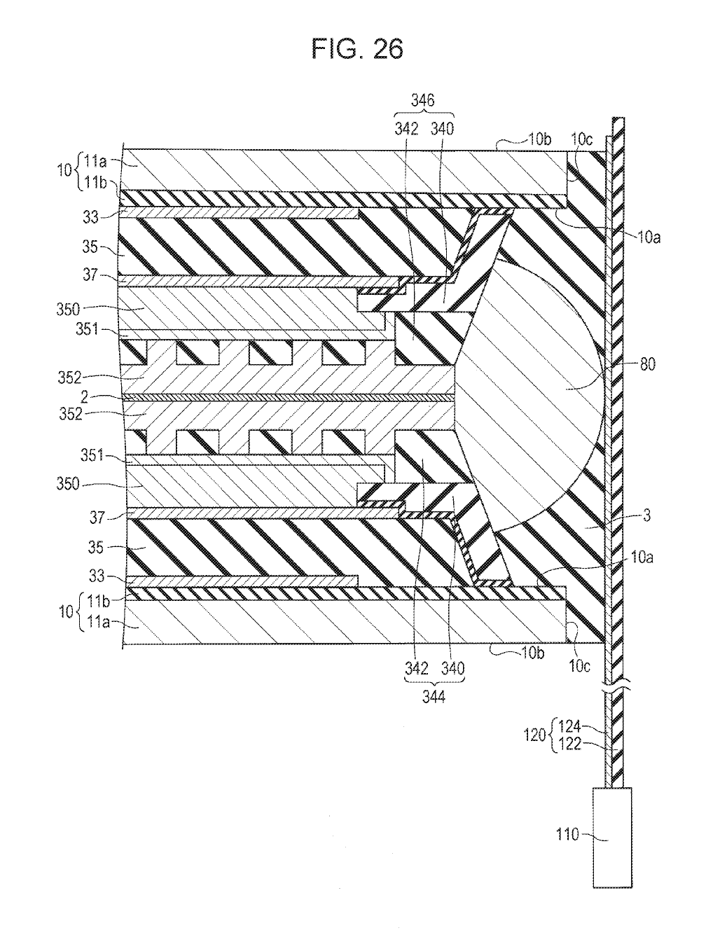

FIG. 26 is a diagram for illustrating an electrical connection method between the terminal 80 and the driving circuit 110 of the piezoelectric driving apparatus 300. Here, for the sake of convenience, FIG. 26 shows the piezoelectric vibrating bodies 101 and 102 in a simplified manner.

As shown in FIG. 26, the terminal 80 is electrically connected to the flexible substrate (external wiring) 120 and the wiring layer 352 of the piezoelectric vibrating bodies 101 and 102. Specifically, the flexible substrate 120 has the insulating substrate 122, and the wiring layer 124 provided on the insulating substrate 122, and the terminal 80 electrically connects the wiring layer 352 and the wiring layer 124. The wiring layer 124 is, for example, a gold layer, or a copper layer. Here, in the same manner as the terminal 80, the terminals 82, 84, and 86 are connected to the flexible substrate (external wiring) 120, and the wiring layer 352 of the piezoelectric vibrating bodies 101 and 102. The flexible substrate 120 electrically connects the terminal 80 and the driving circuit 110.

As shown in FIG. 26, the flexible substrate 120 and the piezoelectric vibrating bodies 101 and 102 are, for example, bonded by an adhesive 3. The adhesive 3 is provided between the flexible substrate 120 and the piezoelectric vibrating bodies 101 and 102 at the periphery of the terminals 80, 82, 84, and 86. The adhesive 3 has, for example, an insulating property.

The piezoelectric driving apparatus 300 has, for example, the following characteristics.

In the piezoelectric driving apparatus 300, the terminals 80, 82, 84, and 86 are connected to the side surface 352a of the wiring layer 352 of the piezoelectric vibrating bodies 101 and 102 and provided so as to protrude outward further than the side surface 10c of the substrate of the piezoelectric vibrating bodies 101 and 102. Therefore, in the piezoelectric driving apparatus 300, the driving circuit 110 and the wiring layer 352 can, for example, be electrically connected by using the flexible substrate 120 as external wiring. Due to this, in the piezoelectric driving apparatus 300, it is possible to reduce the size in comparison with a case where the driving circuit 110 and the wiring layer 352 are electrically connected using a jumper wire. Furthermore, in the piezoelectric driving apparatus 300, the routing of the external wiring can be simplified, and it is possible to easily electrically connect the driving circuit 110 and the wiring layer 352. For example, in a case where the driving circuit 110 and the wiring layer 352 are electrically connected using a jumper wire, in a case where a plurality of piezoelectric vibrating bodies are laminated, space for routing the jumper wire is necessary and the apparatus may increase in size.

In the piezoelectric driving apparatus 300, the terminals 80, 82, 84, and 86 are non-electrolytic plating layers. Therefore, in the piezoelectric driving apparatus 300, for example, it is possible to selectively form the terminals 80 to 86 by selectively attaching palladium as a catalyst to the side surface 352a of the wiring layer 352. Due to this, in the piezoelectric driving apparatus 300, for example, it is possible to easily form the terminals 80 to even when the substrate 10 is in a wafer state. In addition, even when the distance between the substrate 10 of the first piezoelectric vibrating body 101 and the substrate 10 of the second piezoelectric vibrating body 102 is reduced to approximately 20 μm, it is possible to easily form the terminals 80 to 86. For example, in a case of forming the terminals 80 to 86 by a sputtering method, it is necessary to perform sputtering from a direction perpendicular to the thickness direction of the substrate 10 and it may not be possible to easily form the terminals 80 to 86.

Furthermore, the non-electrolytic plating layer can be formed simply by immersion in liquid. Therefore, in the piezoelectric driving apparatus 300, forming the terminals 80 to 86 makes it possible to suppress damage to the wiring layer 352. In addition, in the piezoelectric driving apparatus 300, for example, it is possible to form the terminals 80 to 86 at low cost.

Furthermore, in the piezoelectric driving apparatus 300, for example, it is possible to lower the resistance in comparison with a case of using Ag paste as a terminal. For example, the specific resistance of the Ag paste is 2 Ωcm and the specific resistance of the Ni—P layer of the terminals 80 to 86, which is a non-electrolytic plating layer, is 0.7 Ωcm.

The piezoelectric driving apparatus 300 includes the first insulating portion 344 provided between the substrate 10 and the wiring layer 352 of the first piezoelectric vibrating body 101 and the second insulating portion 346 provided between the substrate 10 and the wiring layer 352 of the second piezoelectric vibrating body 102, and the terminals 80 to 86 are connected to the side surfaces 340a and 342a of the insulating portions 344 and 346. Therefore, in the piezoelectric driving apparatus 300, in a case where the terminals 80 to 86 which are non-electrolytic plating layers are grown isotropically from the side surface 352a of the wiring layer 352, it is possible to suppress the terminals 80 to 86 from coming in contact with the substrate 10 of the piezoelectric vibrating bodies 101 and 102 due to the insulating portions 344 and 346. Due to this, in the piezoelectric driving apparatus 300, between the substrates 10 of the piezoelectric vibrating bodies 101 and 102, it is possible to suppress the leakage current from flowing via the terminals 80 to 86.

In the piezoelectric driving apparatus 300, the substrate 10 is formed of the silicon substrate 11a, and the underlayer 11b which is an insulating layer provided on the silicon substrate 11a. Therefore, in the piezoelectric driving apparatus 300, even when the terminals 80 to 86 are in contact with the substrate 10, it is possible to suppress the leakage current from flowing via the terminals 80 to 86 between the substrates 10 of the piezoelectric vibrating bodies 101 and 102.

Here, the substrate 10 may be formed only of the silicon substrate 11a formed of a high-resistance silicon (for example, a silicon which exceeds 10000 Ωcm). Also in such a case, it is possible to suppress the leakage current from flowing via the terminals 80 to 86 between the substrates 10 of the piezoelectric vibrating bodies 101 and 102. However, in a case of using a high-resistance silicon, the cost is high in comparison with a case of using a normal silicon substrate.

In the piezoelectric driving apparatus 300, the flexible substrate 120 and the piezoelectric vibrating bodies 101 and 102 are bonded to the adhesive 3 which has an insulating characteristic. Therefore, in the piezoelectric driving apparatus 300, it is possible to suppress the leakage current from flowing via the terminals 80 to 86 between the substrates 10 of the piezoelectric vibrating bodies 101 and 102.

In the piezoelectric driving apparatus 300, the terminals 80 to 86 have a gold layer provided so as to cover the Ni—P layer. Therefore, in a case where the material of the wiring layer 124 of the flexible substrate 120 is gold, it is possible to bond the terminals 80 to 86 and the flexible substrate 120 by the metal bond (Au—Au bond). Furthermore, in the piezoelectric driving apparatus 300, for example, due to the Au—Au bond and the adhesive 3, it is possible to strongly bond the flexible substrate 120 and the piezoelectric vibrating bodies 101 and 102. Accordingly, in the piezoelectric driving apparatus 300, due to the vibration of the vibrating body portion 12, it is possible to suppress the cutting of the connection between the flexible substrate 120 and the piezoelectric vibrating bodies 101 and 102. Thus, the piezoelectric driving apparatus 300 can have a high reliability. In addition, it is possible to improve the quality in the piezoelectric driving apparatus 300.

In the piezoelectric driving apparatus 300, the terminals 80 to 86 have a palladium layer provided between the Ni—P layer and the gold layer. Therefore, in the piezoelectric driving apparatus 300, the diffusion between the Ni—P layer and a gold layer can be suppressed by the palladium layer.

### 2.2. Method of Manufacturing Piezoelectric Driving Apparatus

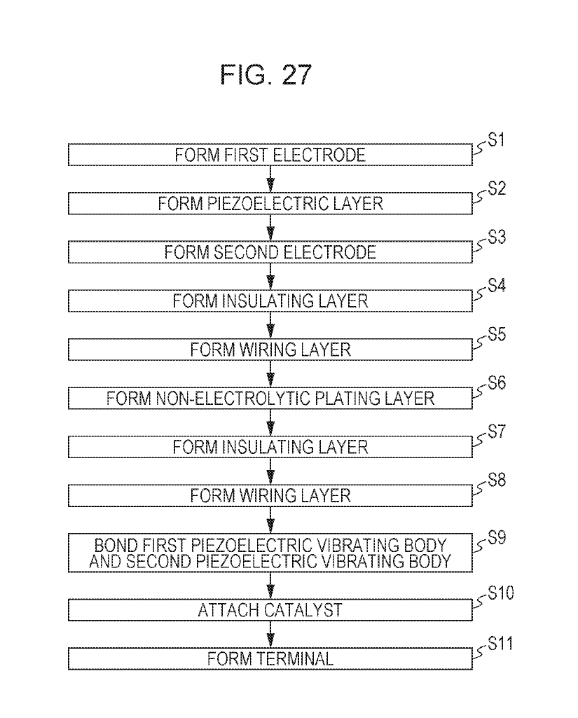

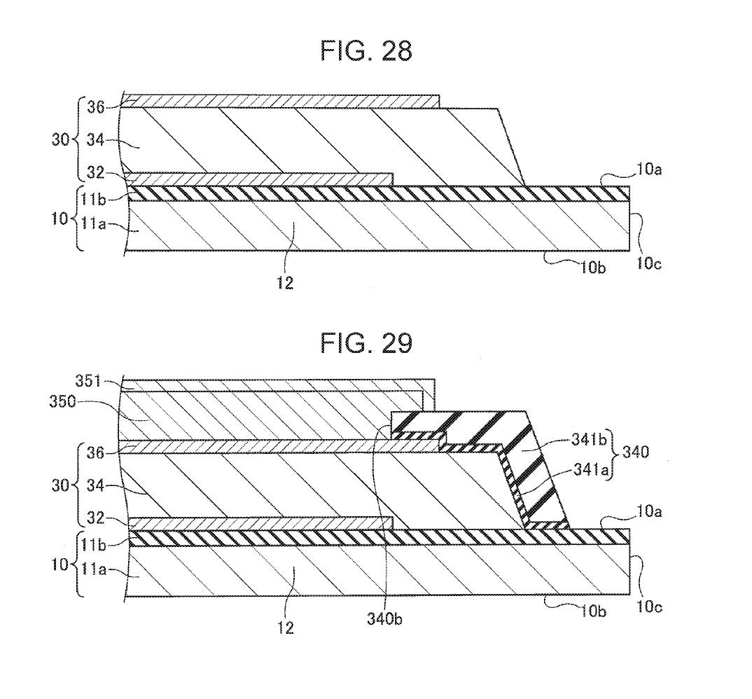

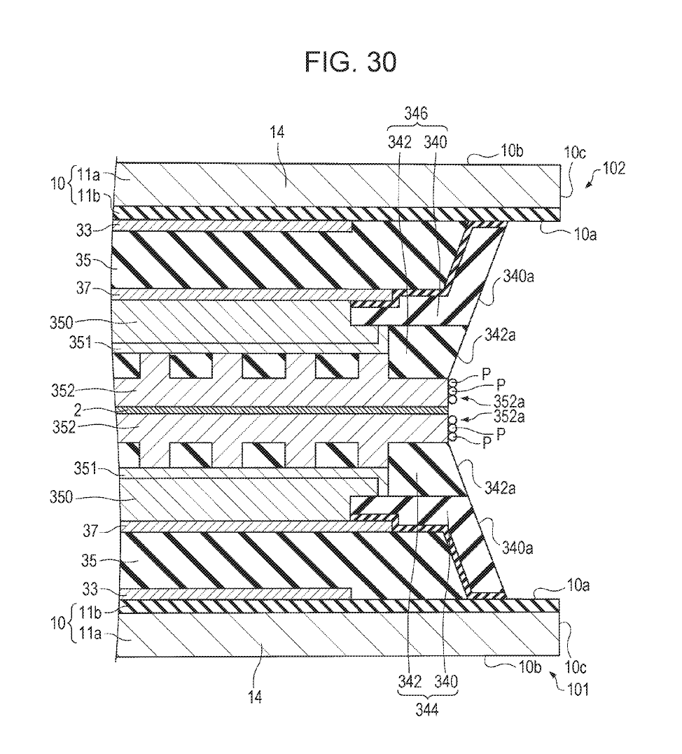

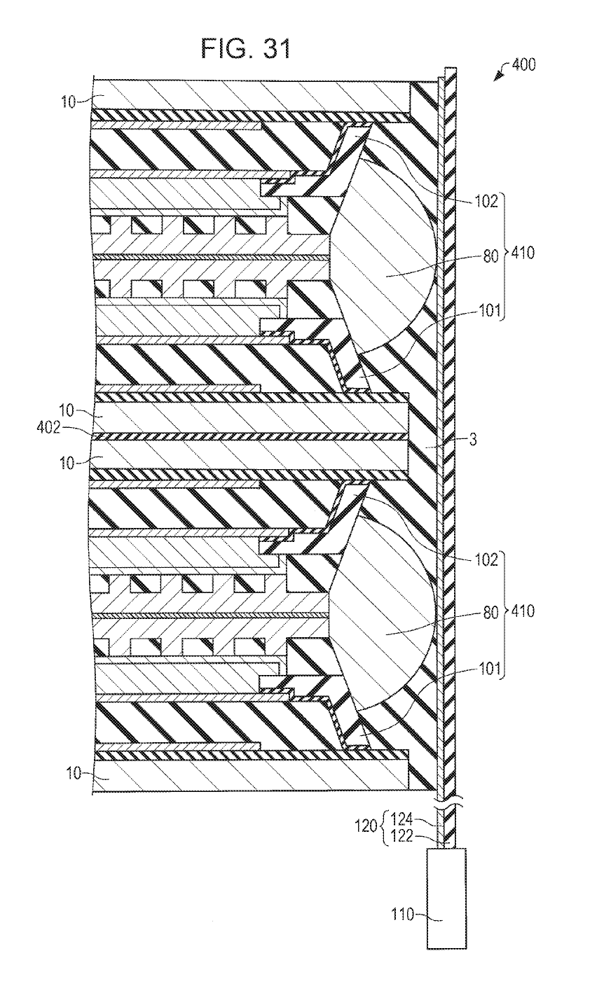

Next, description will be given of the method of manufacturing a piezoelectric driving apparatus 300 according to the second embodiment with reference to the drawings. FIG. 27 is a flowchart for illustrating a method of manufacturing a piezoelectric driving apparatus 300 according to the second embodiment. FIG. 28 to FIG. 30 are cross-sectional views which schematically show manufacturing steps of the piezoelectric driving apparatus 300 according to the second embodiment. Here, FIG. 28 and FIG. 29 show the same cross-section as in FIG. 24, and FIG. 30 shows the same cross-section as FIG. 25.

The first piezoelectric vibrating body 101 and the second piezoelectric vibrating body 102 are basically formed by the same manufacturing method. Accordingly, in the following, description will be given of a method of manufacturing the first piezoelectric vibrating body 101 using FIGS. 23, 28, and 29. The description of the method of manufacturing the first piezoelectric vibrating body 101 can basically be applied to the method of manufacturing the second piezoelectric vibrating body 102.

As shown in FIG. 28, the first electrode 32 is formed on the vibrating body portion 12 of the substrate 10 (S1). The first electrode 32 is formed by, for example, film-forming using a sputtering method, a chemical vapor deposition (CVD) method, a vacuum deposition method, and the like, and patterning (patterning by photolithography and etching). In the present step, it is possible to form the first conductive layer 33 on the support portion 14 and the connecting portions 16 and 18 of the substrate 10 (refer to FIG. 25). Here, the substrate 10 is, for example, obtained by forming the underlayer 11b by a sputtering method or a chemical vapor deposition method on the silicon substrate 11a.

Here, the substrate 10 may be in a wafer state. That is, although not shown, a frame portion is provided on the periphery of the substrate 10 and the substrate 10 may be connected to the frame portion via a cut-away portion. In such a case, the substrate 10, the frame portion, and the cut-away portion are integrally provided.

Next, the piezoelectric body layer 34 is formed on the first electrode 32 (S2). The piezoelectric body layer 34 is, for example, formed by patterning after repeating the forming of the precursor layer by a liquid phase method and the crystallization of the precursor layer. The liquid phase method is a method of forming a film with a thin-film material using a raw material solution which includes a constituent material of the thin film (piezoelectric body layer), specifically, a sol-gel method, a metal organic deposition (MOD) method, or the like. The crystallization is performed by a heat treatment at 700° C. to 800° C. in an oxygen atmosphere. In this step, it is possible to form the insulating layer 35 on the first conductive layer 33 (refer to FIG. 25).

Next, the second electrode 36 is formed on the piezoelectric body layer 34 (S3). The second electrode 36 is, for example, formed with the same method as the first electrode 32. Although not shown, the patterning of the second electrode 36 and the patterning of the piezoelectric body layer 34 may be performed as the same step. In this step, it is possible to form the second conductive layer 37 on the insulating layer 35 (refer to FIG. 25).

Through the above steps, it is possible to form the piezoelectric element 30 on the vibrating body portion 12 of the substrate 10.

As shown in FIG. 29, the insulating layer 340 which has the inorganic insulating layer 341a and an organic insulating layer 341b is formed so as to cover the piezoelectric element 30 (S4). The inorganic insulating layer 341a and the organic insulating layer 341b are formed, for example, a spin coating method, or a CVD method. Next, the contact hole 340b is formed by patterning the insulating layer 340.

Next, the wiring layer 350 is formed on the second electrode 36 and on the insulating layer 340 (S5). The wiring layer 350 is formed by, for example, a plating (electroplating) method, film-forming by sputtering and patterning, or the like.

Next, the non-electrolytic plating layer 351 is formed so as to cover the wiring layer 350 (S6). The non-electrolytic plating layer 351 is formed by non-electrolytic plating. Specifically, after selectively attaching palladium as a catalyst to the surface of the wiring layer 350, the non-electrolytic plating layer 351 is selectively formed on the surface of the wiring layer 350 by non-electrolytic plating.

As shown in FIG. 23, the insulating layers 342 and 343 are formed so as to cover the non-electrolytic plating layer 351 (S7). Specifically, the insulating layer 343 is formed after forming the insulating layer 342. The insulating layers 342 and 343 are formed, for example, a spin coating method, or a CVD method. In a case where the material of the insulating layer 342 and 343 is a photosensitive material, the insulating layers 342 and 343 can be patterned by exposure, developing, and baking without etching. For example, in a case where the insulating layers 342 and 343 are baked, it is possible to suppress the oxidation of the wiring layer 350 by the non-electrolytic plating layer 351. Here, in a case where the material of the insulating layer 342 and 343 is not a photosensitive material, the insulating layers 342 and 343 are patterned by photolithography and etching.

Through the above steps, it is possible to form the insulating portions 344 and 346 (refer to FIG. 25) which have the insulating layers 340 and 342.

Next, the wiring layer 352 is formed on the electrodes 32 and 36 and on the insulating layer 342 (S8). The wiring layer 352 is, for example, is formed by the same method as the wiring layer 350.

Through the above steps, it is possible to form the first piezoelectric vibrating body 101 and the second piezoelectric vibrating body 102. Here, in a case where the substrate 10 is in a wafer state, the first piezoelectric vibrating body 101 and the second piezoelectric vibrating body 102 may be formed on different wafers.

As shown in FIG. 24, the first piezoelectric vibrating body 101 and the second piezoelectric vibrating body 102 are bonded (S9) such that the first surface 10a of the substrate 10 of the first piezoelectric vibrating body 101 and the first surface 10a of the substrate 10 of the second piezoelectric vibrating body 102 are opposed to each other. Specifically, the wiring layer 352 of the first piezoelectric vibrating body 101 and the wiring layer 352 of the second piezoelectric vibrating body 102 are bonded via the adhesive 2.

As shown in FIG. 30, palladium P as a catalyst for the non-electrolytic plating is selectively attached to the side surface 352a of the wiring layer 352 (S10). The palladium P is, for example, attached by a known method.

As shown in FIG. 25, the terminals 80, 82, 84, and 86 are formed on the side surface 352a of the wiring layer 352 (S11). Specifically, the terminals 80 to 86 are selectively formed on the portion of the side surface 352a where the palladium P is attached. The terminals 80 to 86 are formed by non-electrolytic plating. In a case where the terminals 80 to 86 have an Ni—P layer, a palladium layer, and a gold layer, the Ni—P layer is, for example, formed by reducing the nickel layer with hypophosphorous acid (formed by reduction type non-electrolytic plating). The palladium layer and a gold layer are, for example, formed by substitution type non-electrolytic plating.

In step (S11), the terminals 80 to 86 are connected to the side surfaces 352a of the wiring layers 352 of the piezoelectric vibrating bodies 101 and 102 and are formed so as to protrude outward further than the side surface 10c of the substrate 10 of the piezoelectric vibrating bodies 101 and 102. The terminals 80 to 86 are formed so as to connect to the side surfaces 340a and 342a of the insulating portions 344 and 346. The terminals 80 to 86 are formed so as to be separated from the substrates 10 of the piezoelectric vibrating bodies 101 and 102.

Here, although not shown, in a case where the substrate 10 is a wafer state, after step (S11), a cut-away portion is cut away by etching or the like to separate the substrate 10 from the frame portion (chip forming).

Through the above steps, it is possible to manufacture the piezoelectric driving apparatus 300.

The method of manufacturing a piezoelectric driving apparatus 300 includes a step (S11) of forming terminals 80 to 86 which are connected to the side surfaces 352a of the wiring layers 352 of the piezoelectric vibrating bodies 101 and 102 so as to protrude outward further than the side surfaces 10c of the substrates 10 of the piezoelectric vibrating bodies 101 and 102. Therefore, in the method of manufacturing a piezoelectric driving apparatus 300, it is possible to manufacture the piezoelectric driving apparatus 300 which can be reduced in size.

### 2.3. Modification Example of Piezoelectric Driving Apparatus

Next, description will be given of the piezoelectric driving apparatus according to a modification example of the second embodiment with reference to the drawings. FIG. 31 is a cross-sectional view which schematically shows a piezoelectric driving apparatus 400 according to a modification example of the second embodiment.

Below, in the piezoelectric driving apparatus 400 according to the modification example of the second embodiment, the same reference numerals are given to the member which have the same functions as the constituent members of the piezoelectric driving apparatus 300 according to the second embodiment and detailed description thereof will be omitted.

As shown in FIG. 26, in the piezoelectric driving apparatus 300 described above, the first piezoelectric vibrating body 101 and the second piezoelectric vibrating body 102, are included one by one. In contrast, as shown in FIG. 31, the piezoelectric driving apparatus 400 includes a plurality of each of the first piezoelectric vibrating body 101 and the second piezoelectric vibrating body 102.

In the piezoelectric driving apparatus 400, the first piezoelectric vibrating body 101 the second piezoelectric vibrating body 102, and the terminals 80, 82, 84, and 86 form a bonded body 410. A plurality of the bonded bodies 410 are provided. In the illustrated example, two of the bonded bodies 410 are provided. A plurality of the bonded bodies 410 are laminated in the thickness direction of the substrate 10.

In the adjacent bonded bodies 410, the substrate 10 of the first piezoelectric vibrating body 101 of one of the bonded bodies 410 and the substrate 10 of the second piezoelectric vibrating body 102 of the other bonded body 410 are bonded by an adhesive 402. The adhesive 402 has, for example, an insulating characteristic.

In the piezoelectric driving apparatus 400, a plurality of the bonded bodies 410 are laminated in the thickness direction of the substrate 10. Therefore, in the piezoelectric driving apparatus 400, it is possible to achieve a higher output in comparison with a case where only one bonded body 410 is formed.

Furthermore, in the piezoelectric driving apparatus 400, even in a case where a plurality of the bonded bodies 410 are laminated, it is possible to use the flexible substrate 120 and the routing of the external wiring can be simplified. Therefore, in the piezoelectric driving apparatus 400, it is possible to easily electrically connect the driving circuit 110 and the wiring layer 352.

### 3. Third Embodiment

### 3.1. Piezoelectric Driving Apparatus

Next, description will be given of a piezoelectric driving apparatus according to the third embodiment with reference to the drawings.

Here, piezoelectric actuators (piezoelectric driving apparatuses) for driving a driven body by vibrating a piezoelectric body are used in various fields since a magnet or a coil is not necessary. For example, the piezoelectric driving apparatus disclosed in JPA-2004-320979 is formed with four piezoelectric elements disposed in two rows and two columns on each of two surfaces of a plate-like member, and is formed to generate vibration using eight piezoelectric elements in total. At one end of the plate-like member, a protrusion is provided for rotating the rotor by coming in contact with the rotor as a driven body. When an AC voltage is applied to the two piezoelectric elements disposed diagonally out of the four piezoelectric elements, the two piezoelectric elements perform an expansion and contraction movement and the protrusion performs a reciprocating movement or an elliptical movement accordingly. Then, the rotor as a driven member is rotated in a predetermined rotational direction depending on the reciprocating movement or elliptical movement of the protrusion of the reinforcing plate. In addition, switching from the two piezoelectric elements to which an AC voltage is applied to the two other piezoelectric elements makes it possible to rotate the rotor in the opposite direction.

In addition, a piezoelectric driving apparatus with a stack structure for increasing the output by superimposing piezoelectric driving bodies (piezoelectric vibrating bodies) in the thickness direction is known (for example, JP-A-08-237971). The piezoelectric vibrating bodies of the piezoelectric driving apparatus are supported by an elastic support body.

For example, in a case where the motor is formed to generate power using a piezoelectric driving apparatus, one of the basic requirements is to increase the driving force (output). As an example, in the apparatus disclosed in JP-A-2008-227123 described above, an attempt is made to increase the output by the stack structure.

However, in a case where vibrating bodies where a piezoelectric element is formed on the surface of the plate-like member are stacked (laminated), a difference in the thickness is generated between the region of the plate-like member where the piezoelectric element is formed and the region where the piezoelectric element is not formed. Therefore, in the step of bonding or the like in the manufacturing of the laminated body, the plate-like member is easily damaged. In addition, even in a case where the plate-like member is not damaged, defects may be generated in the vibration characteristics when the lamination is carried out in a state where residual stress is generated in the plate-like member.

In addition, in a case where the thickness is different between a fixing location (fixing portion) of the piezoelectric driving apparatus provided in order to fix the piezoelectric driving apparatus with respect to the structural material or the like and a portion (vibrating portion) which vibrates the piezoelectric driving apparatus, in a case of forming a laminated body, the piezoelectric driving apparatus is easily cracked or broken in the step of bonding or the like and residual stress tends to remain. Therefore, in particular, there was a risk of damage in the region (the connecting portion or the like) between the fixing portion and the vibrating portion.

An object according to some embodiments of the invention is to provide a piezoelectric driving apparatus where a plurality of vibrating units are laminated in a state with favorable flatness and where damage or the like does not easily occur, and a motor, robot, and pump provided with such a piezoelectric driving apparatus.

A piezoelectric driving apparatus 500 of the third embodiment includes a plurality of vibrating units 501. Then, the piezoelectric driving apparatus 500 is formed by arranging the vibrating units 501 so as to overlap. Below, after giving description of the vibrating units 501, description will be given of thickness, arrangement, and the like of the vibrating units 501.

### 3.1.1. Vibrating Unit

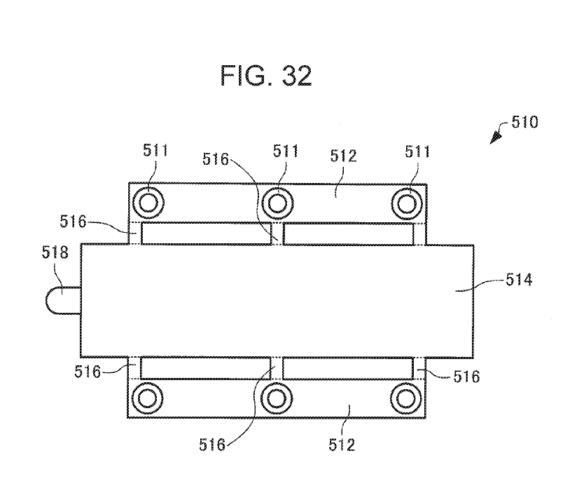

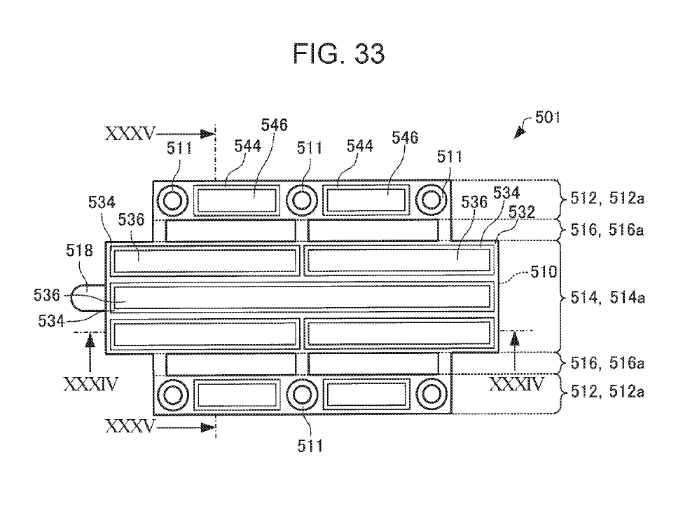

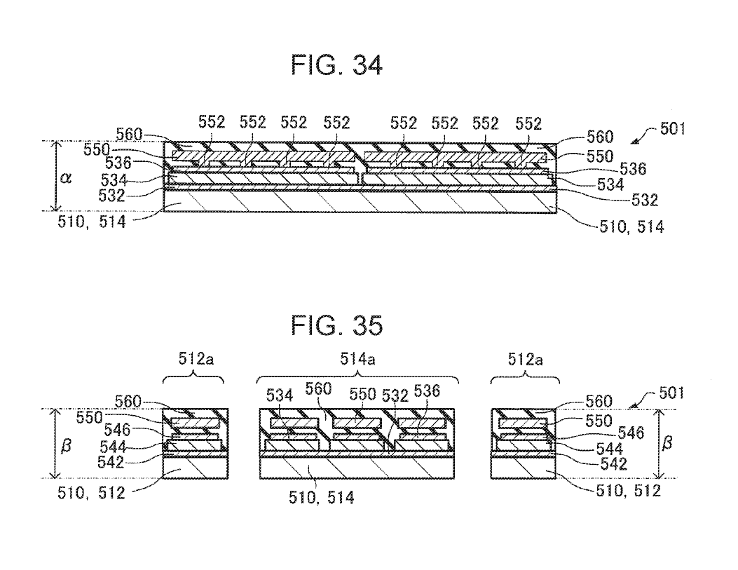

First, description will be given of the vibrating units of piezoelectric driving apparatus according to the third embodiment with reference to the drawings. FIG. 32 is a plan view which schematically shows a vibrating plate 510 of the vibrating unit 501 according to the third embodiment. FIG. 33 is a plan view which schematically shows the vibrating unit 501 according to the third embodiment. FIG. 34 is a cross-sectional view taken along a line XXXIV-XXXIV in FIG. 33 which schematically shows the vibrating unit 501 according to the third embodiment. FIG. 35 is a cross-sectional view taken along a line XXXV-XXXV in FIG. 33 which schematically shows the vibrating unit 501 according to the present embodiment.

The vibrating unit 501 of the present embodiment includes the vibrating plate 510, a first electrode 532, a first piezoelectric body layer 534, a second electrode 536, a third electrode 542, a second piezoelectric body layer 544, and a fourth electrode 546.

### 3.1.1.1. Vibrating Plate

FIG. 32 is a schematic view in which the vibrating plate 510 is seen in plan view. the vibrating plate 510 includes a fixing portion 512, a vibrating portion 514, a connecting portion 516, and a protrusion 518.

The vibrating plate 510 has a flat shape. As shown in FIG. 32, the vibrating portion 514 of the vibrating plate 510 has a shape which has a longitudinal direction and a lateral direction perpendicular to the longitudinal direction. In the illustrated example, the planar shape of the vibrating portion 514 of the vibrating plate 510 is a rectangle. The longitudinal direction is the direction in which the long side extends and the lateral direction is the direction in which the short side extends. The vibrating portion 514 is provided with a piezoelectric element to be described below (a laminated structure of the first electrode 532, the first piezoelectric body layer 534, and the second electrode 536) and can change shape and vibrate due to the driving of the piezoelectric element. Although the planar shape of the vibrating portion 514 is a rectangular shape in the illustrated example, the shape is not particularly limited. In addition, the size and thickness of the vibrating portion 514 are also not particularly limited.

At one end of the vibrating plate 510 in the longitudinal direction, the protrusion 518 is provided. The protrusion 518 may be integrally provided with the vibrating portion 514, or may be formed separately and provided in contact with the vibrating portion 514 using adhesive or the like. The protrusion 518, for example, comes in contact with a rotor (described below) which is not shown in the diagram and the protrusion 518 moves to follow a locus of a circle or an ellipse in plan view to be able to rotate the rotor. The movement of the protrusion 518 is realized by the expanding and contracting vibration and the bending vibration of the vibrating portion 514. Although the form of the vibration of the vibrating portion 514 is arbitrary, the vibration is implemented by a piezoelectric element provided on the vibrating portion 514. The material of the protrusion 518 is, for example, ceramics (specifically, alumina (Al₂O₃), Zirconia (ZrO₂), silicon nitride (Si₃N), or the like).

On the other hand, as shown in FIG. 32, the vibrating plate 510 has the fixing portion 512. The fixing portion 512 is a site for fixing the vibrating unit 501 to another member. The piezoelectric driving apparatus 500 of the present embodiment includes a plurality of vibrating units 501; however, the fixing portion 512 is provided on the vibrating plate 510 of each of the vibrating units 501. It is also possible to use the fixing portion 512 in order to overlap and fix the vibrating unit 501 and the other vibrating unit 501.

In the illustrated example, in plan view, the fixing portions 512 are provided on both sides of the vibrating portion 514 in the lateral direction. The position and number of the fixing portions 512 to be provided is not particularly limited. The size of the fixing portion 512 is also not particularly limited and, for example, may be larger or smaller than the vibrating portion 514 in a range in which the vibration of the vibrating portion 514 is not inhibited.

In the illustrated example, three holes 511 formed so as to be suitable for screwing or the like are formed in each of the fixing portions 512. The holes 511 are through holes passing through the vibrating plate 510. The holes 511 may be used to fix a plurality of vibrating units 501 to each other, or may be used in order to fix a set of the vibrating units 501 to another member when using the holes 511 to form the piezoelectric driving apparatus 500. Here, in the illustrated example, an aspect where the holes 511 are formed in the fixing portion 512 is illustrated; however, the holes 511 are not always necessary as long as it is possible to fix a plurality of the vibrating units 501 to each other by another means or configuration (for example, a pinching member (a clip, or the like)), or to fix a set of the vibrating units 501 to another member.

The vibrating unit 501 is fixed by the fixing portion 512 of the vibrating plate 510; however, a portion (denoted by the reference numeral of a fixing portion 512a below in the vibrating unit 501) corresponding to the fixing portion 512 of the vibrating unit 501 is fixed by fixing the vibrating plate 510. In addition, in the fixing portion 512 of the vibrating plate 510 of the vibrating unit 501 of the present embodiment, the third electrode 542, a second piezoelectric body layer 544, and the fourth electrode 546 are formed. Such an arrangement may be formed to avoid the holes 511 (refer to FIG. 33). In addition, the holes 511 may be disposed so as to pass through this configuration while taking into consideration the insulation property and the like.

In the vibrating plate 510, the connecting portion 516 which connects the fixing portion 512 and the vibrating portion 514 is formed. The connecting portion 516 is provided such that the fixing portion 512 supports the vibrating portion 514. The connecting portion 516 supports the vibrating portion 514; however, the connecting portion 516 is preferably provided so as to not inhibit the vibration (operation) of the vibrating portion 514. For example, the connecting portion 516 is provided in the vicinity of the joint of the vibration when the vibrating portion 514 is vibrated. In addition, for example, as illustrated, the connecting portion 516 is formed to be thinner and with a lower mechanical strength than the vibrating portion 514. However, since the vibrating portion 514 is, for example, pressed against the rotor, or the like, the connecting portion 516 is designed so as to have a strength which is not impaired by the above biasing force.

In the illustrated example, the connecting portions 516 are formed so as to extend three at a time from one vibrating portion 514 with respect to two of the fixing portions 512. The positions, number, shapes, and the like of the connecting portions 516 to be provided are not limited and can be appropriately designed according to the purpose of the piezoelectric driving apparatus 500.

The vibrating plate 510 is, for example, a silicon substrate. The material of the vibrating plate 510 may be silicon, metal, oxide, nitride, or the like and, in addition, may take the form of a laminate or composite material. The vibrating plate 510 can be appropriately provided with a layer functioning as a conductor (an electrode, or the like), a dielectric body, a piezoelectric body, an insulator or the like. In addition, these layers may be provided over the entire surface of the vibrating plate 510, or may be provided on both surfaces of the vibrating plate 510.

A layer such as a conductor (an electrode, or the like), a dielectric body, a piezoelectric body, an insulator or the like is formed on the vibrating plate 510. The thickness of the vibrating plate 510 does not need to be uniform. For example, the thickness of a connecting portion 516a of the vibrating plate 510 may be smaller than the thickness of the vibrating portion 514 and the fixing portion 512. In addition, specific portions of the vibrating plate 510 may have different thicknesses from the thicknesses of other portions. Such a structure can, for example, be comparatively easily formed in a case where the vibrating plate 510 is formed by a silicon substrate. However, as will be described in detail below, in a state where at least the vibrating unit 501 is formed, the thickness of the vibrating unit 501 of the portion (the fixing portion 512a) corresponding to the fixing portion 512 of the vibrating plate 510 is preferably the same as the thickness of the vibrating unit 501 of the portion (denoted by the reference numeral of a vibrating portion 514a below in the vibrating unit 501) corresponding to the vibrating portion 514.

Here, in the present specification, the “same” refers not only to being exactly the same, but also includes a case of being the same after taking measurement errors into consideration and a case of being the same within a range which does not impair the functions. Accordingly, the expression “one thickness is the same as another thickness” takes into account measurement errors, and has the meaning that the difference between the two thicknesses is within ±20% of the one thickness, preferably within ±15%, more preferably within ±10%, even more preferably within ±5%, and particularly preferably within ±3%.

### 3.1.1.2. First Electrode

The first electrode 532 is provided above the vibrating portion 514 of the vibrating plate 510. Between the first electrode 532 and the vibrating plate 510, for example, a layer having a function of adhesion, crystal control, orientation control, insulation, or the like may be formed.

The first electrode 532 may be formed over the entire surface of the vibrating portion 514, or may be formed on a portion of the vibrating portion 514. In the example shown in FIG. 33, the first electrode 532 is entirely formed above the vibrating portion 514 and the connecting portion 516 of the vibrating plate 510. In addition, in the example shown in FIG. 33, the first electrode 532 is integrally formed with the third electrode 542 (described below). In this manner, the first electrode 532 may be electrically connected to the third electrode 542.

Here, in FIG. 33, the first piezoelectric body layer 534 and the second piezoelectric body layer 544, and the members positioned above the second electrode 536 and the fourth electrode are omitted from the illustration.

Some or all of the region provided in the vibrating portion 514 of the first electrode 532 is disposed opposite to the second electrode 536 and this portion functions as one electrode of the piezoelectric element. The first electrode 532 is formed of a material having conductivity such as a metal, an alloy, a conductive oxide, or the like.

The thickness of the first electrode 532 is, for example, 10 nm to 1 μm, preferably 20 nm to 800 nm, more preferably 30 nm to 500 nm, and even more preferably 50 nm to 300 nm.

The first electrode 532 may, for example, be formed of an iridium layer, and a platinum layer provided on the iridium layer. In such a case, the thickness of the iridium layer is, for example, 5 nm to 100 nm. In addition, the thickness of the platinum layer is, for example, 50 nm to 300 nm.

Here, examples of the material of the first electrode 532 include various metals such as nickel, iridium, platinum, Ti, Ta, Sr, In, Sn, Au, Al, Fe, Cr, and Cu, conductive oxides thereof (for example, iridium oxide), complex oxides of strontium and ruthenium (SrRuOₓ:SRO), composite oxides of lanthanum and nickel (LaNiOₓ:LNO), and the like. The first electrode 532 may have a single-layer structure of the illustrated materials, or may have a structure in which a plurality of materials are laminated. In addition, although not illustrated, the first electrode 532 can be etched or patterned by a typical method in semiconductor manufacturing or the like.

### 3.1.1.3. First Piezoelectric Body Layer

The first piezoelectric body layer 534 is provided above the first electrode 532 above the vibrating portion 514 of the vibrating plate 510. Between the first electrode 532 and the first piezoelectric body layer 534, for example, a layer having a function of adhesion, crystal control, orientation control, insulation, or the like may be formed. Here, the material of the adhesive layer in a case of providing the adhesive layer is, for example, a TiW layer, a Ti layer, a Cr layer, an NiCr layer, or a laminate thereof. The first piezoelectric body layer 534 is positioned between the first electrode 532 and the second electrode 536.

The first piezoelectric body layer 534 may be formed over the entire surface of the first electrode 532, or may be formed above a portion thereof. In addition, the first piezoelectric body layer 534 may be formed above the vibrating plate 510 where the first electrode 532 is not formed. As shown in FIG. 33 to FIG. 35, the first piezoelectric body layer 534 is provided above the first electrode 532 of the vibrating portion 514 of the vibrating plate 510. In addition, the first piezoelectric body layer 534 may be provided above the connecting portion 516; however, in a case where the piezoelectric element is formed in the connecting portion 516, it is preferably provided after taking into consideration the vibration of the vibrating portion 514. Furthermore, in a case where the first piezoelectric body layer 534 is provided above the connecting portion 516 and does not form the piezoelectric element, the piezoelectric body layer 534 is preferably provided taking into consideration the thickness of the connecting portion 516 of the vibrating plate 510 and the thickness of the first piezoelectric body layer 534 such that the rigidity of the connecting portion 516 is not excessively high.

In the example shown in FIG. 33 to FIG. 35, the first piezoelectric body layer 534 is patterned and removed in a portion where the piezoelectric element is not formed. The first piezoelectric body layer 534 can be formed in the same step as the second piezoelectric body layer 544. In addition, although not shown, the first piezoelectric body layer 534 and the second piezoelectric body layer 544 may be integrally formed.

The first piezoelectric body layer 534 forms a piezoelectric element in a portion interposed between the first electrode 532 and the second electrode 536 and is able to change shape according to an electromechanical conversion operation by the application of a voltage from both electrodes.

The thickness of the first piezoelectric body layer 534 is, for example, 50 nm to 20 μm, and preferably 1 μm to 7 μm. Accordingly, a piezoelectric element formed by overlapping and arranging the first electrode 532, the first piezoelectric body layer 534, and the second electrode 536 is a thin-film piezoelectric element. As long as the thickness of the first piezoelectric body layer 534 is in this range, it is possible to obtain a sufficient output from the vibrating unit 501 and dielectric breakdown does not easily occur even when the voltage applied to the first piezoelectric body layer 534 is increased. In addition, as long as the thickness of the first piezoelectric body layer 534 is in this range, cracks are not easily generated in the first piezoelectric body layer 534.

Examples of the material of the first piezoelectric body layer 534 include perovskite-type oxide piezoelectric materials. More specifically, the material of the first piezoelectric body layer 534 is preferably a perovskite-type oxide represented by the general formula ABO₃ (for example, A includes Pb and B includes Zr and Ti). Specific examples of such materials include lead zirconate titanate (Pb(Zr, Ti) O₃) (may be abbreviated below as “PZT”), lead zirconate titanate niobate (Pb(Zr, Ti, Nb) O₃) (may be abbreviated below as “PZTN”), barium titanate (BaTiO₃), potassium sodium niobate ((K, Na) NbO₃), and the like. Among these, as the material of the first piezoelectric body layer 534, PZT and PZTN are particularly suitable as the piezoelectric characteristics are good. In addition, although not illustrated, the first piezoelectric body layer 534 can be etched or patterned using a typical method in semiconductor manufacturing or the like.

### 3.1.1.4. Second Electrode

The second electrode 536 is provided above the first piezoelectric body layer 534. Between the second electrode 536 and the first piezoelectric body layer 534, for example, a layer having a function of adhesion, crystal control, orientation control, insulation, or the like may be formed. Here, the material of the adhesive layer in a case of providing the adhesive layer is, for example, a TiW layer, a Ti layer, a Cr layer, an NiCr layer, or a laminate thereof.

Some or all of the region provided in the vibrating portion 514 of the second electrode 536 is disposed opposite the first electrode 532 and this portion functions as one electrode of the piezoelectric element.

As long as the second electrode 536 can form a piezoelectric element by forming a set with the first electrode 532 and the first piezoelectric body layer 534, the second electrode 536 may be formed over the entire surface of the vibrating portion 514. That is, as long as the first electrode 532 is patterned, it is possible to form a set of a predetermined piezoelectric element even when the second electrode 536 is formed over the entire surface of the vibrating portion 514. That is, in the illustrated example, the first electrode 532 is a common electrode of the plurality of piezoelectric elements and the second electrode 536 is an individual electrode of the plurality of piezoelectric elements; however, the second electrode 536 may be a common electrode of the plurality of piezoelectric elements and the first electrode 532 may be an individual electrode of the plurality of piezoelectric element. In addition, the second electrode 536 may be electrically connected to the fourth electrode 546. The thickness of the second electrode 536 is, for example, 1 μm to 10 μm. The second electrode 536 is, for example, a Cu layer, an Au layer, an Al layer, or a laminate thereof.

### 3.1.1.5. Piezoelectric Element

As described above, the piezoelectric element is formed above the vibrating portion 514 of the vibrating plate 510 by the set of the first electrode 532, the first piezoelectric body layer 534, and the second electrode 536; however, the shape, number, arrangement, and the like of the piezoelectric element are arbitrary as long as it is possible for the vibrating portion 514 to generate a predetermined vibration. In the illustrated example, five of the piezoelectric elements are formed above the vibrating portion 514. Then, it is possible for the vibrating unit 501 to carry out bending vibration and expanding and contracting vibration by applying an appropriate voltage to the electrodes of each of the piezoelectric elements using wiring which is not shown.

### 3.1.1.6. Third Electrode

The vibrating unit 501 has the third electrode 542 on the fixing portion 512a. The third electrode 542 is provided above the fixing portion 512 of the vibrating plate 510. Between the third electrode 542 and the vibrating plate 510, for example, a layer having a function of adhesion, crystal control, orientation control, insulation, or the like may be formed.

The third electrode 542 may be formed on the entire surface of the fixing portion 512, or may be formed on a portion of the fixing portion 512. In the example shown in FIG. 33, the third electrode 542 is formed above the fixing portion 512 of the vibrating plate 510. In addition, in the example shown in FIG. 33, the third electrode 542 is integrally formed with the first electrode 532. In this manner, the third electrode 542 may be electrically connected to the first electrode 532.

Some or all of the region provided on the fixing portion 512 of the third electrode 542 is disposed opposite to the fourth electrode 546. The third electrode 542 may function as one electrode of a capacitor in this part. The third electrode 542 is formed of a material having conductivity such as a metal, an alloy, or a conductive oxide. The thickness and material of the third electrode 542 can, for example, be the same as the first electrode 532.

### 3.1.1.7. Second Piezoelectric Body Layer

The vibrating unit 501 has a second piezoelectric body layer 544 on the fixing portion 512a. The second piezoelectric body layer 544 is provided above the third electrode 542 above the fixing portion 512 of the vibrating plate 510. Between the third electrode 542 and the second piezoelectric body layer 544, for example, a layer having a function of adhesion, crystal control, orientation control, insulation, or the like may be formed. The second piezoelectric body layer 544 is positioned between the third electrode 542 and the fourth electrode 546.

The second piezoelectric body layer 544 may be formed over the entire surface of the third electrode 542, and may be formed above a portion thereof. In addition, the second piezoelectric body layer 544 may be formed above the vibrating plate 510 where the third electrode 542 is not formed. As shown in FIG. 33 and FIG. 35, the second piezoelectric body layer 544 is provided above the third electrode 542 of the fixing portion 512 of the vibrating plate 510. In addition, in a case where the first piezoelectric body layer 534 is provided above the connecting portion 516a, the second piezoelectric body layer 544 may be integral with the first piezoelectric body layer 534.

In the example shown in FIG. 33 and FIG. 35, the second piezoelectric body layer 544 is patterned and removed in a portion where the capacitor is not formed. The second piezoelectric body layer 544 may be formed in the same step as the first piezoelectric body layer 534.

The second piezoelectric body layer 544 can form a capacitor in a portion interposed between the third electrode 542 and the fourth electrode 546. Here, since the second piezoelectric body layer 544 does not easily change shape due to being provided in the fixing portion 512 and constrained by a structural member such as a screw and, since the applied electric energy is not easily converted into mechanical energy, the second piezoelectric body layer 544 can be used as a good capacitor (condenser). The thickness and material of the second piezoelectric body layer 544 are the same as those of the first piezoelectric body layer 534.

### 3.1.1.8. Fourth Electrode

The vibrating unit 501 has the fourth electrode 546 on the fixing portion 512a. The fourth electrode 546 is provided above the second piezoelectric body layer 544. Between the fourth electrode 546 and the second piezoelectric body layer 544, for example, a layer having a function of adhesion, crystal control, orientation control, insulation, or the like may be formed.

The fourth electrode 546 may be formed over the entire surface of the fixing portion 512. For example, as long as the third electrode 542 is patterned, it is possible to form a predetermined capacitor even when the fourth electrode 546 is formed over the entire surface of the fixing portion 512. In the illustrated example, the third electrode 542 is a common electrode of the plurality of capacitors and the fourth electrode 546 is an individual electrode of the plurality of capacitors; however, the fourth electrode 546 may be a common electrode of the plurality of capacitors, and the third electrode 542 may be a separate electrode of the plurality of capacitors. In addition, the fourth electrode 546 may be electrically connected to the second electrode 536.

Some or all of the region provided on the fixing portion 512 of the fourth electrode 546 is disposed to oppose the third electrode 542, and this portion can function as one electrode of the capacitor. The thickness and material of the fourth electrode 546 can be the same as the second electrode 536.

### 3.1.1.9. Other Configurations

The vibrating unit 501 of the third embodiment can include other configurations. As such configurations, for example, wiring, a layer of an insulator for wiring, a layer for adhesion to laminate a plurality of vibrating units 501, and the like may be included. Below, description will be given of an insulating layer 560 for providing a wiring layer 550 and the wiring layer 550 which electrically connects each of the electrodes described above.

### 3.1.1.9.1. Wiring Layer

The vibrating unit 501 of the present embodiment includes the wiring layer 550 provided above the second electrode 536 and the fourth electrode 546. The wiring layer 550 is provided above the insulating layer 560 (described below). Providing a contact hole in the insulating layer 560 or the piezoelectric body layer positioned below makes it possible for the wiring layer 550 to electrically connect to a conductor (an electrode or the like) positioned below.

The wiring layer 550 is electrically connected to at least one of the second electrode 536 and the fourth electrode 546. In addition, the wiring layer 550 may be connected to the first electrode 532 and the third electrode 542. The wiring layer 550 can form wiring by being appropriately patterned. For example, the wiring layer 550 can form wiring and, in addition, may form a pad which is not shown (terminal for external connection) or the like.

The thickness of the wiring layer 550 is, for example, 50 nm to 10 μm, preferably 100 nm to 5 μm, and more preferably 200 nm to 3 μm and, as long as the thickness is in this range, it is possible to ensure sufficient conductivity.

Furthermore, as shown in FIG. 34, the wiring layer 550 may be formed so as to cover the second electrode 536 above the individual second electrodes 536. In the example shown in FIG. 34, the wiring layer 550 is electrically connected to respect to the second electrode 536 via a via 552 formed in a plurality of contact holes. In this manner, the conductivity of the second electrode 536 can be compensated by the wiring layer 550. In addition, by doing so, the wiring layer 550 functions as one electrode of the piezoelectric element along with the second electrode 536. In this manner, since the conductivity of the wiring layer 550 is good, it is possible to improve the electromechanical conversion efficiency of the piezoelectric element, and to improve the reliability of the vibrating unit 501.

The material of the wiring layer 550 is not particularly limited and is, for example, formed of various metals such as nickel, iridium, platinum, Ti, Ta, Sr, In, Sn, Au, Al, Fe, Cr, and Cu, or conductive materials such as alloys thereof. In addition, although not illustrated, the wiring layer 550 can be etched or patterned by a typical method in semiconductor manufacturing or the like. In addition, forming a contact hole below the wiring layers 550 and forming the via 552 to carry out the electrical connection with the conductor below, or the like can be performed using a typical method in semiconductor manufacturing or the like.

The wiring layer 550 can be provided as a plurality of layers and, for example, may be formed as multi-layer wiring. In addition, in order to make the wiring layer 550 the multi-layer wiring, the insulating layer 560 described below may be formed as a plurality of layers.

### 3.1.1.9.2. Insulating Layer

The insulating layer 560 is provided above at least the second electrode 536 and the fourth electrode 546. The insulating layer 560 may be provided between each of the electrodes and the wiring layer 550. Furthermore, the insulating layer 560 has a function of insulating the electrodes or the wiring. In addition, the insulating layer 560 may be provided above the wiring layer 550. When the insulating layer 560 is formed above the wiring layer 550, for example, in a case where the vibrating plate 510 of the adjacent vibrating unit 501 is conductive, or the like, it is possible to insulate between the adjacent vibrating units 501.

The insulating layer 560 is an oxide insulator such as, for example, silicon oxide, silicon nitride, or aluminum oxide, and can be formed using a typical method in semiconductor manufacturing or the like. In addition, it is possible to form a contact hole at a predetermined position in the insulating layer 560 and to connect to a predetermined wiring by forming a via using a typical method in semiconductor manufacturing or the like.

### 3.1.1.9.3. Other

In the example shown in FIG. 33 and FIG. 34, the wiring layer 550 is formed as one layer with respect to one vibrating unit 501; however, a plurality of wiring layers 550 may be formed in order to form a predetermined wiring. In addition, in the examples of FIG. 32 to FIG. 35, a piezoelectric element or capacitor is provided on the main surface of one side of the vibrating plate 510; however, the configuration described above may be provided on both the main surfaces of the vibrating plate 510.

### 3.1.2. Thickness and Arrangement of Vibrating Unit

The vibrating unit 501 of the present embodiment is formed so as to be substantially the same thickness in the fixing portion 512 and the vibrating portion 514 of the vibrating plate 510. For example, as shown in FIG. 35, the total thickness (in the diagrams, the thickness α) of the vibrating plate 510, the first electrode 532, the first piezoelectric body layer 534, the second electrode 536, the insulating layer 560, the wiring layer 550, and the insulating layer 560 laminated from below in order in a vibrating portion 114a, is formed to be the same as the total thickness (in the diagrams, the thickness β) of the vibrating plate 510, the third electrode 542, the second piezoelectric body layer 544, the fourth electrode 546, the insulating layer 560, the wiring layer 550, and the insulating layer 560 laminated from below in order in the fixing portion 512a.

That is, in consideration of measurement errors, the difference between the thickness α and the thickness β is, for example, within ±20% of the thickness α, preferably within ±15%, more preferably within ±10%, even more preferably within ±5%, and particularly preferably within ±3%. Here, the same applies to a case where the piezoelectric element or the like is formed on both surfaces of the vibrating plate 510, and the total thickness α of the vibrating portion 114a and the total thickness β of the fixing portion 512a are formed to be the same.

In addition, the thickness of each of the vibrating plate 510, the first electrode 532, the first piezoelectric body layer 534, the second electrode 536, the insulating layer 560, the wiring layer 550, and the insulating layer 560 and the thickness of each of the vibrating plate 510, the third electrode 542, the second piezoelectric body layer 544, the fourth electrode 546, the insulating layer 560, the wiring layer 550, and the insulating layer 560, need not correspond to each other. That is, for example, the thickness of the first piezoelectric body layer 534 in the vibrating portion 114a and the thickness of the second piezoelectric body layer 544 in the fixing portion 512a may be different and it is sufficient if the total thickness α and the total thickness β are made to be the same by adjusting the thickness of the other configurations (for example, the insulating layer 560 or the vibrating plate 510).

However, when manufacturing the vibrating unit 501 of the present embodiment, since each layer of the vibrating portion 514a and the fixing portion 512a can be formed in the same step, it is possible to easily set the total thickness α and the total thickness β to be the same by aligning each of the thicknesses.

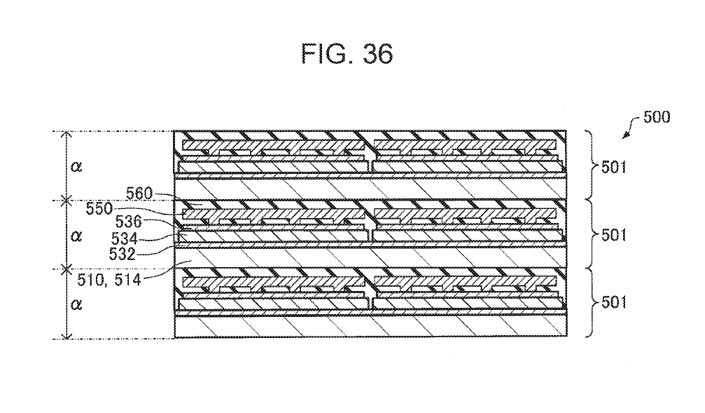

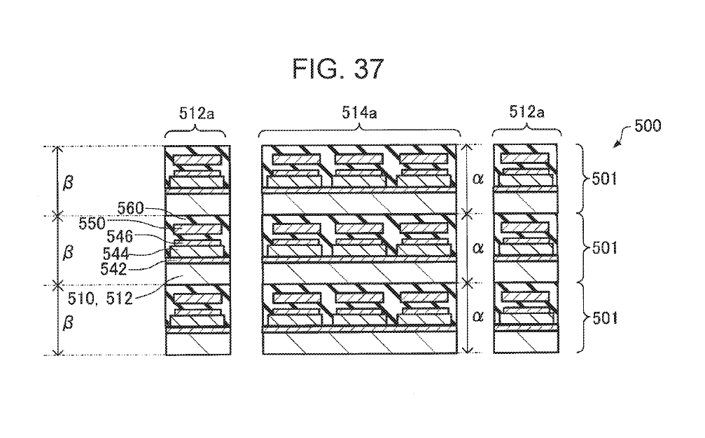

FIG. 36 and FIG. 37 are schematic views of cross-sections of the piezoelectric driving apparatus 500 of the present embodiment. FIG. 5 and FIG. 6 are cross-sections at positions corresponding to the cross-sections of the vibrating unit 501 shown in each of FIG. 34 and FIG. 35. When the vibrating unit 501 of the present embodiment is set as the piezoelectric driving apparatus 500, as shown in FIG. 36 and FIG. 37, a plurality thereof are disposed to overlap in a direction orthogonal to the plate surface of the vibrating plate 510. That is, when the vibrating unit 501 is set as the piezoelectric driving apparatus 500, a plurality thereof are disposed to overlap in plan view. In the illustrated example, three of the vibrating units 501 are disposed so as to overlap.

The number of the vibrating units 501 to be overlapped is not particularly limited and is appropriately set according to the driving force (output) or application of the piezoelectric driving apparatus 500. Even the aspect where the vibrating units 501 are overlapped and disposed is not particularly limited and, for example, as illustrated, it is possible to arrange the fixing portions 512 of each of the vibrating units 501 to overlap each other.

The method for overlapping and arranging the vibrating units 501 is not particularly limited and, for example, it is possible to illustrate a mechanical fixing method of inserting a common screw with respect to the hole 511 of the vibrating unit 501, a method of adhering between the plurality of vibrating units 501 using an adhesive or the like, a method of thermo-compression bonding between the plurality of vibrating units 501, or the like. Furthermore, in a case of adhering between the plurality of vibrating units 501, it is sufficient if at least the fixing portion 512a of the vibrating unit 501 is adhered; however, the vibrating portion 514a of the vibrating unit 501 may be adhered. In addition, although the connecting portion 516a of the vibrating unit 501 may be adhered, it is preferable not to inhibit the vibration of the vibrating portion 514a in such a case.

Here, if the total thickness α of the vibrating portion 514a and the total thickness β of the fixing portion 512a are different, when the plurality of vibrating units 501 are pressed to each other, bending stress is generated in the direction in which each of the vibrating units 501 departs from the surface of the vibrating plate 510. In other words, among the vibrating portion 514a and the fixing portion 512a of the vibrating unit 501, when a thinner region is overlapped and pressed so as to be closer than a thicker region, bending stress is generated in the connecting portion 516a which is present therebetween. Moreover, the connecting portion 516a of the vibrating unit 501 is formed to be structurally weak in comparison with to the vibrating portion 514a and the fixing portion 512a. Therefore, the stress described above tends to concentrate on the connecting portion 516a. In addition, the extent of such bending stress is increased as the number of the overlapped vibrating units 501 increases and a difference in the thickness is accumulated. When such stress is generated, the vibrating unit 501 may be destroyed and, even in a case where the vibrating unit 501 is not destroyed, the piezoelectric driving apparatus 500 is formed with stress still remaining in the connecting portion 516a.

In contrast, in the vibrating unit 501 of the present embodiment, the total thickness α of the vibrating portion 514a and the total thickness β of the fixing portion 512a are the same. Due to this, when overlapped and disposed, bending stress is not easily generated and, in particular, it is possible to suppress damage or the concentration of the stress in the connecting portion 516a. Accordingly, when overlapped, it is possible to form the piezoelectric driving apparatus 500 in a state where damage is not easily caused in the vibrating unit 501 and stress is not easily generated in the connecting portion 516a. In addition, this effect becomes more significant as the number of the vibrating units 501 is increased.

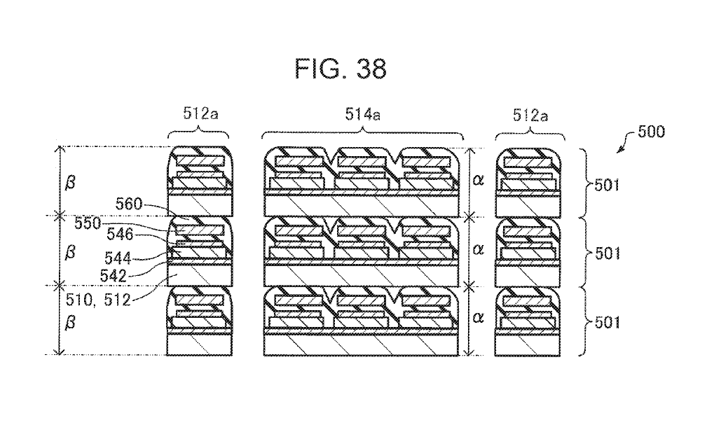

Here, the vibrating portion 514a and the fixing portion 512a of the vibrating unit 501 have a greater mechanical strength than the connecting portion 516a. For this reason, in the vibrating portion 514a and in the fixing portion 512a, even if the thickness of the vibrating unit 501 is non-uniform, stress or damage is not easily generated in the vibrating unit 501. FIG. 38 is a schematic view of a cross-section in a case where the insulating layer 560 is formed so as to follow the shape of the piezoelectric element in the vibrating unit 501 of the third embodiment. For example, as shown in FIG. 38, in a case where the insulating layer 560 is formed so as to follow the shape of the piezoelectric element in the vibrating portion 514a, the total thickness α of the vibrating portion 514a is not uniform in the vibrating portion 514a; however, even so, the concentration of stress in the connecting portion 516a is suppressed and the stress generated in the vibrating portion 514a is extremely small.

### 3.1.3. Capacitor

As described above, by the set of the third electrode 542, the second piezoelectric body layer 544 and the fourth electrode 546, a structure which can be a capacitor is formed above (on the fixing portion 512a of the vibrating unit 501) the fixing portion 512 of the vibrating plate 510; however, the shape, number, arrangement, and the like of the capacitors is arbitrary. In the illustrated example, two of the structures which can become capacitors are formed for each of two of the fixing portions 512, making a total of four. Accordingly, when each electrode is appropriately connected, it is possible for the structure to function as a capacitance (condenser).

Here, the set of the third electrode 542, the second piezoelectric body layer 544, and the fourth electrode 546 can function as a capacitor, but may be used simply as a structural material. That is, in the vibrating unit 501 of the third embodiment, the third electrode 542 which is disposed on the fixing portion 512a, the second piezoelectric body layer 544, and the fourth electrode 546 may be used only in order to set the thickness β of the fixing portion 512a to be the same as the thickness α of the vibrating portion 514a. In other words, in the vibrating unit 501 of the third embodiment, in order to easily set the thickness β of the fixing portion 512a and the thickness α of the vibrating portion 114a to be the same, the same laminate structure as the piezoelectric element is also disposed in the fixing portion 512a, but the laminate structure can also be used as a capacitor.

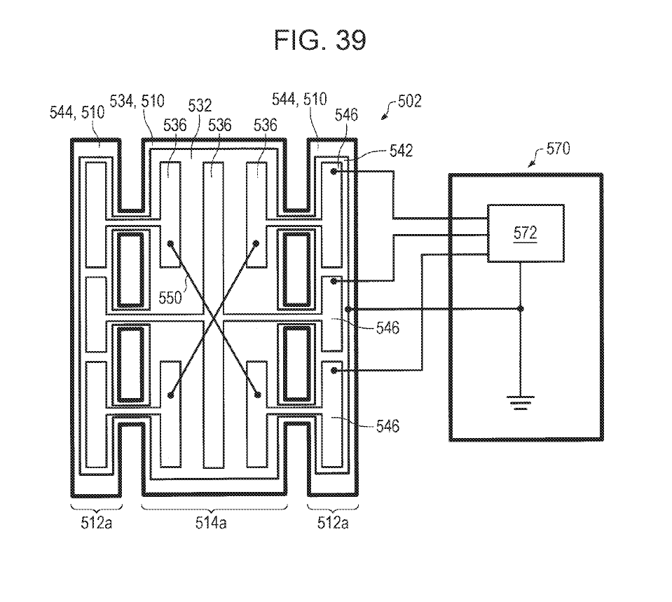

FIG. 39 is a schematic view in which a vibrating unit 502 according to the third embodiment is seen in plan view and a conceptual view of a driving circuit 570. In FIG. 39, the configuration positioned above the second electrode 536 and the fourth electrode 546 is omitted and the wiring formed by the wiring layer 550 is depicted schematically by line drawings. In addition, in the vibrating unit 502, the protrusion 518 and the hole 511 may be formed in the same manner as in the vibrating unit 501 described above, but these are omitted in FIG. 39 for convenience of description.

In the vibrating unit 502 shown in FIG. 39, a piezoelectric body layer is formed over the entire surface of the vibrating portion 514a, the fixing portion 512a, and a connecting portion 116, and the first piezoelectric body layer 534 and the second piezoelectric body layer 544 are present in a region interposed between the second electrode 536 and the fourth electrode 546 and the first electrode 532 and the third electrode 542. Furthermore, in the vibrating unit 502, the first electrode 532 and the third electrode 542 are not provided over the entire surface above the vibrating plate 510 and the outline of both in plan view is smaller than the outline of the vibrating plate 510. Then, the second electrode 536 forming the piezoelectric element and the fourth electrode 546 which is able to form a capacitor are electrically connected. The rest of the configuration is the same as the vibrating unit 501 described above and the description thereof is omitted by applying the same reference numerals.

As shown in FIG. 39, in the vibrating unit 502, the piezoelectric element provided on the vibrating portion 514a and the capacitor provided on the fixing portion 512a have an electrode in common. Accordingly, in a case of being seen from the driving circuit 570 (the power source), the piezoelectric element and the capacitor are connecting in parallel. In this manner, the structural body formed by the third electrode 542, the second piezoelectric body layer 544, and the fourth electrode 546 can be used as a capacitor.

The driving circuit 570 has at least a driving voltage generation circuit 572. In the illustrated example, the first electrode 532 and the third electrode 542 connected to each other have a ground potential, and each of the piezoelectric elements and the capacitor is appropriately connected to the driving voltage generation circuit 572. The driving circuit 570 subjects the vibrating unit to ultrasonic vibration by applying a periodically changing AC voltage or a pulsating voltage between predetermined electrodes. Here, the “pulsating voltage” has the meaning of a voltage where a DC offset is applied to an AC voltage and the orientation of the voltage (electric field) is a direction from one electrode to the other electrode.

### 3.1.4. Inductor

In a case where the vibrating unit 501 of the third embodiment has the wiring layer 550, an inductor may be formed using the wiring layer 550. The inductor may be formed by forming each of the electrodes described above and another conductive layer in addition to the wiring layer 550.

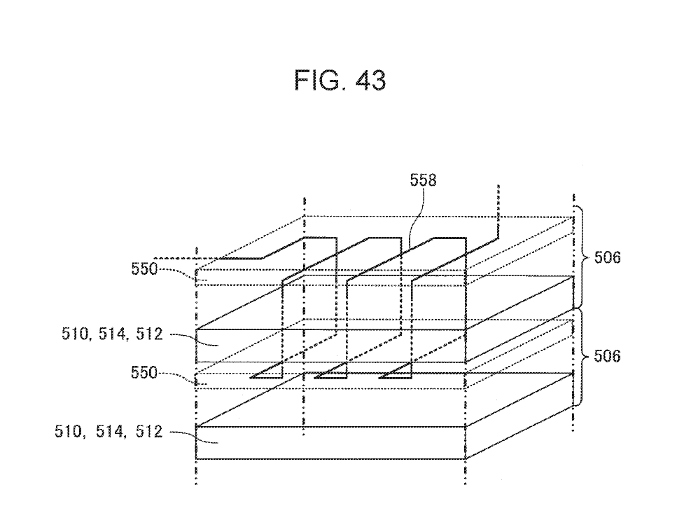

The inductor is, for example, a coil. The coil is not particularly limited and examples thereof include a winding of an electrical conductor. The form of the winding can be designed as appropriate. In the vibrating unit of the third embodiment, the wiring layer 550 is formed of a single layer or multiple layers, but in a case of forming the winding with a single layer, for example, the winding may take the form of a planar spiral or a one-turn loop. In addition, in a case where the wiring layer 550 is formed of a plurality of layers, the winding can form a coil in a form such that the conductor is wound into a cylindrical shape by forming a via or the like and wiring appropriately. Furthermore, it is also possible to form a coil in a form such that the conductor is wound into a cylindrical shape by using the overlapping arrangement of the vibrating unit 501 of the third embodiment and electrically connecting the wiring layer 550 of the vibrating units disposed adjacently (refer to FIG. 43).

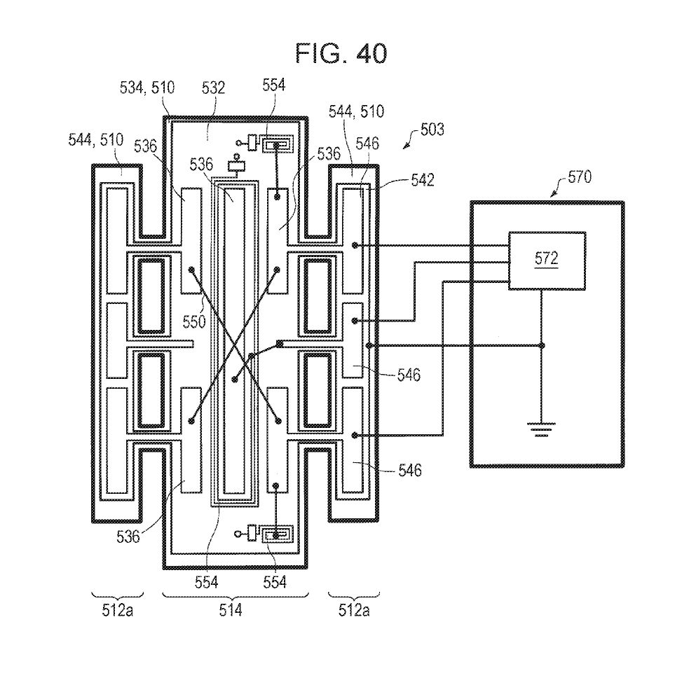

FIG. 40 to FIG. 42 are schematic views in which a vibrating unit 503, a vibrating unit 504, and a vibrating unit 505 are seen according to each embodiment in plan view, and are conceptual views of the driving circuit 570. In FIG. 40 to FIG. 42, the configuration positioned above the second electrode 536 and the fourth electrode 546 is omitted and the wiring formed by the wiring layer 550 is depicted schematically by line drawings. In addition, in the vibrating unit 503, the vibrating unit 504, and the vibrating unit 505 of FIG. 40 to FIG. 42, the protrusion 518 and the hole 511 may be formed in the same manner as the vibrating unit 501 described above; however, description thereof will be omitted in FIG. 40 to FIG. 42 for convenience of description.

Furthermore, in each of the vibrating units shown in FIG. 40 to FIG. 42, the piezoelectric body layer is formed over the entire surface of the vibrating portion 114a, the fixing portion 512a, and the connecting portion 516a, and the first piezoelectric body layer 534 and the second piezoelectric body layer 544 are present in a region interposed between the second electrode 536 and the fourth electrode 546 and the first electrode 532 and the third electrode 542. Furthermore, the first electrode 532 and the third electrode 542 are not provided over the entire surface above the vibrating plate 510 and the outline of both in plan view is smaller than the outline of the vibrating plate 510. Then, the second electrode 536 forming the piezoelectric element is electrically connected to a portion of the fourth electrode 546 which is able to form a capacitor. The rest of the configuration is the same as the vibrating unit 501 described above and the description thereof is omitted by applying the same reference numerals.

In the vibrating unit 503 shown in FIG. 40, the wiring layer 550 is patterned and a plurality of inductors 554 are formed. In the example of FIG. 40, the inductor 554 is formed in a spiral shape. In other words, the inductor 554 shown in FIG. 40 has a winding having a conduction path in a direction along the plane of the vibrating unit 503. In addition, although the details are not shown, both ends of the conductor wiring are connected to a wiring (multi-layer wiring) or an electrode to form a portion of the circuit.

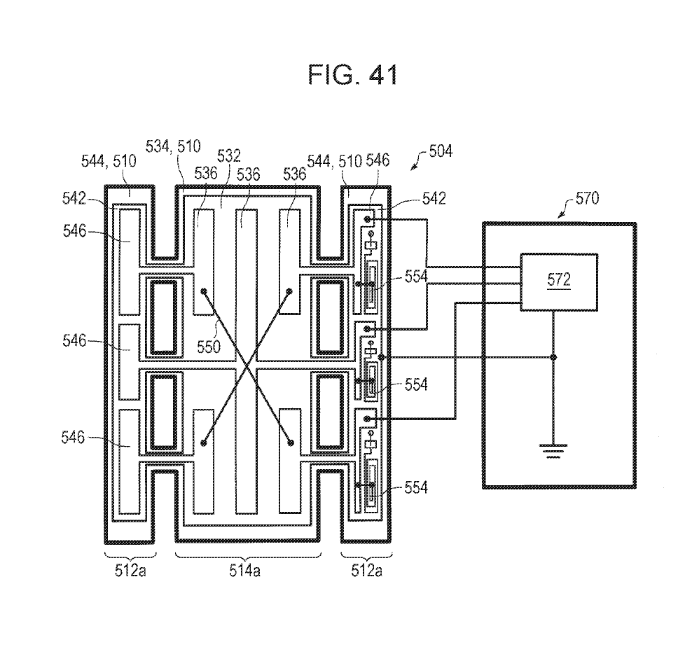

In the vibrating unit 503 shown in FIG. 40, three of the inductors 554 are formed and all are formed on the vibrating portion 514a. However, the inductors 554 may be formed in the fixing portion 512a as in the vibrating unit 504 shown in FIG. 41. Furthermore, although not shown, the inductors 554 may be formed on both of the vibrating portion 514a and the fixing portion 512a. In addition, the number of the inductors 554 to be formed is arbitrary.

The size and shape of the inductors 554 are arbitrary and can be designed to be suitable for a predetermined circuit configuration. In addition, the spiral shape inductor 554 can, for example, also be formed in the layer in which the first electrode 532 is formed. However, since the inductor 554 can reduce the wiring resistance, the inductor 554 is more preferably formed in the wiring layer 550.

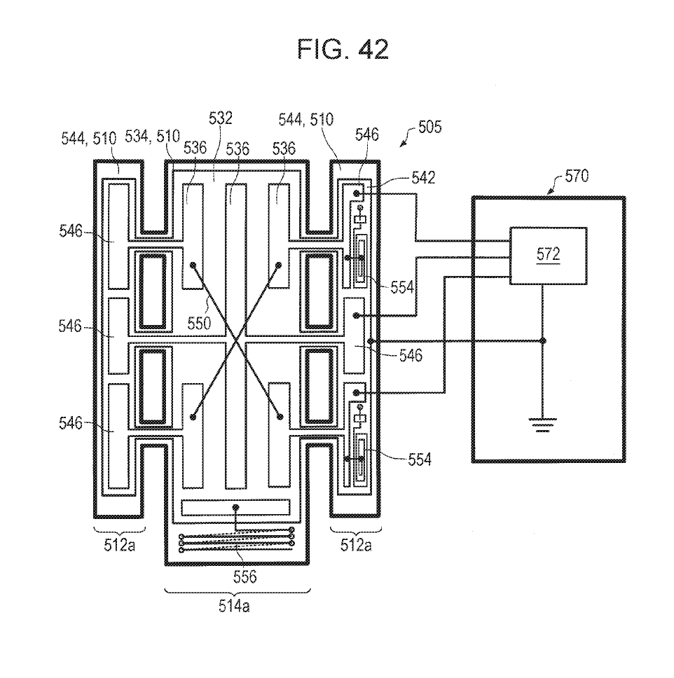

In the vibrating unit 505 shown in FIG. 42, multi-layer wiring layers 550 are respectively patterned and these are connected using a via to form an inductor 556. Accordingly, this is a form in which, in the inductor 556 of the vibrating unit 505, the two wiring layers 550 which are a multi-layer wiring are connected by a via, and the insulating layer 560 is present in the winding. In other words, the inductor 556 shown in FIG. 42 is a winding having a conduction path in a direction along the plane of the vibrating unit 505 and in the thickness direction. In addition, although not shown, in the inductor 556, the multi-layer wiring may be electrically connected by appropriately providing a conductor (conductive coating or the like) on the side surface of the vibrating unit 505 instead of the via. Furthermore, the inductor 556 may be formed in the fixing portion 512a.

FIG. 43 conceptually shows an example where the wiring layers 550 of the vibrating units disposed adjacently are electrically connected to each other to form an inductor 558. A vibrating unit 506 can be patterned by designing the wiring layer 550 as appropriate. Then, as shown in FIG. 43, this is a form in which the inductor 558 is formed by connecting the wiring layer 550 of the vibrating unit 506 provided adjacently using a via, and each configuration including the vibrating plate 510 is present on the inside of the winding. In other words, the inductor 558 shown in FIG. 43 has a winding having a conductive path in the direction along the plane of the vibrating unit 506 and the thickness direction. In addition, although not shown, in an inductor 558, the multi-layer wiring may be electrically connected by appropriately providing a conductor (conductive coating or the like) on the side surface of the laminated vibrating unit 506 instead of the via. In such a case, the inductor 558 may be formed on either of the fixing portion 512a and the vibrating portion 514a.

### 3.1.5. Circuit Configuration

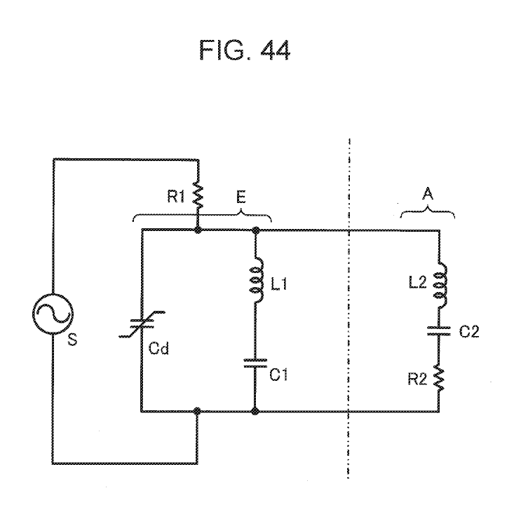

FIG. 44 is a diagram showing an example of a conceptual view of a circuit for driving the piezoelectric driving apparatus of the third embodiment. In the diagram, S represents the power source, R1 represents the wiring resistance, R2 represents the resistance (mechanical loss), Cd represents the piezoelectric driving apparatus, L1 and L2 represent the inductance, and C1 and C2 represent the capacitance respectively. As shown in FIG. 13, the driving circuit can be regarded as a circuit connecting an electrical element E and an acoustic element A. Description will be given below based on this idea.

The mechanical output of the piezoelectric driving apparatus Cd can be conceptually considered as the resistance R2 (mechanical loss). Accordingly, supplying a large amount of the energy applied from the power source S to the acoustic element A makes it possible to increase the mechanical output of the piezoelectric driving apparatus Cd. In other words, it is preferable to reduce the energy consumed by the electric element E.

The power supplied from the power source S is distributed to the electric element E and the acoustic element A. Accordingly, the smaller the impedance of both ends of the electrical element E than the impedance of both ends of the acoustic element A, the more power it is possible to distribute to the acoustic element A.

Here, in the electrical element E, when resonance is caused, it is possible to reduce the apparent impedance of the electrical element E. In order to generate such a resonance, the inductance L1 and capacitance C1 are disposed and connected in parallel to the piezoelectric driving apparatus Cd seen from the power source S, and an LC resonance circuit is formed. On the other hand, in the acoustic element A, an RLC series resonance circuit is formed.

In addition, the capacitance Cl also has a function to make DC current not flow in the entire circuit. The reason is that, since the power source S prevents polarization inversion of the piezoelectric driving apparatus Cd, an AC voltage having a bias is generated such that the potential is not inverted whether the potential is positive or negative. That is, this is because the power source S produces the pulsating voltage where a DC offset is added to an AC voltage.

In this manner, the circuit shown in FIG. 44 is designed such that, by reducing the apparent impedance of the electrical element E, the supply amount of power (energy) to the acoustic element A is increased, and each configuration functions to increase the resistance R2 (mechanical output).

In the configuration shown in FIG. 44, the inductance L1 and capacitance C1 are connected in parallel to the piezoelectric driving apparatus Cd as seen from the power source S. These can form the driving circuit by connecting a coil element or condenser element separate to the piezoelectric driving apparatus Cd with the piezoelectric driving apparatus Cd, and, as in the piezoelectric driving apparatus of the present embodiment described above, the capacitor or the inductor may be integrally provided with the piezoelectric driving apparatus and used.

In this manner, since it is possible to integrally provide at least a portion of the capacitor or inductor required for the driving circuit with the piezoelectric driving apparatus, it is possible to improve the overall space utilization efficiency more than in a case of providing the above separately. In addition, integrally providing at least a portion of the capacitor or the inductor with the piezoelectric driving apparatus makes it possible to reduce the length of the wiring and to reduce the loss of energy due to the wiring resistance.

Furthermore, as in the piezoelectric driving apparatus described above, in a case where a capacitor where a piezoelectric body (a dielectric body) which is the same as the piezoelectric body which forms the piezoelectric element is set as a spacer is integrally provided in the piezoelectric driving apparatus, the temperature characteristics of the piezoelectric element of the piezoelectric driving apparatus and the temperature characteristics of the capacitor are the same. Then, the piezoelectric element and the capacitor are provided at spatially close positions. Therefore, the piezoelectric element and the capacitor can change in the same manner in terms of the electrical characteristics with respect to changes in the temperature of the environment where the piezoelectric driving apparatus is placed. Due to this, for example, when the resonance frequency changes due to a change in environmental temperature, it is possible to reduce the adjustment range of the frequency using the driving circuit. Accordingly, the stability with respect to changes in the environmental temperature is good and it is possible to adjust the resonance frequency more easily.

### 3.2. Motor

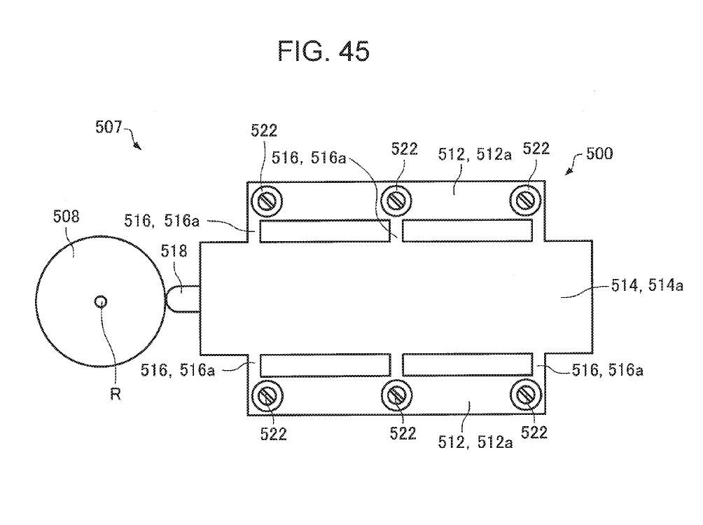

FIG. 45 is a diagram which schematically shows a motor 507 using the piezoelectric driving apparatus 500 described above. The piezoelectric driving apparatus 500 used in the motor 507 is the same as described above and detailed thereof will be omitted. In FIG. 45, the detailed configuration of the piezoelectric driving apparatus 500 is omitted from the illustration. Here, the piezoelectric driving apparatus 500 depicted in FIG. 45 is formed by laminating a plurality of the vibrating units 501 in the thickness direction (the depth direction in the diagram), and all of the configuration, including the protrusion 518, is overlapped.

In the motor 507, the portion of the piezoelectric driving apparatus 500 corresponding to the fixing portion 512a of the vibrating unit 501 is fixed by a screw 522 passing through the hole 511. As shown in FIG. 45, the piezoelectric driving apparatus 500 is in contact with a rotor (driven body) 508 at the protrusion 518. The rotor 508 is rotated by the piezoelectric driving apparatus 500. The rotor 508 has a cylindrical shape and is provided to freely rotate on the central shaft R, and a plurality of the protrusions 518 of the piezoelectric driving apparatus 500 are biased to come in contact with the side surface.

The protrusions 518 are members which come in contact with the rotor 508 and transmit the movement of the vibrating plate 510 to the rotor 508. It is possible for the rotor (driven body) 508 which comes in contact with the protrusions 518 to rotate in a predetermined rotation direction by applying an appropriate pulsating voltage to the piezoelectric driving apparatus 500 to produce ultrasonic vibration. In addition, changing the size and phase of the pulsating voltage for each piezoelectric element makes it possible to rotate the rotor 508 in contact with the protrusion 518 in the opposite direction.

Since the motor 507 of the third embodiment includes the piezoelectric driving apparatus 500 described above, the piezoelectric driving apparatus 500 is not easily damaged and has high reliability.

### 4. Fourth Embodiment

### 4.1. Apparatus Using Piezoelectric Driving Apparatus

The piezoelectric driving apparatus according to the invention is able to apply a large force with respect to a driven body by using resonance, and is applicable to various types of apparatuses. The piezoelectric driving apparatus according to the invention can be used as a driving apparatus in various types of devices such as, for example, robots (also including electronic component transporting apparatuses (IC handlers)), dosing pump, clock calendar feeding apparatuses, and paper feeding mechanisms for printing apparatuses. Description will be given below of a typical embodiment. Below, as the piezoelectric driving apparatus according to the invention, description will be given of an apparatus which includes the piezoelectric driving apparatus 100.

### 4.1.1. Robot

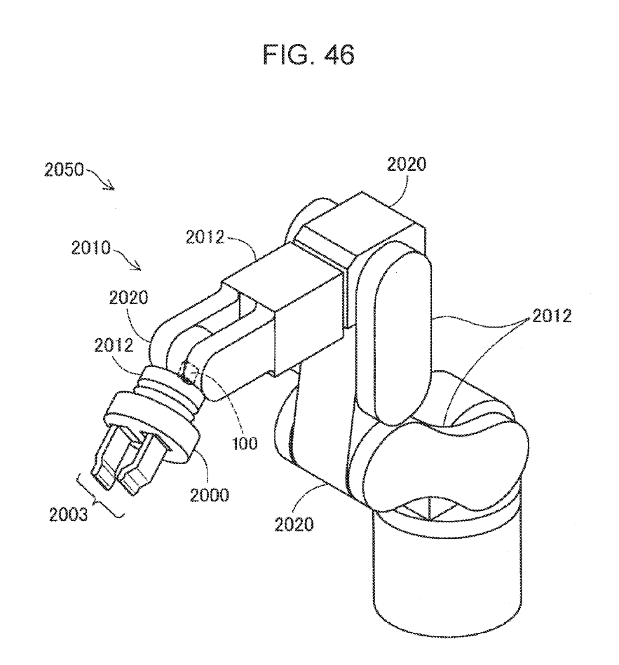

FIG. 46 is a diagram for illustrating a robot 2050 using the piezoelectric driving apparatus 100. The robot 2050 has a plurality of link portions 2012 (also referred to as “link members”), a plurality of joint portions 2020 which connect between the link portions 2012 in a rotatable or bendable state, and an arm 2010 (also referred to as an “arm portion”).

Each of the joint portions 2020 has a built-in piezoelectric driving apparatus 100 and it is possible to rotate or bend the joint portions 2020 at an arbitrary angle using the piezoelectric driving apparatuses 100. A robot hand 2000 is connected at the tip of the arm 2010. The robot hand 2000 is provided with a pair of grip portions 2003. The piezoelectric driving apparatus 100 is also built into the robot hand 2000 and it is possible to grip objects by opening and closing a grip portion 2003 using the piezoelectric driving apparatus 100. In addition, the piezoelectric driving apparatus 100 is also provided between the robot hand 2000 and the arm 2010 and it is possible to rotate the robot hand 2000 with respect to the arm 2010 using the piezoelectric driving apparatus 100.

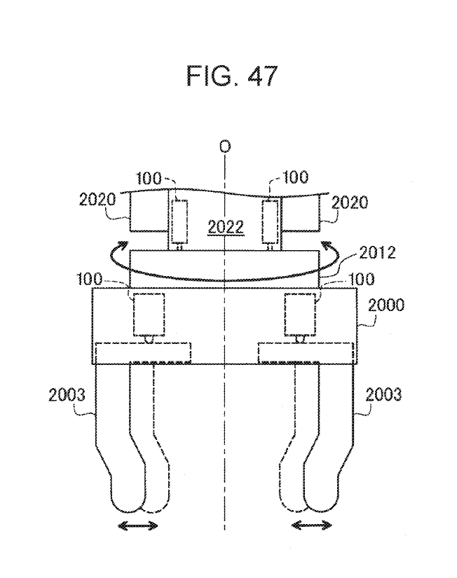

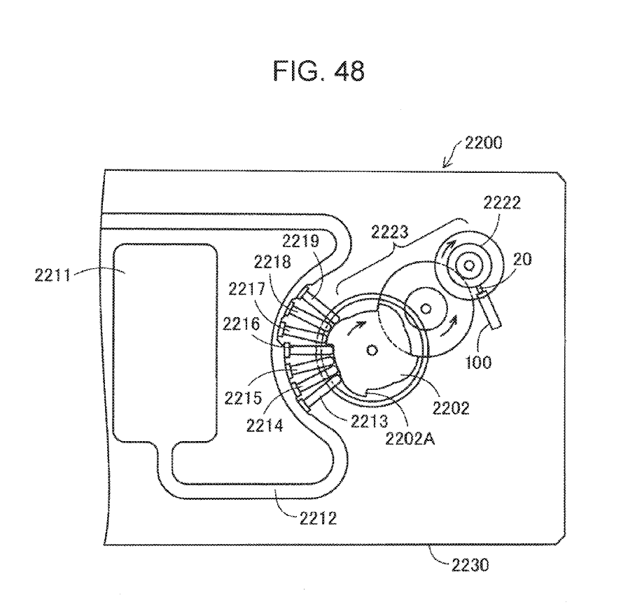

FIG. 47 is a diagram for illustrating the wrist portion of the robot 2050 shown in FIG. 46. The joint portion 2020 of the wrist holds a wrist rotating portion 2022 and link portion 2012 of the wrist is attached to the wrist rotating portion 2022 so as to be able to rotate around a central axis O of the wrist rotating portion 2022. The wrist rotating portion 2022 is provided with the piezoelectric driving apparatus 100 and the piezoelectric driving apparatus 100 rotates the link portion 2012 of the wrist and the robot hand 2000 around the central axis O. A plurality of grip portions 2003 are installed on the robot hand 2000. The base end portion of the grip portion 2003 is movable in the robot hand 2000 and the piezoelectric driving apparatus 100 is mounted on the base portion of the grip portion 2003. For this reason, operating the piezoelectric driving apparatus 100 makes it possible to grip the object by moving the grip portion 2003. Here, the robot is not limited to a single-armed robot, and it is also possible to apply the piezoelectric driving apparatus 100 to a multi-armed robot with two or more arms.

Here, in addition to the piezoelectric driving apparatus 100, a power line for supplying power to various devices such as a force sensor or a gyro sensor, a signal line for transmitting a signal, or the like is included in the interior of the joint portion 2020 of the wrist or the robot hand 2000 and an extremely large amount of wiring is necessary. Accordingly, arranging the wiring in the interior of the joint portion 2020 or the robot hand 2000 was extremely difficult. However, since the piezoelectric driving apparatus 100 can reduce the driving current more than a normal electric motor, it is possible to arrange the wiring even in a small space such as the joint portion 2020 (in particular, the joint portion at the tip of the arm 2010) or the robot hand 2000.

### 4.1.2. Pump

FIG. 49 is a diagram for illustrating an example of a feeding pump 2200 using the piezoelectric driving apparatus 100. The feeding pump 2200 includes a reservoir 2211, a tube 2212, the piezoelectric driving apparatus 100, a rotor 2222, a reduction transmission mechanism 2223, a cam 2202, and a plurality of fingers 2213, 2214, 2215, 2216, 2217, 2218, and 2219, in a case 2230.

The reservoir 2211 is an accommodating portion which accommodates a liquid which is a transportation object. The tube 2212 is a tube for transporting the liquid fed from the reservoir 2211. The contact portion 20 of the piezoelectric driving apparatus 100 is provided in a state of being pressed against the side surface of the rotor 2222 and the piezoelectric driving apparatus 100 rotates and drives the rotor 2222. The rotational force of the rotor 2222 is transmitted to the cam 2202 via the reduction transmission mechanism 2223. The fingers 2213 to 2219 are members for closing the tube 2212. When the cam 2202 is rotated, the fingers 2213 to 2219 are pressed outward in the radial direction in order by a protrusion 2202A of the cam 2202. The fingers 2213 to 2219 close the tube 2212 in order from the upstream side (the reservoir 2211 side) in the transport direction. Due to this, the liquid in the tube 2212 is sequentially transported to the downstream side. In this manner, it is possible to transport extremely small amounts with high accuracy and it is also possible to realize the small feeding pump 2200.

Here, the arrangement of each member is not limited to that illustrated. In addition, a configuration may be adopted in which a ball or the like provided in the rotor 2222 closes the tube 2212 without providing members such as the fingers. The feeding pump 2200 described above can be used in a dispensing device which administers medicine such as insulin to humans, or the like. Here, since it is possible to reduce the driving current more than in a normal electric motor by using the piezoelectric driving apparatus 100, it is possible to suppress the power consumption of the dispensing device. Accordingly, in a case where the dispensing device is driven by a battery, the invention is particularly effective.

The embodiments and modification examples described above are examples and the invention is not limited thereto. For example, it is also possible to appropriately combine each embodiment and each modification example.

The invention includes configurations substantially the same as the configurations described in the embodiments (for example, configurations where the functions, methods, and results are the same, or configurations where the object and effects are the same). In addition, the invention includes configurations obtained by replacing the portions not essential to the configurations described in the embodiments. In addition, the invention includes configurations which exhibit the same effects as the configurations described in the embodiments or configurations which are able to achieve the same object. In addition, the invention includes configurations where a known technique is added to the configuration described in the embodiments.

The entire disclosure of Japanese Patent Application No. 2015-190750, filed Sep. 29, 2015, No. 2015-222938, filed Nov. 13, 2015 and No. 2015-222939, filed Nov. 13, 2015, is expressly incorporated by reference herein.

What is claimed is:

1. A piezoelectric driving apparatus comprising:
a substrate;
a piezoelectric element which has a first electrode provided on the substrate, a piezoelectric body layer provided on the first electrode, and a second electrode provided on the first piezoelectric body layer;
a layer including copper provided along an outer periphery of the substrate in plan view and electrically connected to the first electrode; and
a conductive layer including nickel and phosphorus provided so as to cover the layer including copper.

2. The piezoelectric driving apparatus according to claim 1,
wherein the conductive layer has a layer including nickel and phosphorus, and a gold layer provided so as to cover the layer including nickel and phosphorus.

3. The piezoelectric driving apparatus according to claim 2,
wherein the conductive layer has a palladium layer provided between the layer including nickel and phosphorus and the gold layer.

4. The piezoelectric driving apparatus according to claim 1,
wherein the conductive layer is a non-electrolytic plating layer.

5. The piezoelectric driving apparatus according to claim 1,
wherein the substrate has a first surface and a second surface on an opposite side to the first surface,
the piezoelectric element is provided on the first surface,
a metal layer is provided on the second surface, and
the metal layer is connected to the conductive layer.

6. The piezoelectric driving apparatus according to claim 5, further comprising:
a first piezoelectric vibrating body; and
a second piezoelectric vibrating body bonded to the first piezoelectric vibrating body,
wherein the first piezoelectric vibrating body and the second piezoelectric vibrating body include the substrate, the piezoelectric element, and the layer including copper, and
the layer including copper of the first piezoelectric vibrating body and the layer including copper of the second piezoelectric vibrating body are bonded.

7. The piezoelectric driving apparatus according to claim 6,
wherein the first piezoelectric vibrating body and the second piezoelectric vibrating body form a bonded body,
the bonded body includes the metal layer,
a plurality of the bonded bodies are laminated in a thickness direction of the substrate, and
in adjacent bonded bodies, the metal layer of one bonded body and the metal layer of the other bonded body are bonded.

8. A method of manufacturing a piezoelectric driving apparatus, the method comprising:
forming a first electrode on a substrate;
forming a piezoelectric body layer on the first electrode;
forming a second electrode on the piezoelectric body layer;
forming a layer including copper electrically connected to the first electrode along an outer periphery of the substrate in plan view; and
forming a non-electrolytic plating layer so as to cover the layer including copper.

9. A piezoelectric driving apparatus comprising:
a first piezoelectric vibrating body having a first substrate, a first piezoelectric element provided on a first surface of the first substrate, and a first wiring layer electrically connected to the first piezoelectric element;
a second piezoelectric vibrating body having a second substrate, a second piezoelectric element provided on a first surface of the second substrate, and a second wiring layer electrically connected to the second piezoelectric element, and
a terminal electrically connecting external wiring and the first wiring layer and the second wiring layer,
wherein the first piezoelectric vibrating body and the second piezoelectric vibrating body are bonded such that the first surface of the first substrate and the first surface of the second substrate are opposed, and
the terminal is connected to a side surface of the first wiring layer and a side surface of the second wiring layer, and is provided so as to protrude further outward than the side surface of the first substrate and the side surface of the second substrate.

10. The piezoelectric driving apparatus according to claim 9,
wherein the terminal is a non-electrolytic plating layer.

11. The piezoelectric driving apparatus according to claim 9, further comprising:
a first insulating portion provided between the first substrate and the first wiring layer; and
a second insulating portion provided between the second substrate and the second wiring layer,
wherein the terminal is connected to a side surface of the first insulating portion and a side surface of the second insulating portion.

12. The piezoelectric driving apparatus according to claim 9,
wherein the terminal is provided to be separated from the first substrate and the second substrate.

13. A method of manufacturing a piezoelectric driving apparatus, the method comprising:
forming a first piezoelectric vibrating body having a first substrate, a first piezoelectric element provided on a first surface of the first substrate, and a first wiring layer electrically connected to the first piezoelectric element;
forming a second piezoelectric vibrating body having a second substrate, a second piezoelectric element provided on a first surface of the second substrate, and a second wiring layer electrically connected to the second piezoelectric element, and
bonding the first piezoelectric vibrating body and the second piezoelectric vibrating body such that the first surface of the first substrate and the first surface of the second substrate are opposed, and
forming a terminal so as to be connected to a side surface of the first wiring layer and a side surface of the second wiring layer, and protrude further outward than the side surface of the first substrate and the side surface of the second substrate.

14. The method of manufacturing a piezoelectric driving apparatus according to claim 13,
wherein the terminal is formed by non-electrolytic plating in the forming of the terminal.

15. The method of manufacturing a piezoelectric driving apparatus according to claim 13,
wherein, in the forming of the first piezoelectric vibrating body, the first piezoelectric vibrating body is formed so as to have a first insulating portion,
in the forming of the second piezoelectric vibrating body, the second piezoelectric vibrating body is formed so as to have a second insulating portion, and
in the forming of the terminal, the terminal is formed so as to connect a side surface of the first insulating portion and a side surface of the second insulating portion.

16. The method of manufacturing a piezoelectric driving apparatus according to claim 13,
wherein, in the forming of the terminal, the terminal is formed so as to be separated from the first substrate and the second substrate.

17. A piezoelectric driving apparatus comprising:
a plurality of vibrating units,
wherein the vibrating units include
a vibrating plate having a fixing portion, a vibrating portion, and a connecting portion connecting the fixing portion and the vibrating portion,
a first electrode provided above the vibrating portion,
a first piezoelectric body layer provided above the first electrode,
a second electrode provided above the first piezoelectric body layer,
a third electrode provided above the fixing portion,
a second piezoelectric body layer provided above the third electrode, and
a fourth electrode provided above the second piezoelectric body layer,
the first electrode, the first piezoelectric body layer, and the second electrode form a piezoelectric element, and
the vibrating unit is disposed so as to overlap a plate surface of the vibrating plate in an orthogonal direction.

18. The piezoelectric driving apparatus according to claim 17,
wherein the vibrating unit includes an insulating layer provided above the second electrode and the fourth electrode and a wiring layer provided above the insulating layer, and
at least one of the second electrode and the fourth electrode is electrically connected to the wiring layer.

19. The piezoelectric driving apparatus according to claim 18,
wherein an inductor is formed by electrically connecting the wiring layers of the adjacently disposed vibrating units to each other.

20. The piezoelectric driving apparatus according to claim 17,
wherein the third electrode, the second piezoelectric body layer, and the fourth electrode form a capacitor.

21. The piezoelectric driving apparatus according to claim 20,
wherein the capacitor is electrically connected in parallel with the piezoelectric element as seen from a power source of the vibrating unit.

22. The piezoelectric driving apparatus according to claim 17,
wherein the wiring layer forms an inductor.

23. The piezoelectric driving apparatus according to claim 22,
wherein the inductor is electrically connected in parallel with the piezoelectric element as seen from a power source of the vibrating unit.

24. A motor comprising:
the piezoelectric driving apparatus according to claim 1; and
a rotor rotated by the piezoelectric driving apparatus.

25. A robot comprising:
a plurality of link portions;
joint portions connecting the plurality of link portions; and
the piezoelectric driving apparatus according to claim 1, which rotates the plurality of link portions in the joint portions.

26. A pump comprising:
the piezoelectric driving apparatus according to claim 1;
a tube transporting a liquid; and
a plurality of fingers closing the tube according to driving of the piezoelectric driving apparatus.
